(19) United States
(12) Patent Application Publication
(10) Pub. No.: US 2026/0090289 A1
(43) Pub. Date: Mar. 26, 2026

(54) APPARATUS AND PROCESS FOR MONOLITHIC STOCHASTIC COMPUTING ARCHITECTURE FOR ENERGY ARITHMETIC

(71) Applicant: The Penn State Research Foundation, University Park, PA (US)

(72) Inventors: Saptarshi Das, State College, PA (US); Harikrishnan Ravichandran, State College, PA (US); Yikai Zheng, State College, PA (US)

(21) Appl. No.: 19/112,341

(22) PCT Filed: Sep. 18, 2023
(86) PCT No.: PCT/US2023/033046

§ 371 Date: Mar. 17, 2025

Related U.S. Application Data
(60) Provisional application No. 63/408,285, filed on Sep. 20, 2022.

(51) Int. Cl. H10N 70/20; G06F 7/50; G06F 7/52; H10N 70/00

(52) U.S. Cl. CPC H10N 70/253; H10N 70/24; H10N 70/8822; G06F 7/50; G06F 7/52

(57) ABSTRACT

Embodiments relate to devices, circuits, and systems including s-bit generators constructed from memtransistors. Each memtransistor is stacked on a non-volatile and programmable local back-gate stack. Each memtransistor has a 2D channel formed between its source and its drain. The s-bit generator can be used to construct s-bit generator circuits that exploit the different sources of inherent stochasticity in 2D memtransistors (e.g., cycle-to-cycle fluctuations in the carrier trapping and detrapping phenomena in a gate insulator of a 2D memtransistor, thermal conductance fluctuations in a defect-engineered and scaled 2D memtransistor, random telegraph signals (RTS) in a defect-engineered and scaled 2D memtransistor, etc.) and combine it with an inverting amplifier and a programmable thresholding inverter to obtain s-bits. Additional embodiments relate to integration of s-bit generators with 2D memtransistor based logic gates such as AND, MUX, XOR, and OR gates to perform arithmetic operations such as addition, subtraction, multiplication, and/or sorting.

### CROSS-REFERENCE TO RELATED APPLICATIONS

This patent application is related to and claims the benefit of priority to U.S. 63/408,285, filed on Sep. 20, 2022, the entire contents of which is incorporated by reference.

### STATEMENT REGARDING FEDERALLY SPONSORED RESEARCH AND DEVELOPMENT

This invention was made with government support under Grant No. W911NF-19-2-0338 awarded by the United States Army/ARO and under Grant No. DMR1539916 awarded by the National Science Foundation. The Government has certain rights in the invention.

### FIELD OF THE INVENTION

Embodiments relate to s-bit generators constructed from memtransistors that exploit the different sources of inherent stochasticity in 2D memtransistors. The different sources of stochasticity can include cycle-to-cycle fluctuations in the carrier trapping and detrapping phenomena in a gate insulator of a 2D memtransistor, thermal conductance fluctuations in a defect-engineered and scaled 2D memtransistor, random telegraph signals (RTS) in a defect-engineered and scaled 2D memtransistor, etc., and combine it with an inverting amplifier and a programmable thresholding inverter to obtain s-bits.

### BACKGROUND OF THE INVENTION

The aggressive downscaling of feature sizes in silicon based complementary metal-oxide-semiconductor (CMOS) technology over the past five decades has led to an exponential growth in the computing power of modern-day computers. Today, computers can fly jets, control industrial processes, and solve optimization problems. In fact, computers can also beat professional players in the game of ‘Go’ and predict complex structures of proteins thanks to the remarkable progress in the field of artificial intelligence (AI). The ongoing revolution in AI is directly linked to the unfathomable data processing power by computers enabling implementation of deep learning and various other sophisticated machine learning algorithms. However, there is significant infrastructure cost associated with advanced AI and computing systems. For example, any mathematical algorithm implemented using hardware requires arithmetic operations such as addition, subtraction, multiplication, sorting, etc., which are executed using logic circuits consisting of hundreds of transistors that occupy large area and consume significant amount of energy. Furthermore, the von Neumann architecture necessitate frequent data shuttling between the arithmetic and the memory units to run algorithms adding area and energy overheads. Needless to say, these challenges are aggravated as the data size grows exponentially for both AI and no-AI platforms. Therefore, a new paradigm that can drastically reduce the area and energy cost of arithmetic operations can not only benefit cloud computing using supercomputers but also enable edge computing in resource-constrained internet of things (IoT) devices.

### SUMMARY OF THE INVENTION

An exemplary embodiment relates to an s-bit generator configured to exploit inherent stochasticity in 2D memtransistors for stochastic bit (s-bit) generation.

An exemplary embodiment relates to an s-bit generator. The s-bit generator can include plural 2D memtransistors, an inverting amplifier, and a programmable threshold inverter. One or more s-bits can be generated from inherent stochasticity in the plural 2D memtransistors. In some embodiments, the plural 2D memtransistors form a voltage divider.

Inherent stochasticity in the plural 2D memtransistors can include one or more of: cycle-to-cycle fluctuations in carrier trapping and detrapping phenomena in a gate insulator of a 2D memtransistor of the plural 2D memtransistor, thermal conductance fluctuations in a defect-engineered and scaled 2D memtransistor of the plural 2D memtransistors, and/or random telegraph signals (RTS) in a defect-engineered and scaled 2D memtransistor of the plural 2D memtransistors.

An exemplary embodiment relates to a s-bit generator. The s-bit generator includes plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor is stacked on a non-volatile and programmable local back-gate stack. Each memtransistor has a 2D channel formed between its source and its drain. MT1-drain is connected to: MT3-drain, MT5-drain, and node N1. MT1-gate is connected to node N2. MT1-source is connected to: MT2-drain and MT4-gate via node N5. MT2-drain is connected to MT4-gate via node N5. MT2-gate is connected to node N3. MT2-source is connected to: MT4-source, MT6-source, and node N4. MT3-drain is connected to: MT1-drain, MT5-drain, and node N1. MT3-gate is connected to MT6-gate via node N6. MT3-source is connected to: MT6-gate via node N6 and MT4-drain via node N6. MT4-drain is connected to: MT3-source via node N6, MT3-gate via node N6, and MT6-gate via node N6. MT4-gate is connected to: MT1-source via node N5 and MT2-drain via node N5. MT4-source is connected to: MT2-source, MT6-source, and node N4. MT5-drain is connected to: MT1-drain, MT3-drain, and node N1. MT5-gate is connected to MT6-drain via node N7. MT6-drain is connected to: MT5-source via node N7 and MT5-gate via node N7. MT6-gate is connected to: MT3-source via node N6, MT3-gate via node N6, and MT4-drain via node N6. MT6-source is connected to: MT4-source, MT2-source, and node N4.

In some embodiments, the 2D channel is a monolayer.

In some embodiments, the monolayer includes MoS2.

An exemplary embodiment relates to a stochastic computing processor. The stochastic computing processor includes a processing module having a processor and a memory. The stochastic computing processor includes plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor is stacked on a non-volatile and programmable local back-gate stack. Each memtransistor has a 2D channel formed between its source and its drain. MT1-drain is connected to: MT3-drain, MT5-drain, and node N1. MT1-gate is connected to node N2. MT1-source is connected to: MT2-drain and MT4-gate via node N5. MT2-drain is connected to MT4-gate via node N5. MT2-gate is connected to node N3. MT2-source is connected to: MT4-source, MT6-source, and node N4. MT3-drain is connected to: MT1-drain, MT5-drain, and node N1. MT3-gate is connected to MT6-gate via node N6. MT3-source is connected to: MT6-gate via node N6 and MT4-drain via node N6. MT4-drain is connected to: MT3-source via node N6, MT3-gate via node N6, and MT6-gate via node N6. MT4-gate is connected to: MT1-source via node N5 and MT2-drain via node N5. MT4-source is connected to: MT2-source, MT6-source, and node N4. MT5-drain is connected to: MT1-drain, MT3-drain, and node N1. MT5-gate is connected to MT6-drain via node N7. MT6-drain is connected to: MT5-source via node N7 and MT5-gate via node N7. MT6-gate is connected to: MT3-source via node N6, MT3-gate via node N6, and MT4-drain via node N6. MT6-source is connected to: MT4-source, MT2-source, and node N4.

In some embodiments, the stochastic computing processor has a non-von Neuman architecture.

An exemplary embodiment relates to a stochastic multiplier. The stochastic multiplier includes a first s-bit generator having plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor is stacked on a non-volatile and programmable local back-gate stack. Each memtransistor has a 2D channel formed between its source and its drain. MT1-drain is connected to: MT3-drain, MT5-drain, and node N1. MT1-gate is connected to node N2. MT1-source is connected to: MT2-drain and MT4-gate via node N5. MT2-drain is connected to MT4-gate via node N5. MT2-gate is connected to node N3. MT2-source is connected to: MT4-source, MT6-source, and node N4. MT3-drain is connected to: MT1-drain, MT5-drain, and node N1. MT3-gate is connected to MT6-gate via node N6. MT3-source is connected to: MT6-gate via node N6 and MT4-drain via node N6. MT4-drain is connected to: MT3-source via node N6, MT3-gate via node N6, and MT6-gate via node N6. MT4-gate is connected to: MT1-source via node N5 and MT2-drain via node N5. MT4-source is connected to: MT2-source, MT6-source, and node N4. MT5-drain is connected to: MT1-drain, MT3-drain, and node N1. MT5-gate is connected to MT6-drain via node N7. MT6-drain is connected to: MT5-source via node N7 and MT5-gate via node N7. MT6-gate is connected to: MT3-source via node N6, MT3-gate via node N6, and MT4-drain via node N6. MT6-source is connected to: MT4-source, MT2-source, and node N4. The first s-bit generator is configured to generate an output A at node N7. The stochastic multiplier includes a second s-bit generator having plural memtransistors, comprising: a memtransistor, MT14, having a MT14-drain, a MT14-source, and a MT14-gate; a memtransistor, MT15, having a MT15-drain, a MT15-source, and a MT15-gate; a memtransistor, MT12, having a MT12-drain, a MT12-source, and a MT12-gate; a memtransistor, MT13, having a MT13-drain, a MT13-source, and a MT13-gate; a memtransistor, MT10, having a MT10-drain, a MT10-source, and a MT10-gate; and a memtransistor, MT1, having a MT11-drain, a MT11-source, and a MT1-gate. Each memtransistor is stacked on a non-volatile and programmable local back-gate stack. Each memtransistor has a 2D channel formed between its source and its drain. MT14-drain is connected to: MT12-drain, MT10-drain, and V_{DD}. MT14-gate is connected to node N12. MT14-source is connected to: MT15-drain and MT13-gate via node N11. MT15-drain is connected to MT13-gate via node N11. MT15-gate is connected to node N13. MT15-source is connected to: MT13-source, MT11-source, and GND. MT12-drain is connected to: MT14-drain, MT10-drain, and V_{DD}). MT12-gate is connected to MT1-gate via node N10. MT12-source is connected to: MT1-gate via node N10 and MT13-drain via node N10. MT13-drain is connected to: MT12-source via node N10, MT12-gate via node N10, and MT1-gate via node N10. MT13-gate is connected to: MT14-source via node N11 and MT15-drain via node N11. MT13-source is connected to: MT14-source, MT11-source, and GND. MT10-drain is connected to: MT14-drain, MT12-drain, and V_{DD}. MT10-gate is connected to MT11-drain via node N9. MT11-drain is connected to: MT10-source via node N9 and MT10-gate via node N9. MT1-gate is connected to: MT12-source via node N10, MT12-gate via node N10, and MT13-drain via node N10. MT11-source is connected to: MT13-source, MT15-source, and GND. The second s-bit generator is configured to generate an output B at node N9. The stochastic multiplier includes an AND gate configured to receive output A, receive output B, and generate an output C.

In some embodiments, the AND gate includes plural memtransistors, comprising: a memtransistor, MT7, having a MT7-drain, a MT7-source, and a MT7-gate; a memtransistor, MT8, having a MT8-drain, a MT8-source, and a MT8-gate; and a memtransistor, MT9, having a MT9-drain, a MT9-source, and a MT9-gate.

In some embodiments, for the first s-bit generator: output A is transmitted to the AND gate via node N7; node N7 is connected to MT7-gate; MT1-drain, MT3-drain, and MT5-drain are connected to MT7-drain; and MT2-source, MT4-source, and MT6-source are connected to: MT9-gate and to MT9-source. For the second s-bit generator: output B is transmitted to the AND gate via node N9; node N7 is connected to MT8-gate; MT10-drain, MT12-drain, and MT14-drain are connected to MT7-drain; and MT14-source, MT13-source, and MT11-source are connected to: MT9-gate and to MT9-source. For the AND gate: MT7-source is connected to MT8-drain; MT8-source connected to MT9-drain and to node N8; and the AND gate outputs C at node N8.

An exemplary embodiment relates to a stochastic adder. The stochastic adder includes a first s-bit generator having plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor is stacked on a non-volatile and programmable local back-gate stack. Each memtransistor has a 2D channel formed between its source and its drain. MT1-drain is connected to: MT3-drain, MT5-drain, and node N1. MT1-gate is connected to node N2. MT1-source is connected to: MT2-drain and MT4-gate via node N5. MT2-drain is connected to MT4-gate via node N5. MT2-gate is connected to node N3. MT2-source is connected to: MT4-source, MT6-source, and node N4. MT3-drain is connected to: MT1-drain, MT5-drain, and node N1. MT3-gate is connected to MT6-gate via node N6. MT3-source is connected to: MT6-gate via node N6 and MT4-drain via node N6. MT4-drain is connected to: MT3-source via node N6, MT3-gate via node N6, and MT6-gate via node N6. MT4-gate is connected to: MT1-source via node N5 and MT2-drain via node N5. MT4-source is connected to: MT2-source, MT6-source, and node N4. MT5-drain is connected to: MT1-drain, MT3-drain, and node N1. MT5-gate is connected to MT6-drain via node N7. MT6-drain is connected to: MT5-source via node N7 and MT5-gate via node N7. MT6-gate is connected to: MT3-source via node N6, MT3-gate via node N6, and MT4-drain via node N6. MT6-source is connected to: MT4-source, MT2-source, and node N4. The first s-bit generator is configured to generate an output S. The stochastic adder includes a second s-bit generator having plural memtransistors, comprising: a memtransistor, MT7, having a MT7-drain, a MT7-source, and a MT7-gate; a memtransistor, MT8, having a MT8-drain, a MT8-source, and a MT8-gate; a memtransistor, MT9, having a MT9-drain, a MT9-source, and a MT9-gate; a memtransistor, MT10, having a MT10-drain, a MT10-source, and a MT10-gate; a memtransistor, MT1, having a MT11-drain, a MT11-source, and a MT1-gate; and a memtransistor, MT12, having a MT12-drain, a MT12-source, and a MT12-gate. Each memtransistor is stacked on a non-volatile and programmable local back-gate stack. Each memtransistor has a 2D channel formed between its source and its drain. MT7-drain is connected to: MT9-drain, MT11-drain, and node V_{DD}. MT7-gate is connected to node N8. MT7-source is connected to: MT8-drain and MT10-gate via node N10. MT8-drain is connected to MT10-gate via node N10. MT2-gate is connected to node N3. MT8-source is connected to: MT10-source, MT12-source, and GND. MT9-drain is connected to: MT7-drain, MT11-drain, and V_{DD}). MT9-gate is connected to MT12-gate via node N11. MT9-source is connected to: MT12-gate via node N11 and MT10-drain via node N11. MT10-drain is connected to: MT9-source via node N11, MT9-gate via node N11, and MT12-gate via node N11. MT10-gate is connected to: MT7-source via node N10 and MT8-drain via node N10. MT10-source is connected to: MT8-source, MT12-source, and GND. MT11-drain is connected to: MT7-drain, MT9-drain, and V_{DD}. MT1-gate is connected to MT12-drain via node N12. MT12-drain is connected to: MT11-source via node N12 and MT1-gate via node N12. MT12-gate is connected to: MT9-source via node N11, MT9-gate via node N11, and MT10-drain via node N11. MT12-source is connected to: MT10-source, MT8-source, and GND. The second s-bit generator is configured to generate an output A.

The stochastic adder includes a third s-bit generator having plural memtransistors, comprising: a memtransistor, MT13, having a MT13-drain, a MT13-source, and a MT13-gate; a memtransistor, MT14, having a MT14-drain, a MT14-source, and a MT14-gate; a memtransistor, MT15, having a MT15-drain, a MT15-source, and a MT15-gate; a memtransistor, MT16, having a MT16-drain, a MT16-source, and a MT16-gate; a memtransistor, MT17, having a MT17-drain, a MT17-source, and a MT17-gate; and a memtransistor, MT18, having a MT18-drain, a MT18-source, and a MT18-gate. Each memtransistor is stacked on a non-volatile and programmable local back-gate stack. Each memtransistor has a 2D channel formed between its source and its drain. MT17-drain is connected to: MT15-drain, MT13-drain, and V_{DD}. MT17-gate is connected to node N16. MT17-source is connected to: MT18-drain and MT16-gate via node N15. MT18-drain is connected to MT16-gate via node N15. MT18-gate is connected to node N17. MT18-source is connected to: MT16-source, MT14-source, and GND. MT15-drain is connected to: MT17-drain, MT13-drain, and V_{DD}). MT15-gate is connected to MT14-gate via node N14. MT15-source is connected to: MT14-gate via node N14 and MT16-drain via node N14. MT16-drain is connected to: MT15-source via node N14, MT15-gate via node N14, and MT14-gate via node N14. MT16-gate is connected to: MT17-source via node N15 and MT18-drain via node N15. MT16-source is connected to: MT14-source, MT18-source, and GND. MT13-drain is connected to: MT17-drain, MT15-drain, and V_{DD}). MT13-gate is connected to MT14-drain via node N13. MT14-drain is connected to: MT13-source via node N13 and MT13-gate via node N13. MT14-gate is connected to: MT15-source via node N14, MT15-gate via node N14, and MT16-drain via node N14. MT15-source is connected to: MT16-source, MT18-source, and GND. The third s-bit generator is configured to generate an output B. The stochastic adder includes MUX gate configured to receive output S, receive output A, receive output B, and generate an output C.

In some embodiments, the MUX gate includes plural memtransistors, comprising: a memtransistor, MT19, having a MT19-drain, a MT19-source, and a MT19-gate; a memtransistor, MT20, having a MT20-drain, a MT20-source, and a MT20-gate; a memtransistor, MT21, having a MT21-drain, a MT21-source, and a MT21-gate; and a memtransistor, MT22, having a MT22-drain, a MT22-source, and a MT22-gate.

In some embodiments, for the first s-bit generator: node N1 is connected to V_{DD}; node N7 is connected to MT20-gate; and node N4 is connected to GND. For the second s-bit generator: MT7-drain, MT9-drain, and MT11-drain are connected to MT19-drain; and node N12 is connected to MT21-drain. For the third s-bit generator: node N13 is connected to MT22-source. For the MUX gate: MT19-drain is connected to N1 and V_{DD}; MT19-gate is connected to: MT21-gate via node N18 and MT20-drain via node N18; MT19-source is connected to: MT21-gate via node N18 and MT20-drain via node N18; MT20-drain is connected to: MT19-gate via node N18, MT19-source via node N18, and MT21-gate via node N18; MT20-gate is connected to: node N7 and MT22-gate; MT20-source is connected to node N4 and GND; MT21-drain is connected to N12; MT21-gate is connected to: MT19-source via node N18, MT19-gate via node N18, and MT20-drain via node N18; MT21-source is connected to MT22-drain via node N19; MT22-drain is connected to MT21-source via node N19; MT22-gate is connected to MT20-gate; MT22-source is connected to node N13; and the MUX gate outputs C at node N19.

An exemplary embodiment relates to a stochastic subtractor. The stochastic subtractor includes a first s-bit generator configured to generate output A, and a second s-bit generator configured to generate output B, wherein output A and output B are correlated bit streams. The stochastic subtractor includes an XOR gate, comprising plural memtransistors, the plural memtransistors including: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; a memtransistor, MT6, having a MT6-drain, a MT6-source, and a MT6-gate; a memtransistor, MT7, having a MT7-drain, a MT7-source, and a MT7-gate; and a memtransistor, MT8, having a MT8-drain, a MT8-source, and a MT8-gate; a memtransistor, MT9, having a MT9-drain, a MT9-source, and a MT9-gate. Each memtransistor is stacked on a non-volatile and programmable local back-gate stack. Each memtransistor has a 2D channel formed between its source and its drain. MT1-drain is connected to: node N1, MT3-drain, MT5-drain, MT7-drain, and V_{DD}). MT1-gate is connected to: MT7-gate and MT2-drain via node N2. MT1-source is connected to MT2-drain via node N2. MT2-drain is connected to: MT1-source via node N2 and MT1-gate via node N2. MT2-gate is connected to MT4-gate via node N4. MT2-source is connected to: MT9-gate via node N3 and GND. MT3-drain is connected to: node N1, MT1-drain, MT5-drain, MT7-drain, and V_{DD}). MT3-gate is connected to: MT5-gate and MT6-drain via node N6. MT3-source is connected to MT4-drain. MT4-drain is connected to MT3-source. MT4-gate is connected to MT2-gate via node N4. MT4-source is connected to: MT9-drain via node N5 and MT8-source via node N5. MT5-drain is connected to: node N1, MT1-drain, MT3-drain, MT7-drain, and V_{DD}). MT5-gate is connected to: MT3-gate and MT6-drain via node N6. MT5-source is connected to: MT3-gate via node N6 and MT6-drain via node N6. MT6-drain is connected to: MT5-source via node N6, MT5-gate via node N6, and MT3-gate via node N6. MT6-gate is connected to: MT8-gate via node N7. MT6-source is connected to: node N8 and GND. MT7-drain is connected to: node N1, MT1-drain, MT3-drain, MT5-drain, and V_{DD}). MT7-gate is connected to: MT1-gate, MT1-source, and MT2-drain via node N2. MT7-source is connected to MT8-drain. MT8-drain is connected to MT7-source. MT8-gate is connected to MT6-gate via node N7. MT8-source is connected to MT9-drain via node N5. MT9-drain is connected to MT4-source via node N5 and MT8-source via node N5. MT9-gate is connected to: node N3 and GND. MT9-source is connected to: node N3 and GND. Output A is received at node N4 and output B is received at node N7. MT1 and MT2, together, act as a NOT gate to invert output A to generate output A^{c}. MT5 and MT6, together, act as a NOT gate to invert output B to generate B^{c}. The XOR gate is configured to receive output A, receive output B, and generate an output C via node N5.

An exemplary embodiment relates to a stochastic correlator, comprising: a first s-bit generator configured to generate output A, and a second s-bit generator configured to generate output B, wherein output A and output B are uncorrelated bit streams. The stochastic correlator includes an OR gate, comprising plural memtransistors, the plural memtransistors including: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; Each memtransistor is stacked on a non-volatile and programmable local back-gate stack. Each memtransistor has a 2D channel formed between its source and its drain. MT1-drain is connected to: node N1 and V_{DD}. MT1-gate is connected to node N2. MT1-source is connected to: MT2-source, node N4, and MT3-drain. MT2-drain is connected to: node N1 and V_{DD}. MT2-gate is connected to node N3. MT2-drain is connected to: MT1-source, node N4, and MT3-drain. MT3-drain is connected to MT1-source, MT2-source, and node N4. MT3-gate is connected to node N5 and GND. MT3-source is connected to GND. The OR gate is configured to receive output A at node N2, receive output B at node N3, and generate an output C via node N4.

An exemplary embodiment relates to a stochastic sorter. The stochastic sorter includes a first s-bit generator configured to generate output A, and a second s-bit generator configured to generate output B. The stochastic sorter includes an OR gate configured to receive output A, receive output B, and generate an output C that is a maximum value of output A and output B. The stochastic sorter includes an AND gate configured to receive output A, receive output B, and generate an output D that is a minimum value of output A and output B.

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 shows an exemplary stochastic computing processor including an embodiment of a s-bit generator.

FIGS. 2A-2-I show fabrication and characterization of 2D memtransistors for acceleration of stochastic computing (SC). FIG. 2A shows an optical image of a representative 2D memtransistor based medium scale integrated circuit for the hardware acceleration of SC.

FIG. 2B shows an optical image and corresponding 3D schematic of a representative 2D memtransistor based on monolayer MoS₂, which are locally back-gated using a stack comprising of atomic layer deposition (ALD) grown 50 nm Al₂O₃ on sputter deposited 40/30 nm Pt/TiN. All back-gate islands were fabricated on SiO_{2/p}⁺⁺—Si substrate. FIG. 2C shows transfer characteristics, i.e. source to drain current (I_{DS}) versus local back-gate voltage (V_{BG}) measured using source to drain bias, V_{DS}=1 V for a representative MoS₂ memtransistor with channel length, L=1 μm, and channel width, W=5 μm in linear and logarithmic scale. FIG. 2D shows output characteristics, i.e. I_{DS} versus V_{DS} for different V_{BG} for the same MoS₂ memtransistor. FIG. 2E shows device-to-device variation in the transfer characteristics. FIG. 2F shows a corresponding histogram of extracted field effect mobility (μ_{FE}) distribution across 50 memtransistors. FIG. 2G shows analog programming and FIG. 2H shows erase capability of 2D memtransistor when subjected to negative “Write” (V_{P}) and positive “Erase” (V_{E}) voltage pulses of different amplitudes ranging from 6 V to 15 V applied to the local back-gate electrode, each for a duration of τ_{P/E}=100 μs. FIG. 2I shows non-volatile retention for 4 representative programmed and erased states for 100 seconds.

FIGS. 3A-3K shows programming stochasticity in 2D memtransistor and s-bit generation. FIG. 3A shows transfer characteristics of a representative 2D memtransistor, measured each time after the application of V_{P}=−10 V and V_{E}=10 V each for rₛ=100 μs, for a total of 100 cycles. FIG. 3B shows an optical image and FIG. 3C corresponding circuit diagram for the proposed s-bit generator consisting of six memtransistors (MT1, MT2, MT3, MT4, MT5, MT6). Voltage waveform applied to the nodes, N1, i.e., V_{N1} toggles between 0 V, 0 V, and V_{DD}=2 V and voltage waveforms applied to node, N2, i.e., V_{N2} toggles between V_{P}=−7 V, V_{E}=10 V, and V_{R}=1 V during each clock cycle (r_{clk}). Voltages applied to nodes, N3, and N4, i.e., V_{N3}, and V_{N4} are held constant at 1V and 0 V, respectively. FIG. 3D shows voltage readout at node, N₅, i.e., V_{N5}. Since memtransistors MT1 and MT2 are connected in series and G_{MT1} fluctuates due to programming and reset every (τ_{clk}), so does V_{N5}. FIG. 3E shows distribution of V_{N5} over 200 τ_{clk} follows a random Gaussian distribution with mean, μV_{N5}=0.27 V and standard deviation, σV_{N5}=0.05 V. FIG. 3F shows output, V_{N6}, of an inverting amplifier constructed using MT3 and MT4 as a function of the input, V_{N5} with a gain of ˜7. FIG. 3G shows V_{N6} corresponding to V_{N5} shown in FIG. 3D. FIG. 3H shows distribution of V_{N6} which follows a random Gaussian distribution with mean, μV_{N6}=1.01 V and an increased standard deviation of σV_{N6}=0.35 V. FIG. 3I shows output, V_{N7}, of a thresholding inverter constructed using MT5 and MT6 as a function of the input, V_{N6} for different inversion threshold, V_{IT}. FIG. 3J shows V_{N7} corresponding to V_{N6} shown in FIG. 3G for different V_{IT}. FIG. 3K shows probability of obtaining ‘1’ in the bit stream (pₛ) as a function of V_{IT}. This clearly shows the ability of the proposed circuit to transform the cycle-to-cycle conductance fluctuations in 2D memtransistor into s-bits with reconfigurable pₛ that lie between [0,1].

FIGS. 4A-4F show a stochastic multiplier. FIG. 4A shows a schematic, FIG. 4B shows an optical image, and FIG. 4C shows a corresponding circuit configuration of a stochastic multiplier having a 2 s-bit generator and one AND gate with a total of 15 memtransistors. FIG. 4D shows representative stochastic bit-streams for the random variables, A(p_{A}) and B(p_{B}) obtained from their respective s-bit generators and the corresponding output bit-stream for C(p_{c}). Colormaps (FIG. 4E) of percentage errors E for multiplication and corresponding correlation coefficient (CC) (FIG. 4F) for different combinations of p_{A} and p_{B} are shown. Lower values of e is a direct consequence of near ideal CC values close to zero indicating mutual independence of A and B, which is critical for accurate multiplication. Bit-streams of length 200-bit are used to evaluate the probability values associated with the random variable.

FIGS. 5A-5E show a stochastic adder. FIG. 5A shows a schematic, FIG. 5B shows an optical image, and FIG. 5C shows a corresponding circuit configuration of a stochastic adder having a 3 s-bit generator and one 2×1 MUX gate with a total of 22 memtransistors. FIG. 5D shows representative stochastic bit-streams for the random variables S(pₛ), A(p_{A}), and B(p_{B}) obtained from their respective s-bit generation modules at nodes N7, N12, and N13 and the corresponding output bit-stream for C(p_{C}). Colormaps (FIG. 5E) of percentage errors (ε) for scaled addition for different combinations of p_{A}, p_{B}, for pₛ˜0.5 are shown.

FIGS. 6A-6L show stochastic subtraction and sorting using correlated s-bits. FIG. 6A shows a schematic, FIG. 6B shows an optical image, and FIG. 6C shows a corresponding circuit configuration for stochastic subtraction using one XOR gate and 9 memtransistors. FIG. 6D shows representative stochastic bit-streams for the random variables A(p_{A}) and B(p_{B}), which are highly correlated with CC=0.88, and the corresponding output bit-stream for C(p_{C}). FIG. 6E shows a schematic, FIG. 6F shows an optical image, and FIG. 6G shows a corresponding circuit configuration for a correlator circuit based on OR gate and 3 memtransistors. FIG. 6H shows colormaps of correlation coefficient between the output C and input A (CC_{A-C}) and input B (CC_{B-C}). FIG. 6I shows a schematic, FIG. 6J shows an optical image, and FIGS. 6Ka and 6Kb show a corresponding circuit configuration of a sorting circuit having of one OR gate and one AND gate. FIG. 6L shows representative stochastic bit-streams for the correlated random variables A, B, and the sorted output C for maximum and D for minimum values, respectively.

FIGS. 7A-7I show fabrication and characterization of monolayer MoS₂ field effect transistor (FET). FIG. 7A shows Raman spectra obtained from MoS₂ film showing the characteristic in-plane

$${E}_{2 g}^{1} ,$$

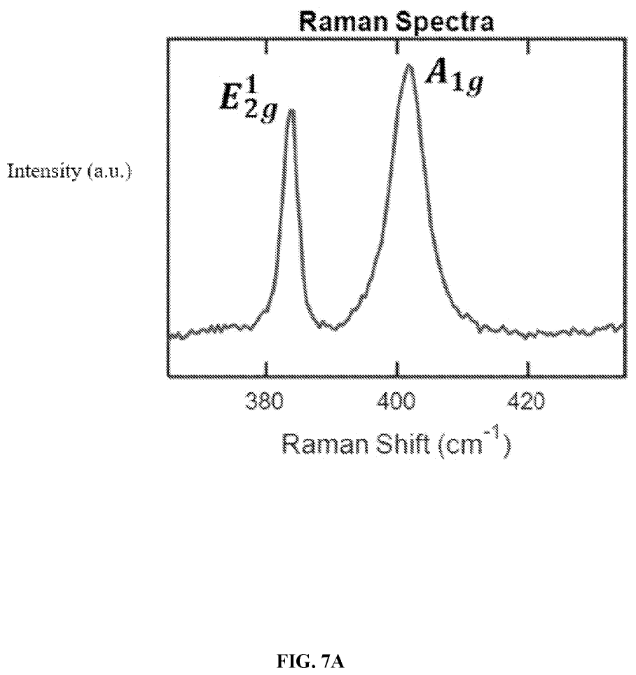

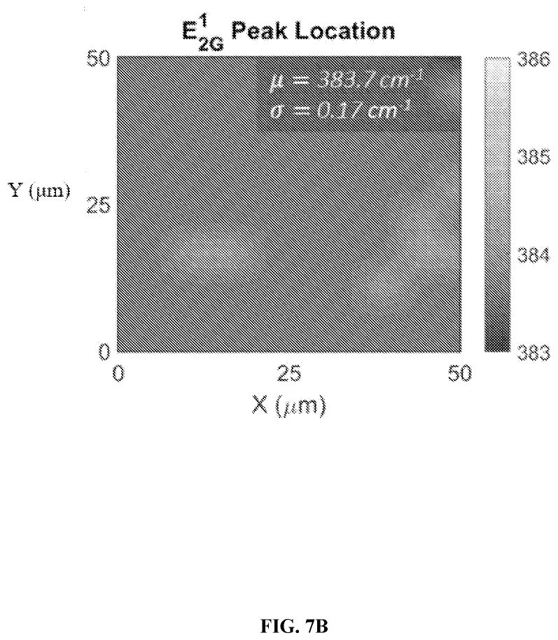

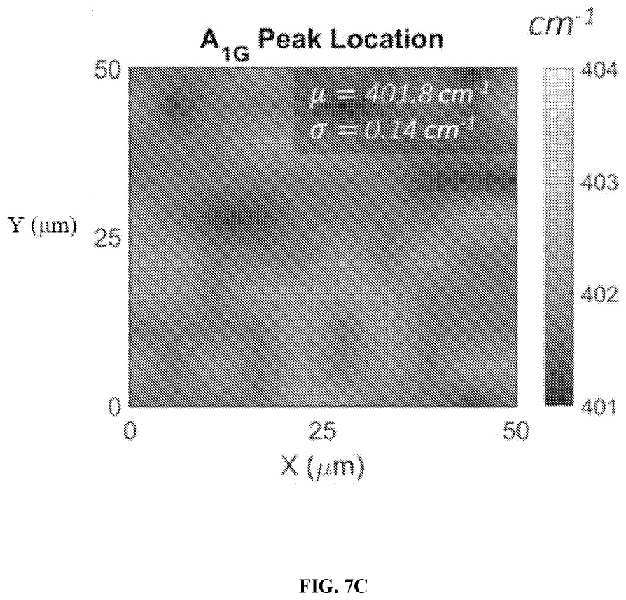

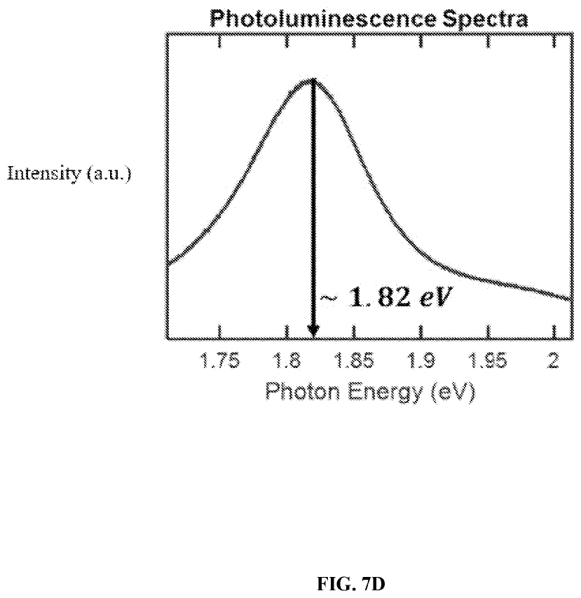

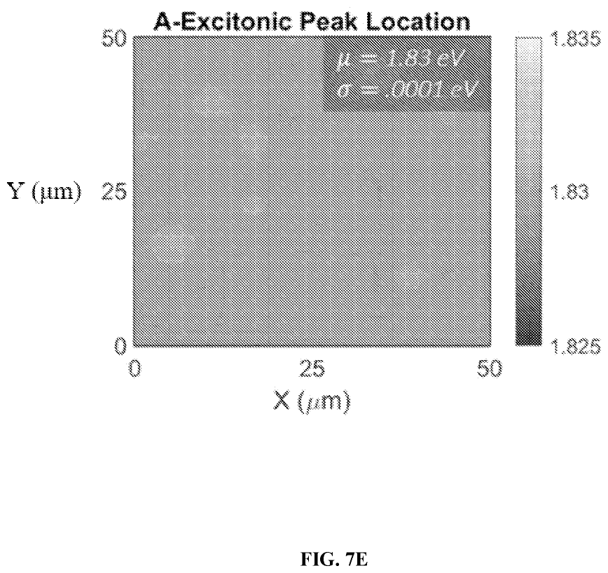

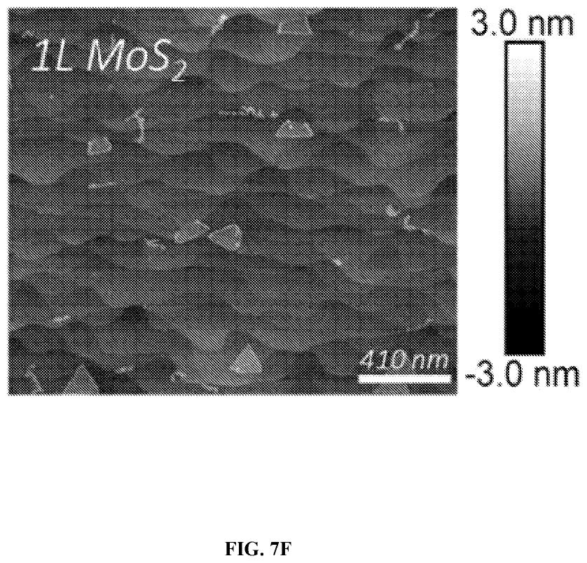

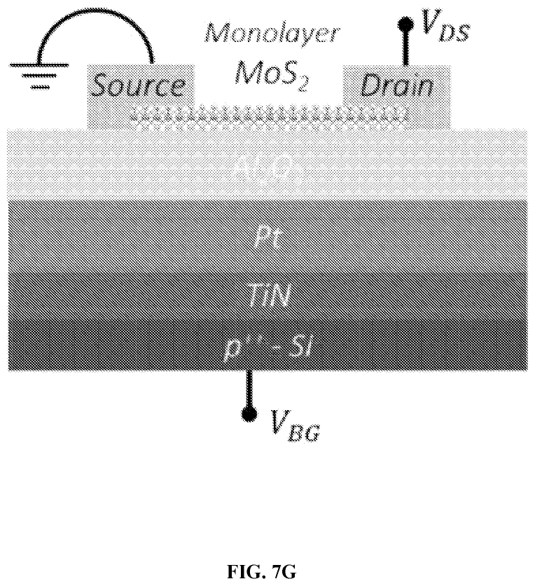

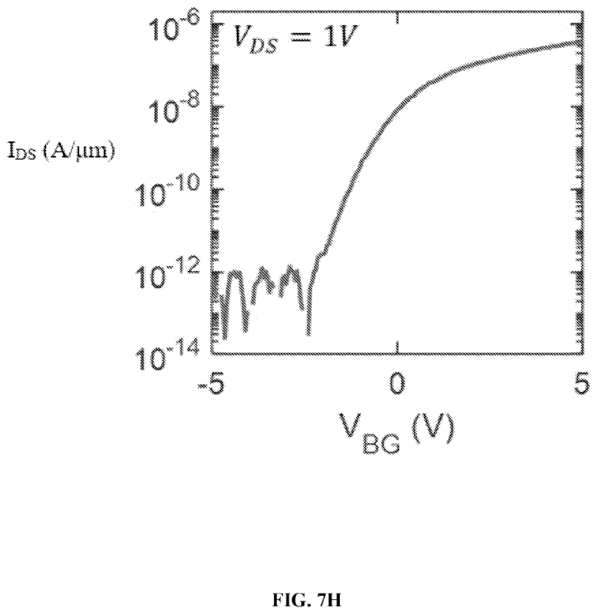

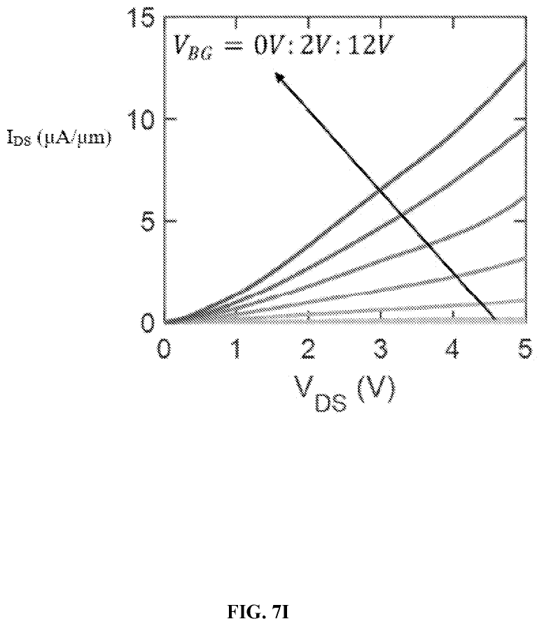

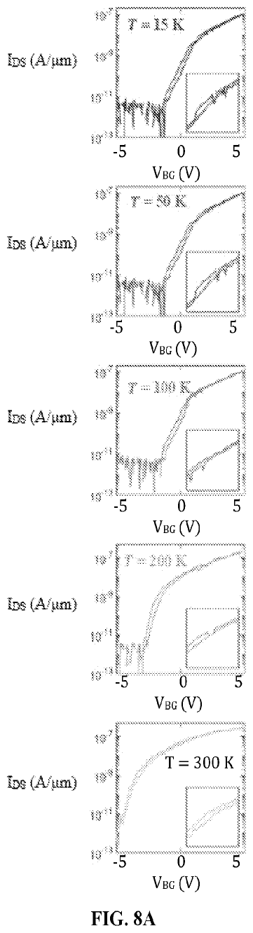

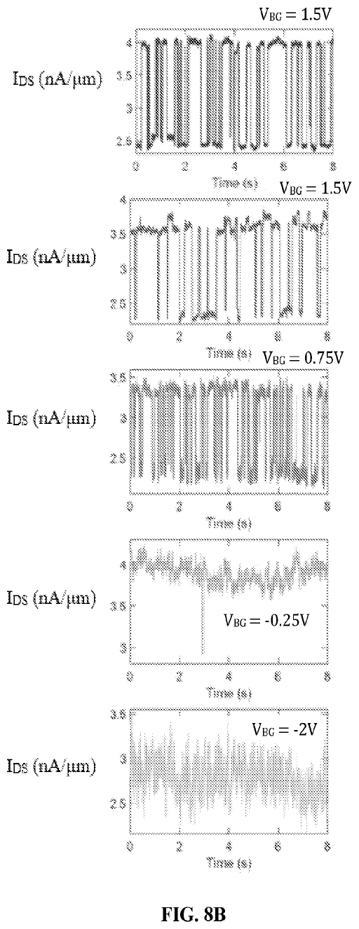

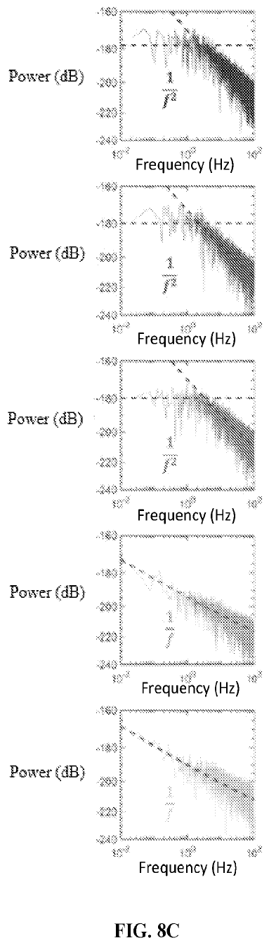

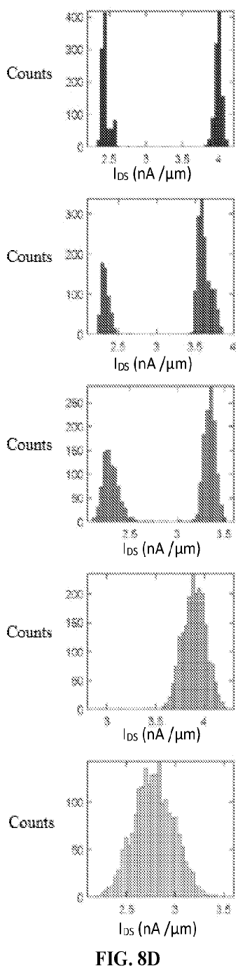

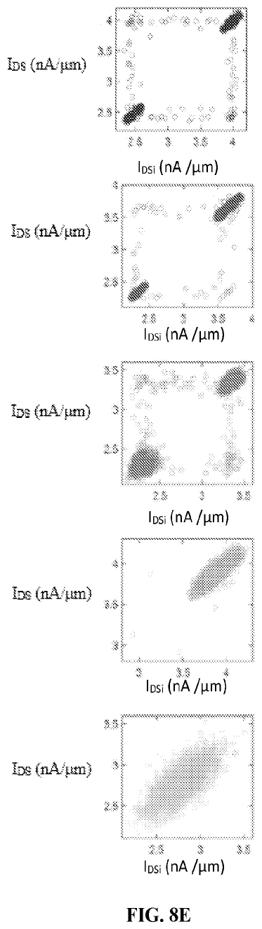

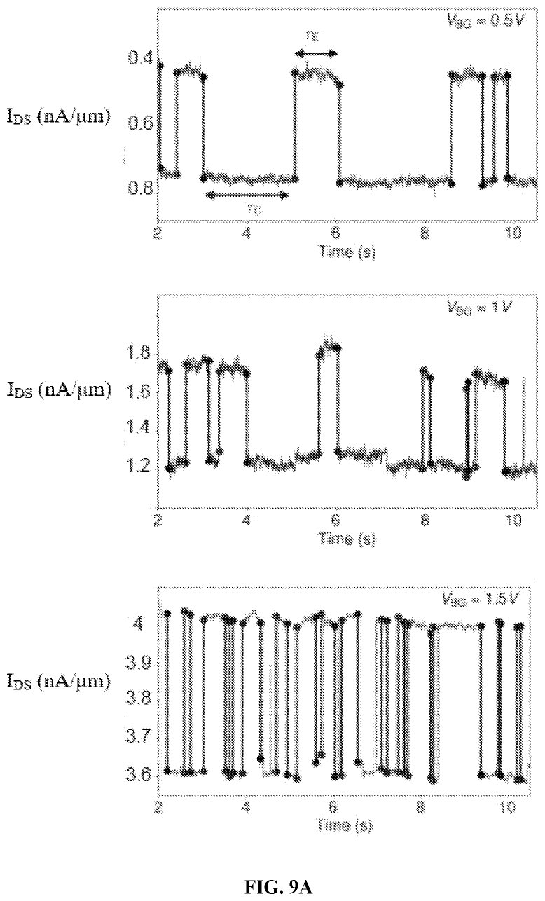

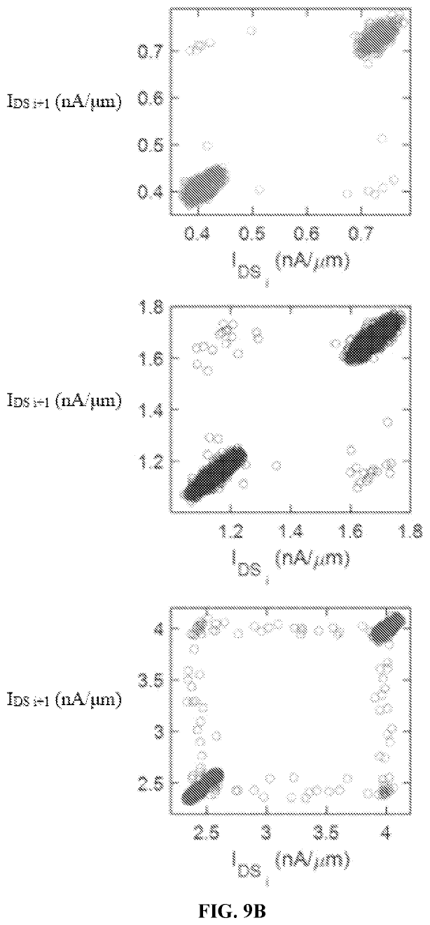

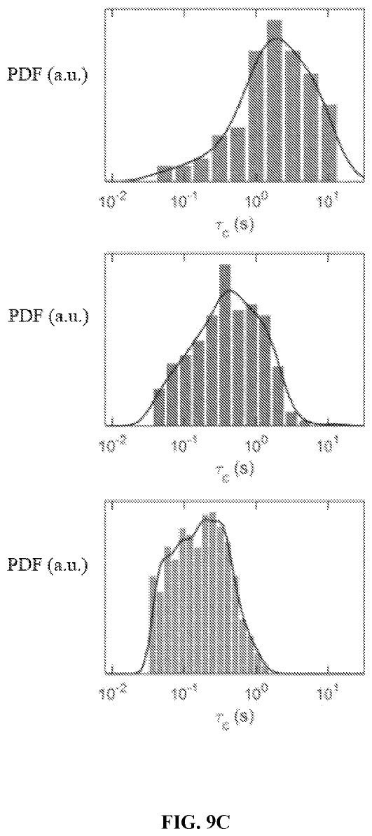

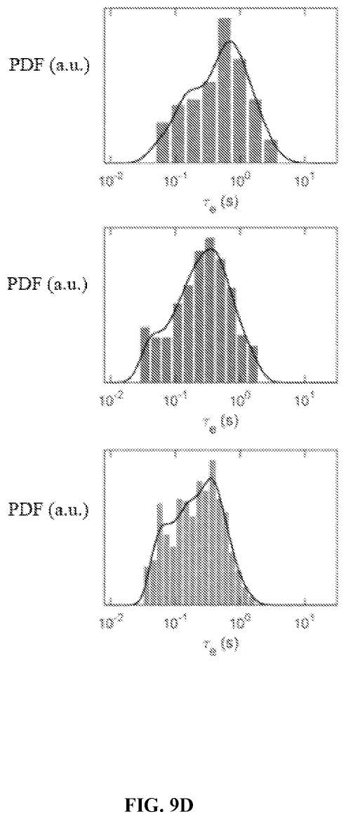

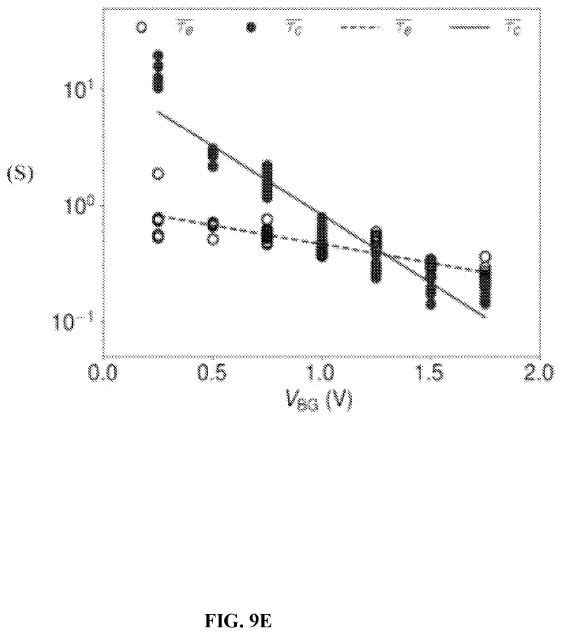

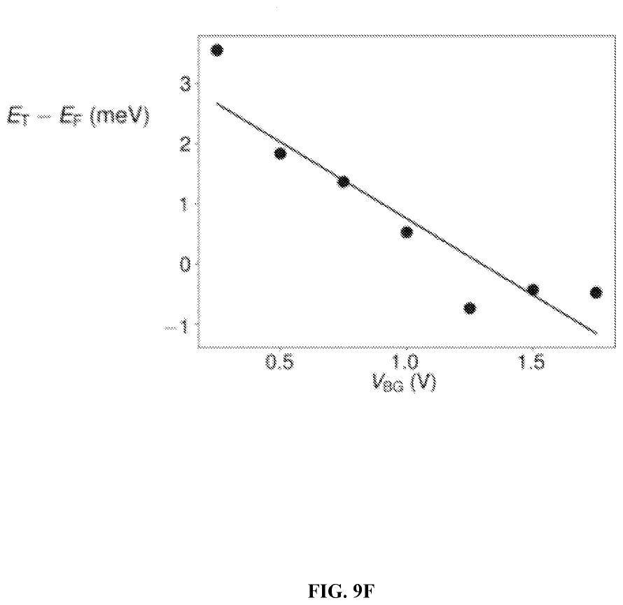

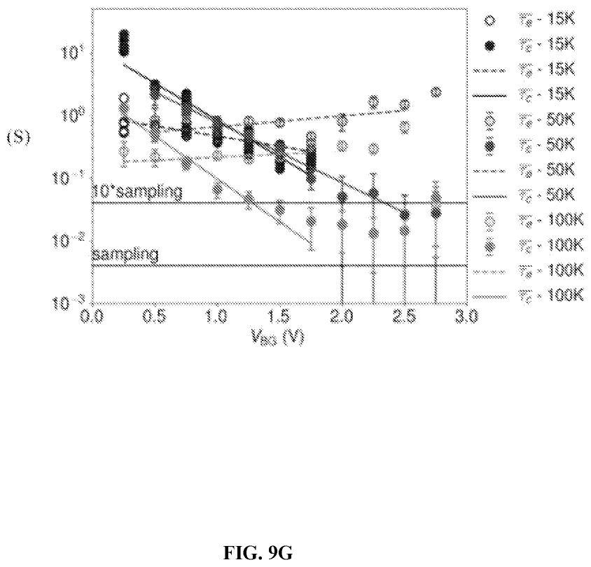

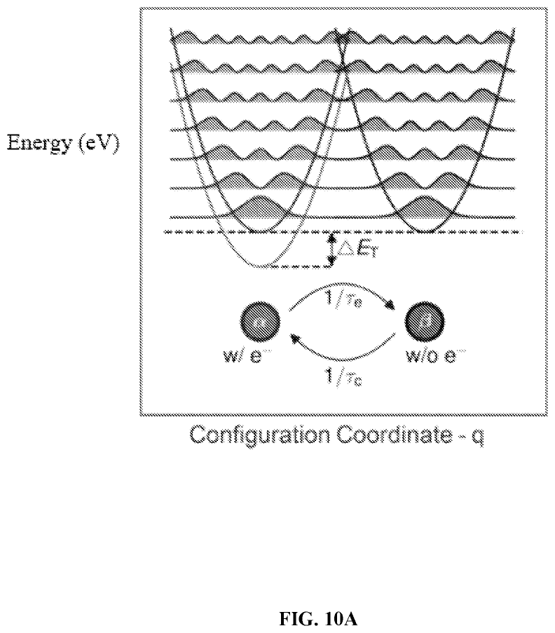

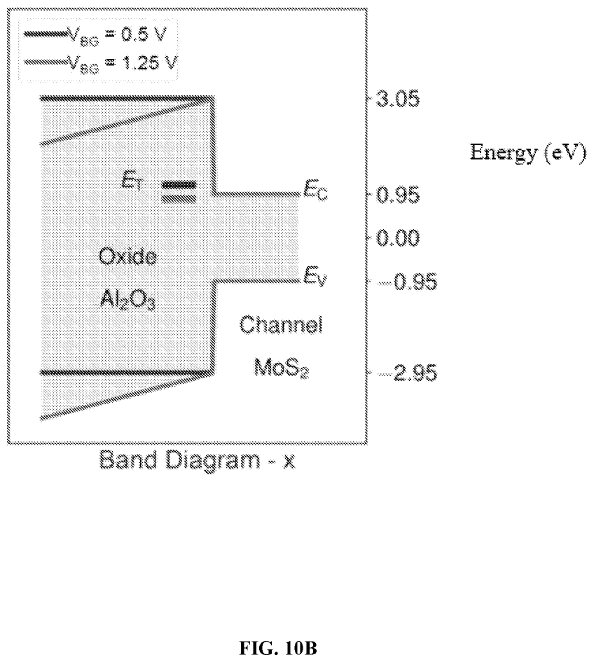

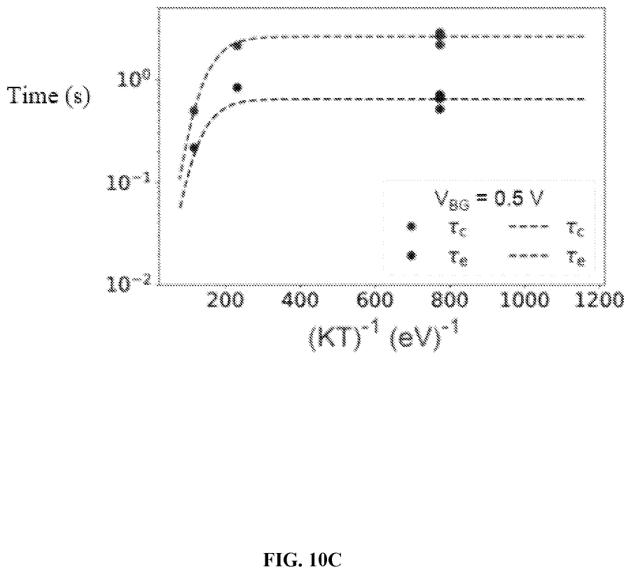

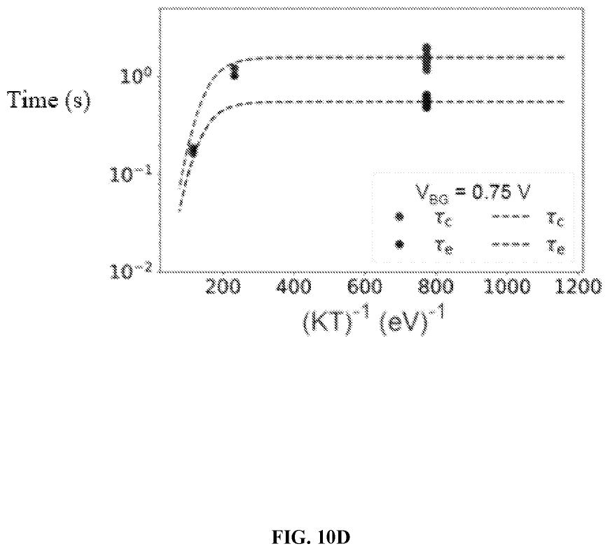

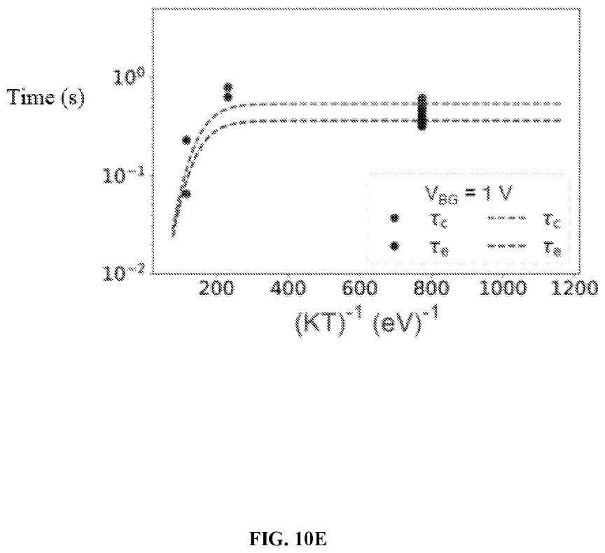

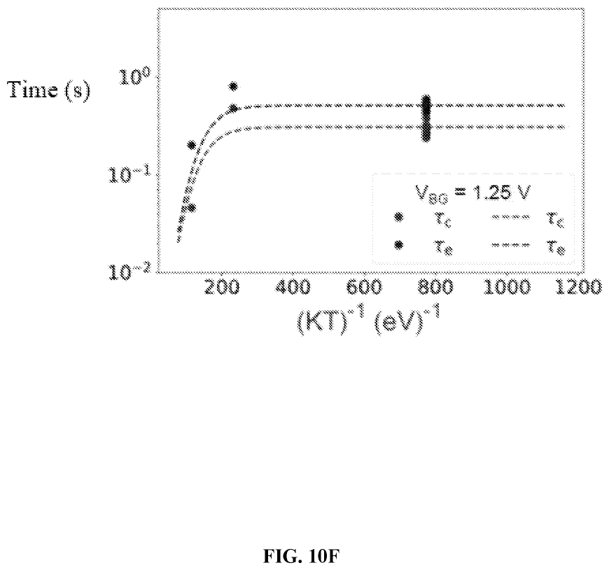

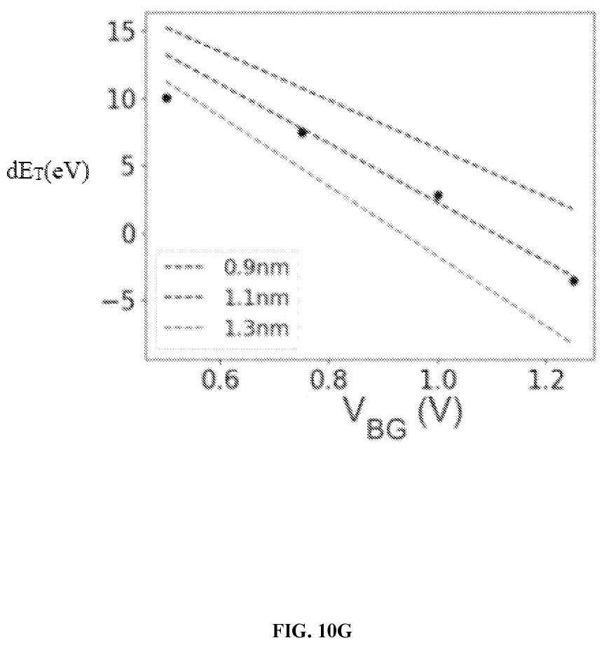

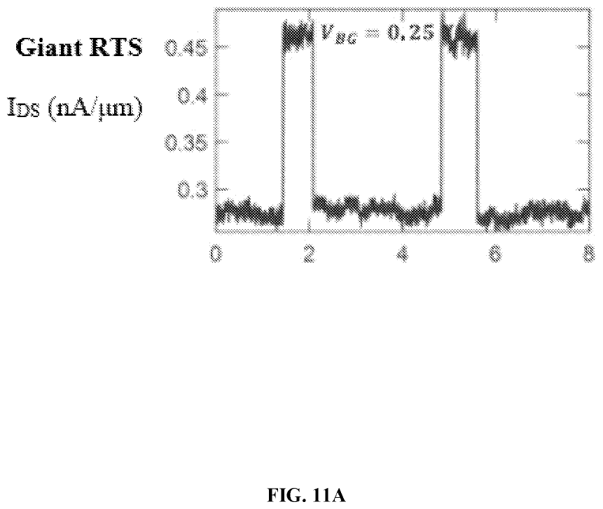

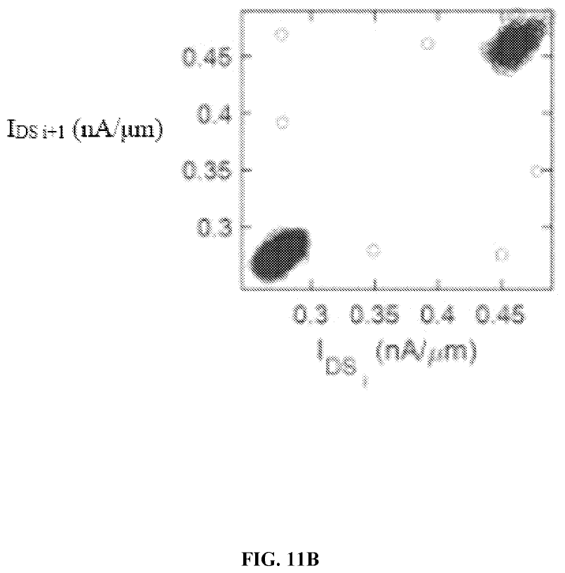

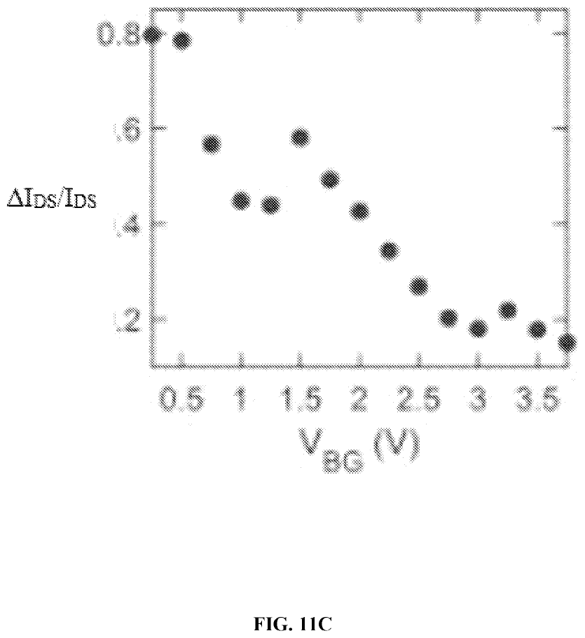

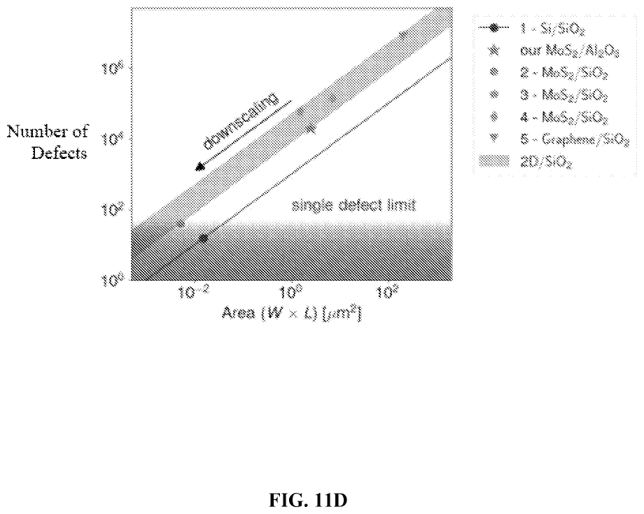

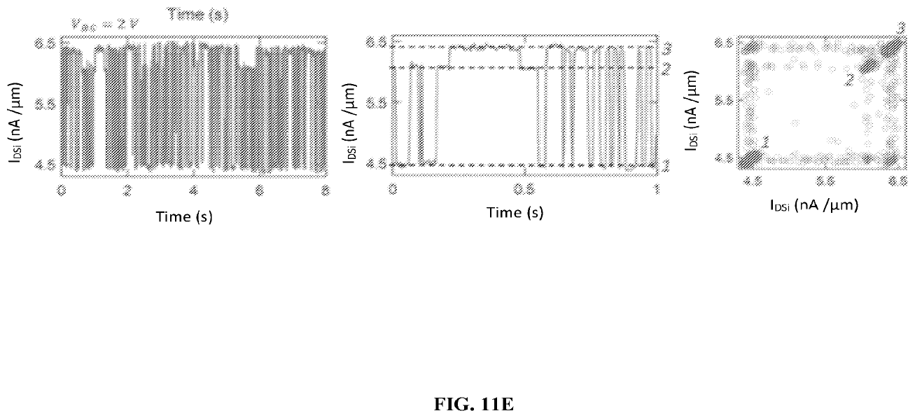

out-of-plane A_{1g} modes at 304 cm⁻¹ and 402 cm⁻¹ respectively, with a peak-to-peak distance of ˜18 cm⁻¹. Raman maps for (FIG. 7B)

$${E}_{2 g}^{1}$$

and (FIG. 7C) A_{1g} peak positions measured over a 50 μm×50 μm area. The mean and standard deviation values are shown in the inset. FIG. 7D shows photoluminescence (PL) spectra with characteristic monolayer peak at 1.82 eV. FIG. 7E shows a colormap for the PL peak position, measured over a 50 μm×50 μm area. The mean PL peak position was found to be at ˜1.83 eV with a standard deviation of ˜0.001 eV. FIG. 7 F shows atomic force microscopy (AFM) micrographs of the MoS₂ film indicating a coalesced monolayer film with a few oriented bilayer domains on top and a thickness of ˜0.7 nm. FIG. 7G shows a schematic of the MoS₂ FET with 50 nm atomic layer deposition grown Al₂O₃ as the gate dielectric and Pt/TiN/p⁺⁺-Si as the back-gate. The channel length (L) and width (W) were defined to be 500 nm and 5 μm, respectively. FIG. 7H shows transfer characteristics i.e., source-to-drain current (I_{DS}) versus back-gate voltage (V_{BG}) measured at a source-to-drain voltage, V_{DS}=1 V, for a representative MoS₂ FET at room temperature (T=300 K). FIG. 7I shows output characteristics, i.e., I_{DS} versus I_{DS} measured using different V_{BG} for the same representative FET.

FIGS. 8A-8E show observation of random telegraph signals (RTS) in monolayer MoS₂ FET. FIG. 8A shows transfer characteristics of a monolayer MoS₂ FET measured using V_{DS}=1 V at different temperatures, T=15, 50, 100, 200, and 300 K and (FIG. 8B) corresponding I_{DS} sampled every σₛ=4 ms at V_{BG}=1.5, 1.5, 0.75, −0.25, and −2 V, respectively. RTS is observed for T<200 K. FIG. 8C shows power spectral density (PSD) obtained using the fast Fourier transform (FFT) of I_{DS} in FIG. 8B. Presence of RTS is associated with a Lorentzian profile in the frequency domain, i.e., slope=1/ƒ², whereas absence of RTS is associated with a flicker noise profile in the frequency domain, i.e., slope=1/ƒ. FIG. 8D shows a histogram plot for I_{DS} in FIG. 8B. Presence of RTS is associated with two distinct Gaussian distributions, whereas absence of RTS is associated with a single Gaussian distribution. FIG. 8E shows a Time Lag Plot (TLP) for I_{DS} in FIG. 8B. TLP involves the plotting of time-domain I_{DS} data in an x-y plane, where the x-values represent the i^{th} and the y-values represent the i+1^{th} time series data for I_{DS}. In a strictly, two-level state transition dynamics, corresponding to a single defect, one would expect a rectangular TLP with only the four corner points. However, at any finite temperature, the discrete current points transform into clusters, whereas the transition points get distributed along the arms of the rectangular feature. As the temperature increases, the clusters start to spread more and eventually coalesce into a single diagonal line as seen from the TLPs corresponding to the I_{DS} measured at T >200 K.

FIGS. 9A-9G show gate-bias dependent RTS for extracting energetic and physical location of defect. FIG. 9A shows RTS traces and FIG. 9B shows corresponding TLPs obtained for V_{BG}=0.5, 1, and 1.5 V at T=15 K. The V_{BG} range was chosen such that the two-state defect dynamics dominate. Here, the time spent in the lower state is referred to as the capture time and the time spent in the upper state as the emission time, i.e., τ_{c} and τₑ, respectively. Normalized histogram plots on a logarithmic time scale for (FIG. 9C) τ_{c} and (FIG. 9D) τₑ showing the probability density of observing an event with a certain time constant. Insets show the Gaussian kernel density estimates used for extracting t̅_̅{̅c̅}̅ and t̅ₑ̅. FIG. 9E shows the and the as a function V_{BG}. FIG. 9F shows the relative energetic location of the defect with respect to the Fermi level in the semiconducting channel, i.e., E_{T}−E_{F} as a function of V_{BG}. FIG. 9G shows t̅ₑ̅ and t̅_̅{̅c̅}̅ as a function of V_{BG} at temperatures of 15 K, 50 K and 100 K.

FIG. 10A-10G shows modeling the temperature and gate-bias dependence to extract vibronic defect properties. FIG. 10A shows a configuration coordinate diagram for the transition of the defect configuration between the charged and the uncharged states. FIG. 10B shows a band diagram for Al₂O₃ and MoS₂ showing the energetic alignment of the trap level E_{T}, that is shifted by the applied gate bias at a gate contact to the left of the diagram. Modeled time constants as a function of temperature for different gate biases of (FIG. 10C) V_{BG}=0.5 V, (FIG. 10D) 0.75 V, (FIG. 10E) 1 V and (FIG. 10F) 1.25 V. For a relaxation energy of Eᵣₑₗₐₓ=0.31 eV and a configuration coordinate distance of ΔQ=2.03 Å\sqrt{u}, the root mean square error amounts to 0.15 s. FIG. 10G shows the shift E_{T} of the charged state α as a function of the gate bias corresponds to a distance of 1.1 nm for the charge trap from the interface.

FIGS. 11A-11E show rich defect dynamics in monolayer MoS₂ FET. FIG. 11A shows giant RTS measured at T=15 K at a V_{BG}=1.5 V. The

$$\frac{Δ {I}_{DS}}{{I}_{DS}}$$

was found to be ˜80% FIG. 11B shows corresponding TLP indicating the two discrete current levels. FIG. 11C shows

$$\frac{Δ {I}_{DS}}{{I}_{DS}}$$

as a function of V_{BG}. RTS is expected if the number of defects within the device falls into the red shaded area, the single defect limit as shown in FIG. 11D. For the MoS₂/Al₂O₃FETs studied here, 20,000 active defects are expected to be located within the device area. As the single-defect limit is not reached, an effectively locally narrowed channel region is observed. The border trap densities shown as symbols are taken from literature. Anomalous RTS and corresponding TLPs showing (FIG. 11E) three discrete current levels. The RTS and the corresponding TLP in FIG. 11E indicate the involvement of a metastable state in addition to one regular trap state.

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

An exemplary embodiment related to an s-bit generator 100. The s-bit generator 100 can include plural memtransistors 200 (e.g., 2D memtransistors), an inverting amplifier 300 (e.g., a differential amplifier in which the circuit's non-inverting input is grounded), and a programmable threshold inverter 400 (e.g., a circuit in which the output is switched from 0 to Vad when input is less than Vₜₕ such that for 0<Vᵢₙ<Vₜₕ output is equal to logic 0 input and Vₜₕ<Vᵢₙ<V_{dd} is equal to logic 1 input for inverter). One or more s-bits can be generated from inherent stochasticity in the plural 2D memtransistors. As can be appreciated from the disclosure herein, circuit topologies can be configured with the plural memtransistors 200 to provide the inverting amplifier 300 and/or the threshold inverter 400. For instance, in some embodiments, the s-bit generator 100 can consist of plural memtransistors 200, wherein some of the memtransistors 200 form the inverting amplifier 300 and/or the threshold inverter 400. Other embodiments of the s-bit generator 100 can have inverting amplifier 300 and/or the threshold inverter 400 that is/are not formed by memtransistors 200.

Inherent stochasticity in the plural 2D memtransistors 200 can include one or more of: cycle-to-cycle fluctuations in carrier trapping and detrapping phenomena in a gate insulator of a 2D memtransistor of the plural 2D memtransistor, thermal conductance fluctuations in a defect-engineered and scaled 2D memtransistor of the plural 2D memtransistors, and/or random telegraph signals (RTS) in a defect-engineered and scaled 2D memtransistor of the plural 2D memtransistors.

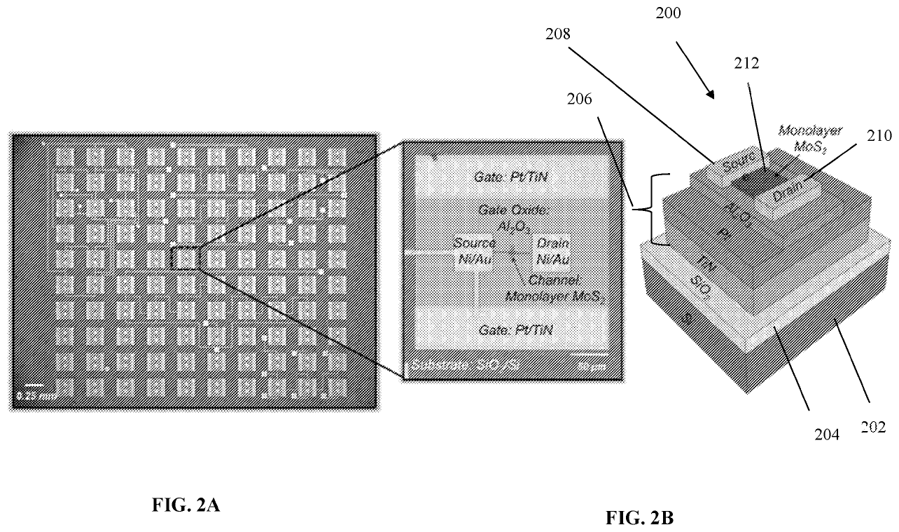

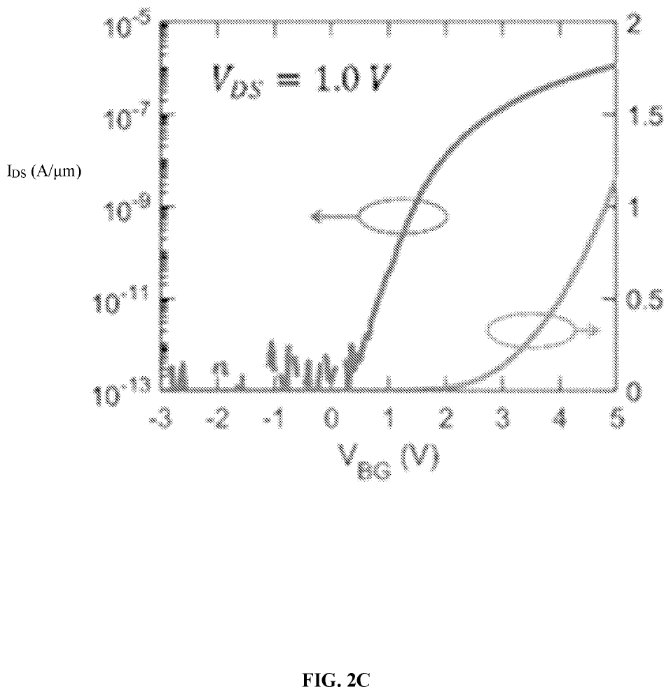

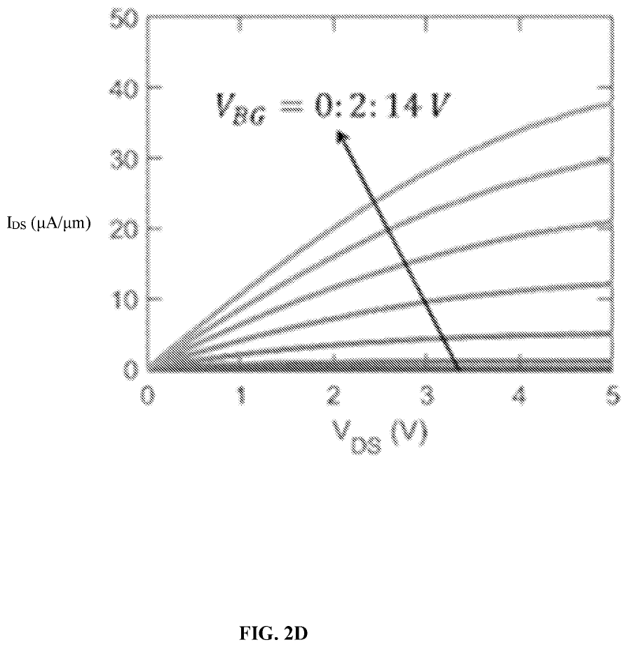

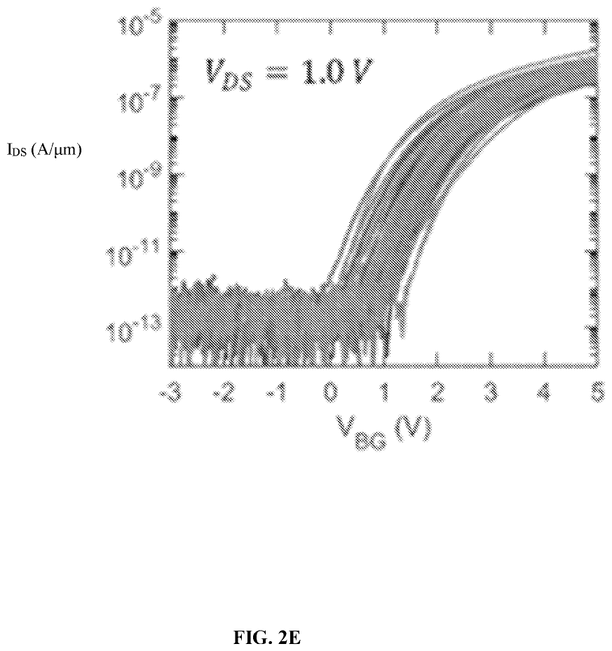

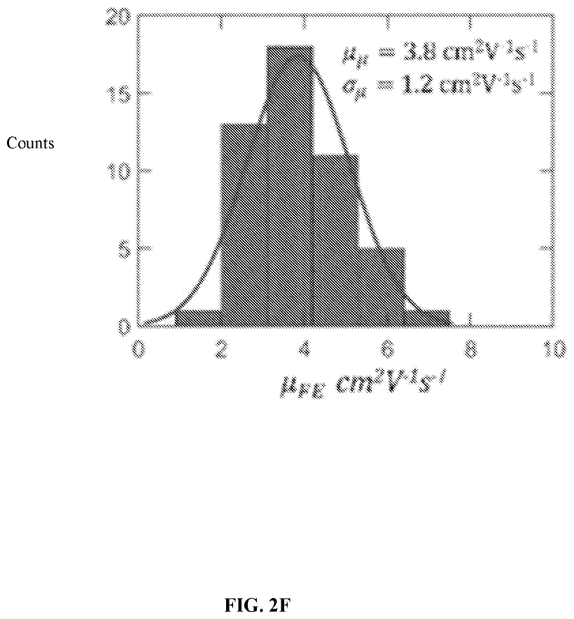

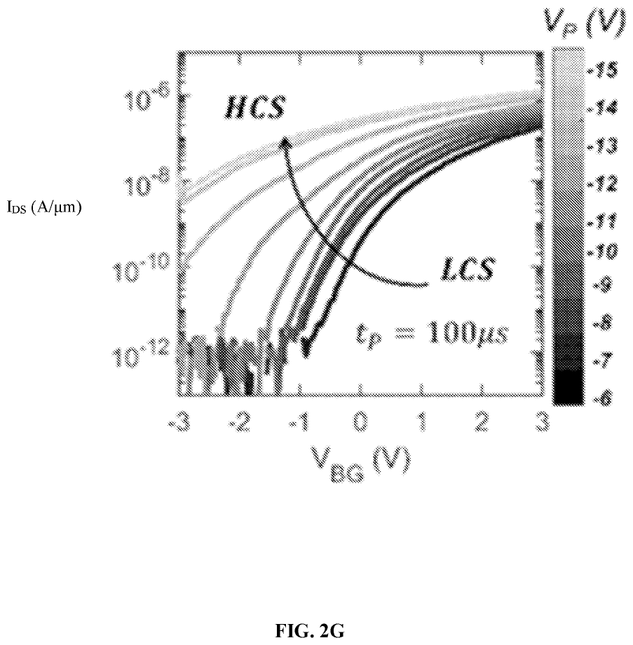

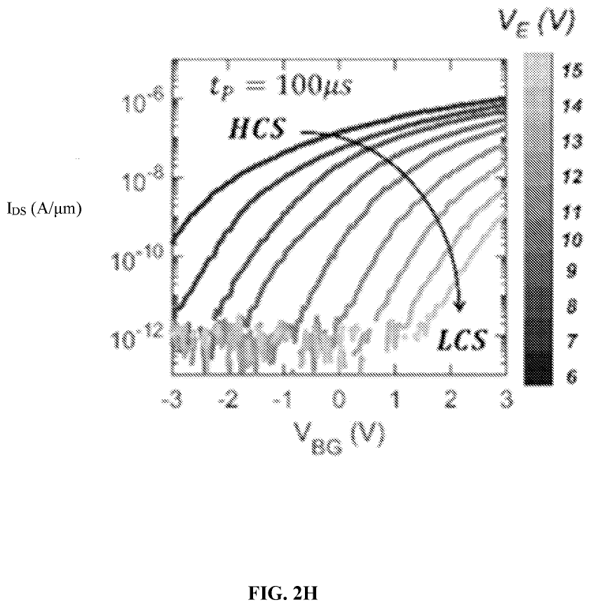

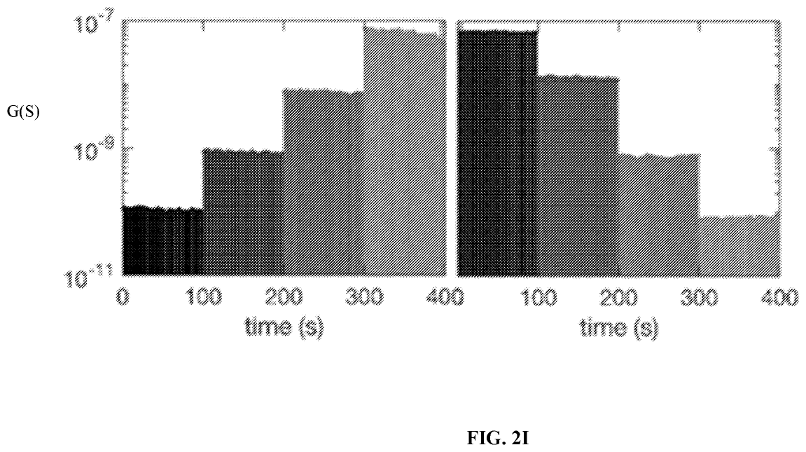

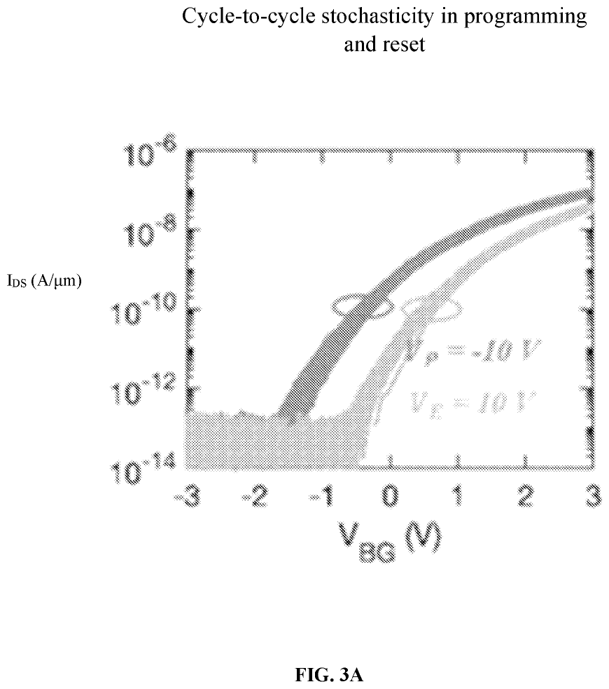

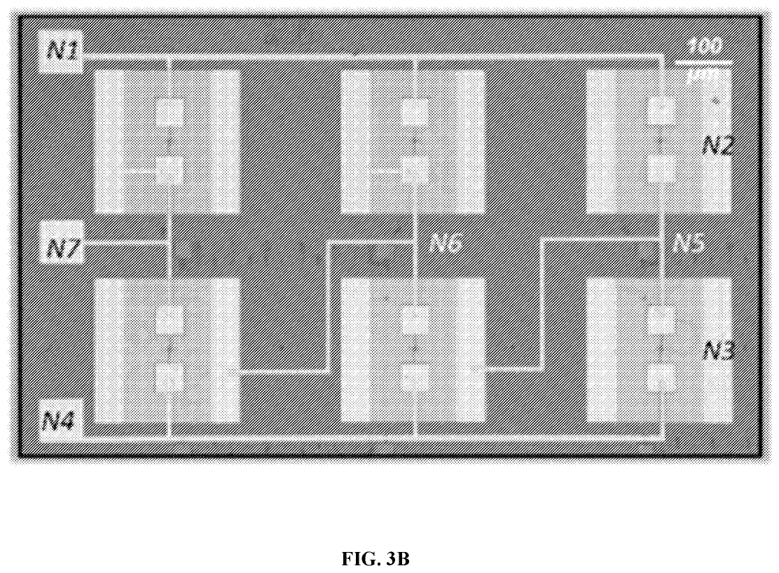

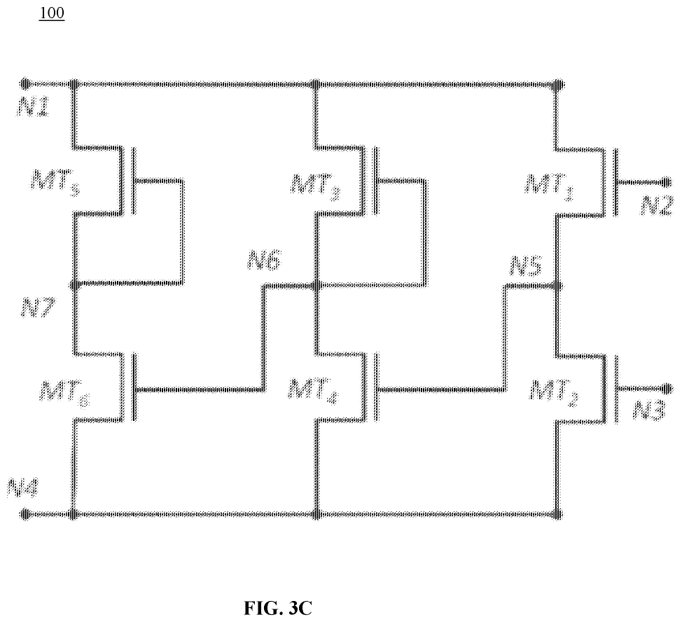

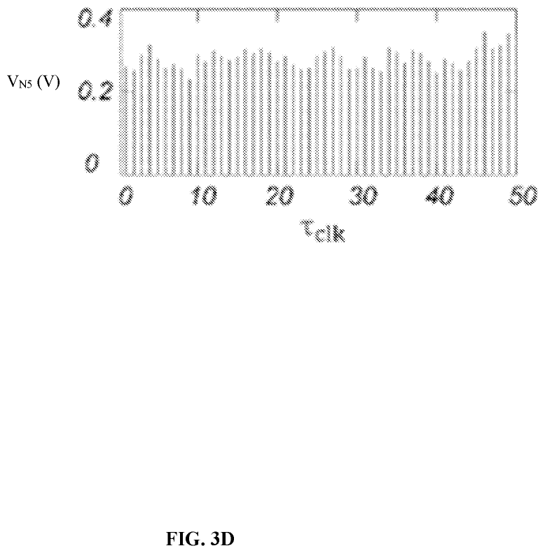

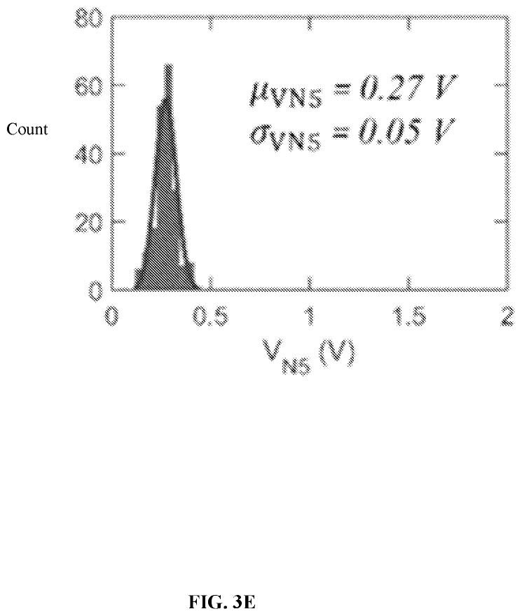

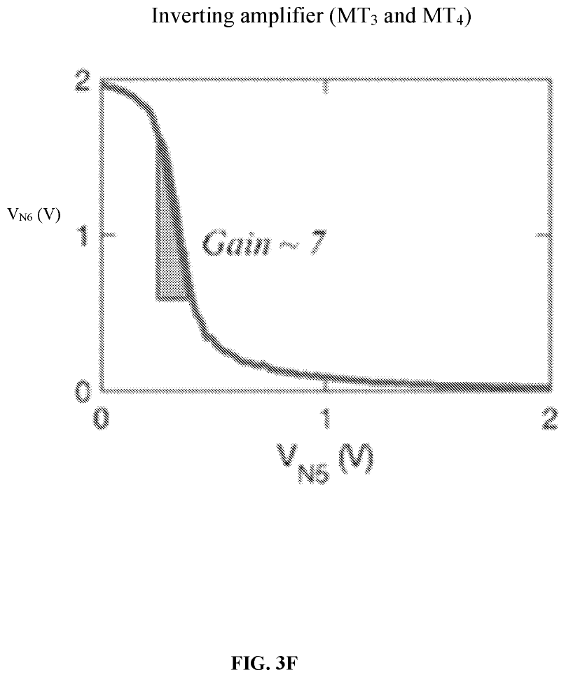

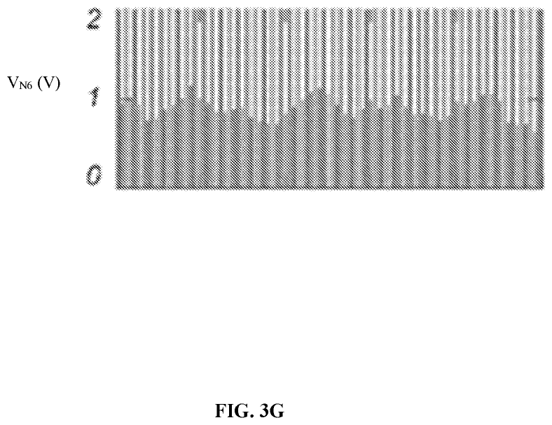

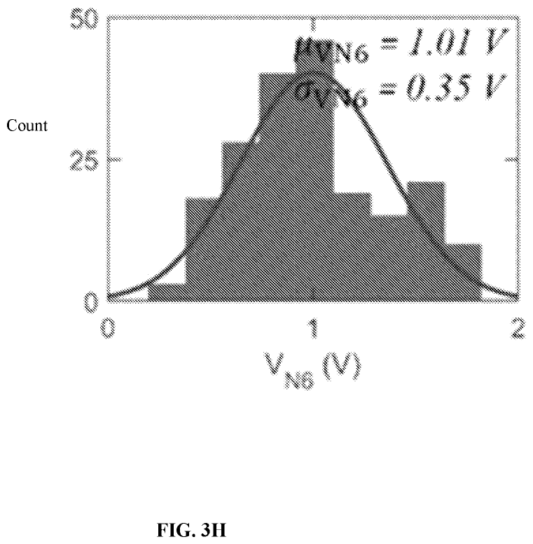

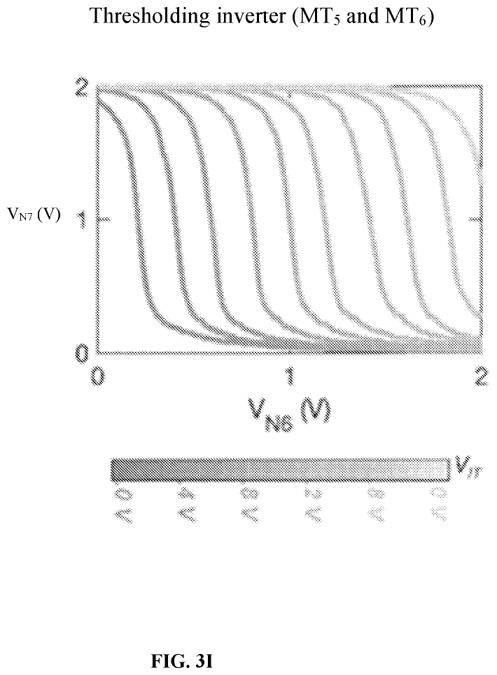

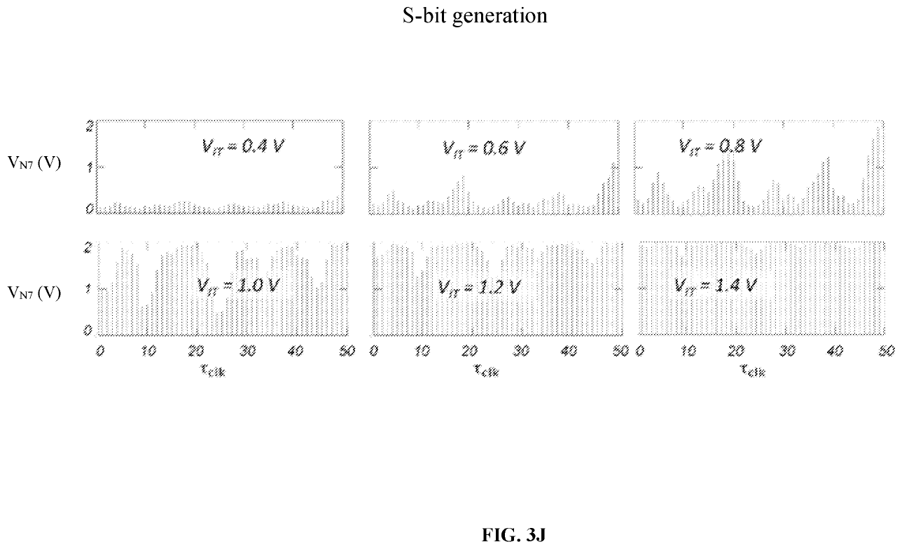

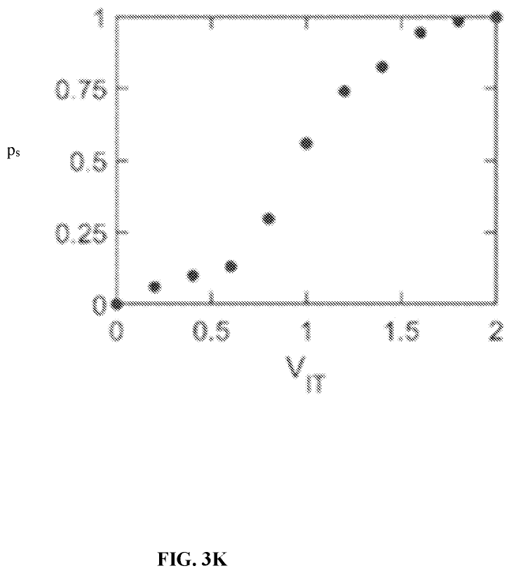

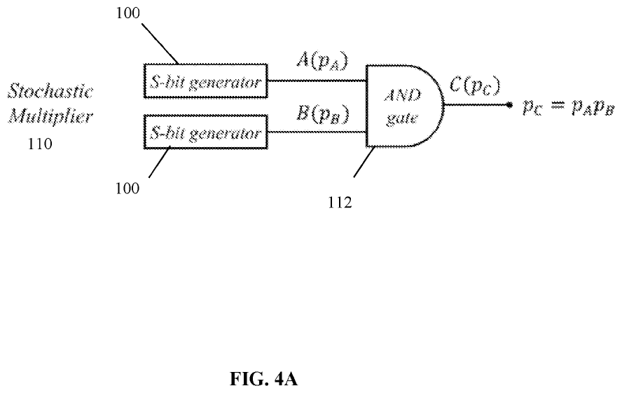

Referring to FIGS. 2A, 2B, 3B, and 3C exemplary embodiments can relate to a s-bit generator 100. The s-bit generator 100 can include one or more memtransistors. For instance, the s-bit generator 100 can include a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. One or more of the memtransistors can be stacked on a non-volatile and programmable local back-gate stack. One or more of the memtransistors\ can have a 2D channel formed between its source and its drain.

As shown in FIG. 2B, each memtransistor 200 can be formed on a substrate 202 (e.g., Si). The substrate 202 can have an oxide layer 204 (e.g., SiO₂) formed on a surface of the substrate 202. An island layer 206 can be formed on a surface of the oxide layer 204. In an exemplary embodiment, the island layer 206 can be Al₂O₃/Pt/TiN (e.g., TiN can be formed on a surface of the oxide layer 204, Pt can be formed on a surface of the TiN layer, and Al₂O₃ can be formed on a surface of the TiN layer). A source 208 (e.g., Ni/Au, a drain 210 (e.g., Ni/Au), and a channel 212 (e.g., MoS₂) can be formed on a surface of the island layer 206. Each of source 208, the drain 210, and the channel 212 can be form on the surface of the island layer 206, wherein the source 208 and drain 210 subtend each other and are adjacent the channel 212.

In an exemplary embodiment, MT1-drain can be connected to: MT3-drain, MT5-drain, and node N1. MT1-gate can be connected to node N2. MT1-source can be connected to: MT2-drain and MT4-gate via node N5. MT2-drain can be connected to MT4-gate via node N5. MT2-gate can be connected to node N3. MT2-source can be connected to: MT4-source, MT6-source, and node N4. MT3-drain can be connected to: MT1-drain, MT5-drain, and node N1. MT3-gate can be connected to MT6-gate via node N6. MT3-source can be connected to: MT6-gate via node N6 and MT4-drain via node N6. MT4-drain can be connected to: MT3-source via node N6, MT3-gate via node N6, and MT6-gate via node N6. MT4-gate can be connected to: MT1-source via node N5 and MT2-drain via node N5. MT4-source can be connected to: MT2-source, MT6-source, and node N4. MT5-drain can be connected to: MT1-drain, MT3-drain, and node N1. MT5-gate can be connected to MT6-drain via node N7. MT6-drain can be connected to: MT5-source via node N7 and MT5-gate via node N7. MT6-gate can be connected to: MT3-source via node N6, MT3-gate via node N6, and MT4-drain via node N6. MT6-source can be connected to: MT4-source, MT2-source, and node N4.

In some embodiments, the 2D channel is a monolayer.

In some embodiments, the monolayer includes MoS₂.

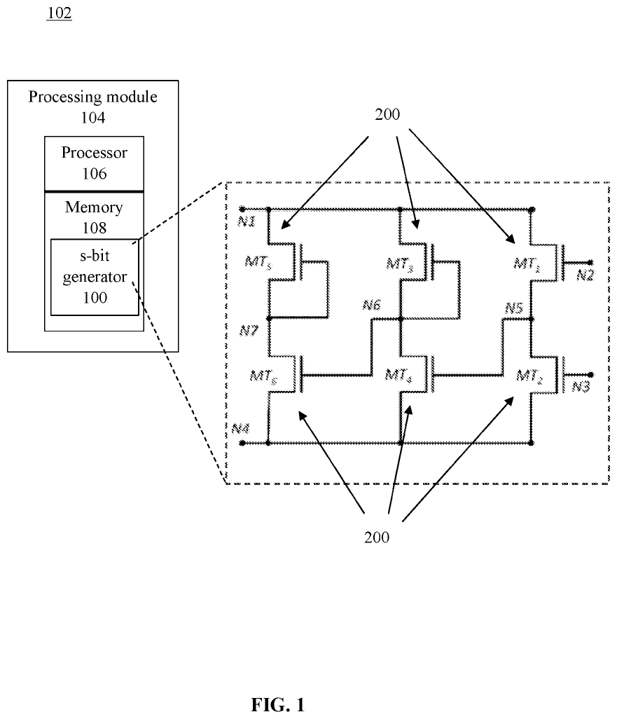

Referring to FIG. 1, an exemplary embodiment can relate to a stochastic computing processor 102. The stochastic computing processor 102 can include a processing module 104 having a processor 106 and a memory 108. The stochastic computing processor 102 can include plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor can be stacked on a non-volatile and programmable local back-gate stack. Each memtransistor can have a 2D channel formed between its source and its drain. MT1-drain can be connected to: MT3-drain, MT5-drain, and node N1. MT1-gate is connected to node N2. MT1-source can be connected to: MT2-drain and MT4-gate via node N5. MT2-drain can be connected to MT4-gate via node N5. MT2-gate can be connected to node N3. MT2-source can be connected to: MT4-source, MT6-source, and node N4. MT3-drain can be connected to: MT1-drain, MT5-drain, and node N1. MT3-gate can be connected to MT6-gate via node N6. MT3-source can be connected to: MT6-gate via node N6 and MT4-drain via node N6. MT4-drain can be connected to: MT3-source via node N6, MT3-gate via node N6, and MT6-gate via node N6. MT4-gate can be connected to: MT1-source via node N5 and MT2-drain via node N5. MT4-source is connected to: MT2-source, MT6-source, and node N4. MT5-drain can be connected to: MT1-drain, MT3-drain, and node N1. MT5-gate can be connected to MT6-drain via node N7. MT6-drain can be connected to: MT5-source via node N7 and MT5-gate via node N7. MT6-gate can be connected to: MT3-source via node N6, MT3-gate via node N6, and MT4-drain via node N6. MT6-source can be connected to: MT4-source, MT2-source, and node N4.

In some embodiments, the stochastic computing processor can have a non-von Neuman architecture. A von Neumann architecture generally consists of a single, shared memory for programs and data, a single bus for memory access, an arithmetic unit, and a program control unit. A non-von Neumann architecture deviates from this arrangement.

Any of the processors 106 disclosed herein can be part of or in communication with a machine (e.g., a computer device, a logic device, a circuit, an operating module (hardware, software, and/or firmware), etc.). The processor 106 can be hardware (e.g., processor, integrated circuit, central processing unit, microprocessor, core processor, computer device, etc.), firmware, software, etc. configured to perform operations by execution of instructions embodied in computer program code, algorithms, program logic, control, logic, data processing program logic, artificial intelligence programming, machine learning programming, artificial neural network programming, automated reasoning programming, etc. The processor 106 can receive, process, and/or store data.

Any of the processors 106 disclosed herein can be a scalable processor, a parallelizable processor, a multi-thread processing processor, etc. The processor 106 can be a computer in which the processing power is selected as a function of anticipated network traffic (e.g. data flow). The processor 106 can include any integrated circuit or other electronic device (or collection of devices) capable of performing an operation on at least one instruction, which can include a Reduced Instruction Set Core (RISC) processor, a Complex Instruction Set Computer (CISC) microprocessor, a Microcontroller Unit (MCU), a CISC-based Central Processing Unit (CPU), a Digital Signal Processor (DSP), a Graphics Processing Unit (GPU), a Field Programmable Gate Array (FPGA), etc. The hardware of such devices may be integrated onto a single substrate (e.g., silicon “die”), or distributed among two or more substrates. Various functional aspects of the processor may be implemented solely as software or firmware associated with the processor 106.

The processor 106 can include one or more processing or operating modules. A processing or operating module can be a software or firmware operating module configured to implement any of the functions disclosed herein. The processing or operating module can be embodied as software and stored in memory 108, the memory 108 being operatively associated with the processor 106. A processing module can be embodied as a web application, a desktop application, a console application, etc.

The processor 106 can include or be associated with a computer or machine readable medium. The computer or machine readable medium can include memory 108. Any of the memory 108 discussed herein can be computer readable memory configured to store data. The memory 108 can include a volatile or non-volatile, transitory or non-transitory memory, and be embodied as an in-memory, an active memory, a cloud memory, etc. Examples of memory 108 can include flash memory, Random Access Memory (RAM), Read Only Memory (ROM), Programmable Read only Memory (PROM), Erasable Programmable Read only Memory (EPROM), Electronically Erasable Programmable Read only Memory (EEPROM), FLASH-EPROM, Compact Disc (CD)-ROM, Digital Optical Disc DVD), optical storage, optical medium, a carrier wave, magnetic cassettes, magnetic tape, magnetic disk storage or other magnetic storage devices, or any other medium which can be used to store the desired information and which can accessed by the processor 106.

The memory 108 can be a non-transitory computer-readable medium. The term “computer-readable medium” (or “machine-readable medium”) as used herein is an extensible term that refers to any medium or any memory 108, that participates in providing instructions to the processor for execution, or any mechanism for storing or transmitting information in a form readable by a machine (e.g., a computer). Such a medium may store computer-executable instructions to be executed by a processing element and/or control logic, and data which is manipulated by a processing element and/or control logic, and may take many forms, including but not limited to, non-volatile medium, volatile medium, transmission media, etc. The computer or machine readable medium can be configured to store one or more instructions thereon. The instructions can be in the form of algorithms, program logic, etc. that cause the processor 106 to execute any of the functions disclosed herein.

Embodiments of the memory 108 can include a processor module and other circuitry to allow for the transfer of data to and from the memory 108, which can include to and from other components of a communication system. This transfer can be via hardwire or wireless transmission. The communication system can include transceivers, which can be used in combination with switches, receivers, transmitters, routers, gateways, wave-guides, etc. to facilitate communications via a communication approach or protocol for controlled and coordinated signal transmission and processing to any other component or combination of components of the communication system. The transmission can be via a communication link. The communication link can be electronic-based, optical-based, opto-electronic-based, quantum-based, etc. Communications can be via Bluetooth, near field communications, cellular communications, telemetry communications, Internet communications, etc.

Transmission of data and signals can be via transmission media. Transmission media can include coaxial cables, copper wire, fiber optics, etc. Transmission media can also take the form of acoustic or light waves, such as those generated during radio-wave and infrared data communications, or other form of propagated signals (e.g., carrier waves, digital signals, etc.).

Any of the processors 106 can be in communication with other processors of other devices (e.g., a computer device, a computer system, a laptop computer, a desktop computer, etc.). Any of the processors 106 can have transceivers or other communication devices/circuitry to facilitate transmission and reception of wireless signals. Any of the processors 106 can include an Application Programming Interface (API) as a software intermediary that allows two or more applications to talk to each other.

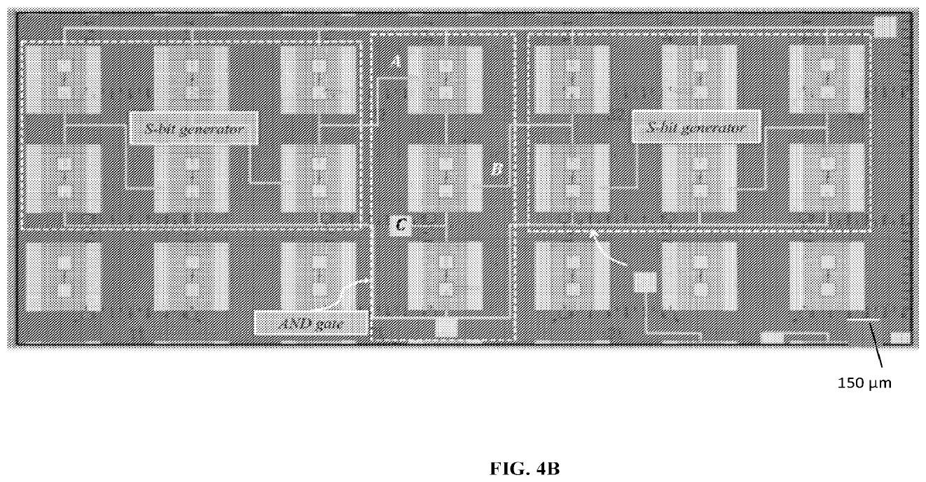

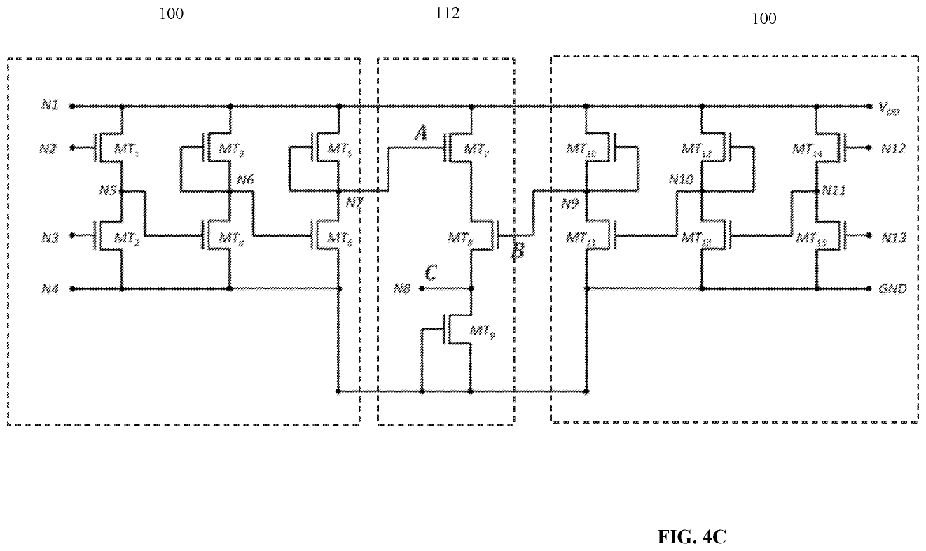

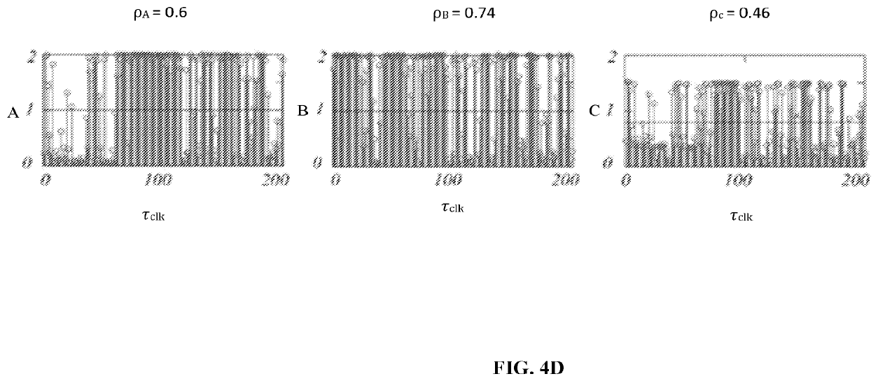

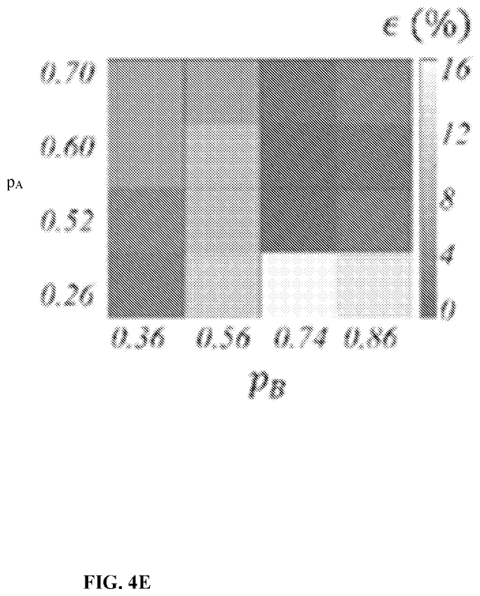

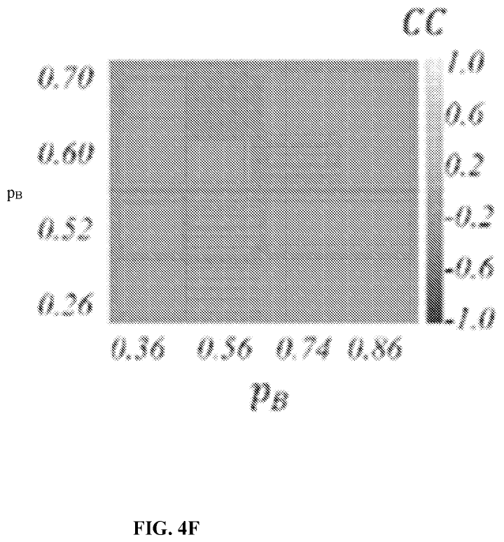

Referring to FIGS. 4A, 4B, and 4C, an exemplary embodiment can relate to a stochastic multiplier 110. The stochastic multiplier 110 can include a first s-bit generator 100 having plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor can be stacked on a non-volatile and programmable local back-gate stack. Each memtransistor can have a 2D channel formed between its source and its drain. MT1-drain can be connected to: MT3-drain, MT5-drain, and node N1. MT1-gate can be connected to node N2. MT1-source can be connected to: MT2-drain and MT4-gate via node N5. MT2-drain can be connected to MT4-gate via node N5. MT2-gate can be connected to node N3. MT2-source can be connected to: MT4-source, MT6-source, and node N4. MT3-drain can be connected to: MT1-drain, MT5-drain, and node N1. MT3-gate can be connected to MT6-gate via node N6. MT3-source can be connected to: MT6-gate via node N6 and MT4-drain via node N6. MT4-drain can be connected to: MT3-source via node N6, MT3-gate via node N6, and MT6-gate via node N6. MT4-gate can be connected to: MT1-source via node N5 and MT2-drain via node N5. MT4-source can be connected to: MT2-source, MT6-source, and node N4. MT5-drain can be connected to: MT1-drain, MT3-drain, and node N1. MT5-gate can be connected to MT6-drain via node N7. MT6-drain can be connected to: MT5-source via node N7 and MT5-gate via node N7. MT6-gate can be connected to: MT3-source via node N6, MT3-gate via node N6, and MT4-drain via node N6. MT6-source can be connected to: MT4-source, MT2-source, and node N4. The first s-bit generator can be configured to generate an output A at node N7. The stochastic multiplier 110 can include a second s-bit generator having plural memtransistors, comprising: a memtransistor, MT14, having a MT14-drain, a MT14-source, and a MT14-gate; a memtransistor, MT15, having a MT15-drain, a MT15-source, and a MT15-gate; a memtransistor, MT12, having a MT12-drain, a MT12-source, and a MT12-gate; a memtransistor, MT13, having a MT13-drain, a MT13-source, and a MT13-gate; a memtransistor, MT10, having a MT10-drain, a MT10-source, and a MT10-gate; and a memtransistor, MT1, having a MT11-drain, a MT11-source, and a MT1-gate. Each memtransistor can be stacked on a non-volatile and programmable local back-gate stack. Each memtransistor can have a 2D channel formed between its source and its drain. MT14-drain can be connected to: MT12-drain, MT10-drain, and V_{DD}. MT14-gate is connected to node N12. MT14-source can be connected to: MT15-drain and MT13-gate via node N11. MT15-drain can be connected to MT13-gate via node N11. MT15-gate can be connected to node N13. MT15-source can be connected to: MT13-source, MT11-source, and GND. MT12-drain can be connected to: MT14-drain, MT10-drain, and V_{DD}. MT12-gate can be connected to MT1-gate via node N10. MT12-source can be connected to: MT1-gate via node N10 and MT13-drain via node N10. MT13-drain can be connected to: MT12-source via node N10, MT12-gate via node N10, and MT1-gate via node N10. MT13-gate is connected to: MT14-source via node N11 and MT15-drain via node N11. MT13-source can be connected to: MT14-source, MT11-source, and GND. MT10-drain can be connected to: MT14-drain, MT12-drain, and V_{DD}. MT10-gate can be connected to MT11-drain via node N9. MT11-drain can be connected to: MT10-source via node N9 and MT10-gate via node N9. MT1-gate can be connected to: MT12-source via node N10, MT12-gate via node N10, and MT13-drain via node N10. MT11-source can be connected to: MT13-source, MT15-source, and GND. The second s-bit generator configured to generate an output B at node N9. The stochastic multiplier 110 can include an AND gate configured to receive output A, receive output B, and generate an output C.

In some embodiments, the AND gate 112 can include plural memtransistors, comprising: a memtransistor, MT7, having a MT7-drain, a MT7-source, and a MT7-gate; a memtransistor, MT8, having a MT8-drain, a MT8-source, and a MT8-gate; and a memtransistor, MT9, having a MT9-drain, a MT9-source, and a MT9-gate.

For the first s-bit generator 100: output A is transmitted to the AND gate 112 via node N7; node N7 is connected to MT7-gate; MT1-drain, MT3-drain, and MT5-drain are connected to MT7-drain; and MT2-source, MT4-source, and MT6-source are connected to: MT9-gate and to MT9-source. For the second s-bit generator 100: output B is transmitted to the AND gate via node N9; node N7 is connected to MT8-gate; MT10-drain, MT12-drain, and MT14-drain are connected to MT7-drain; and MT14-source, MT13-source, and MT11-source are connected to: MT9-gate and to MT9-source. For the AND gate 112: MT7-source is connected to MT8-drain; MT8-source connected to MT9-drain and to node N8; and the AND gate outputs C at node N8.

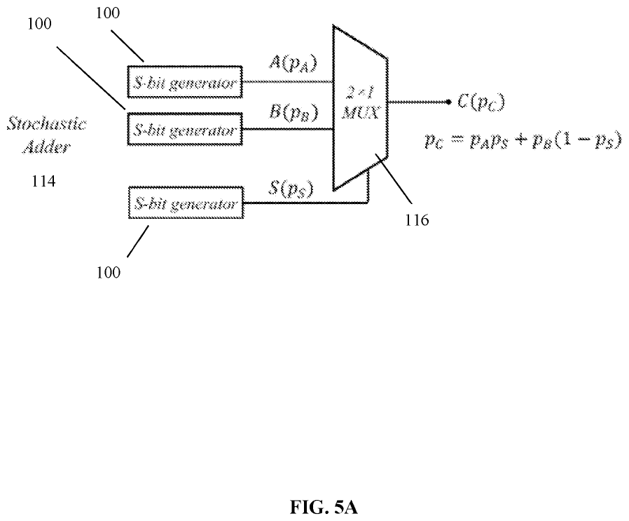

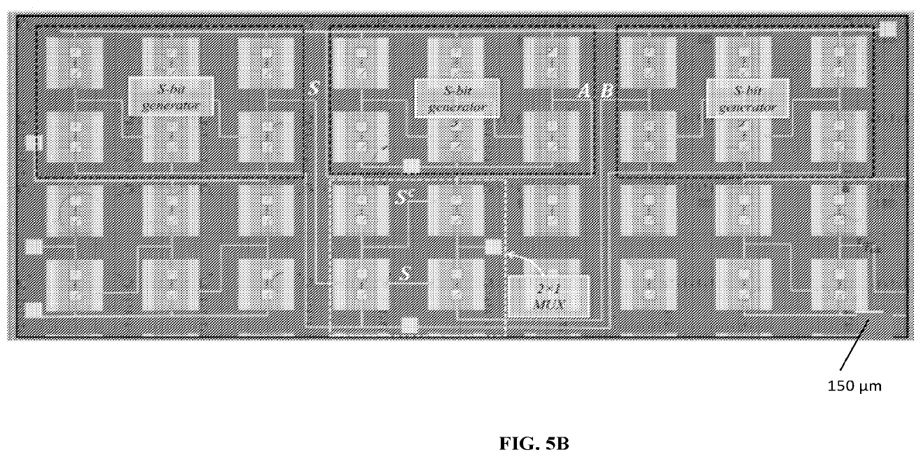

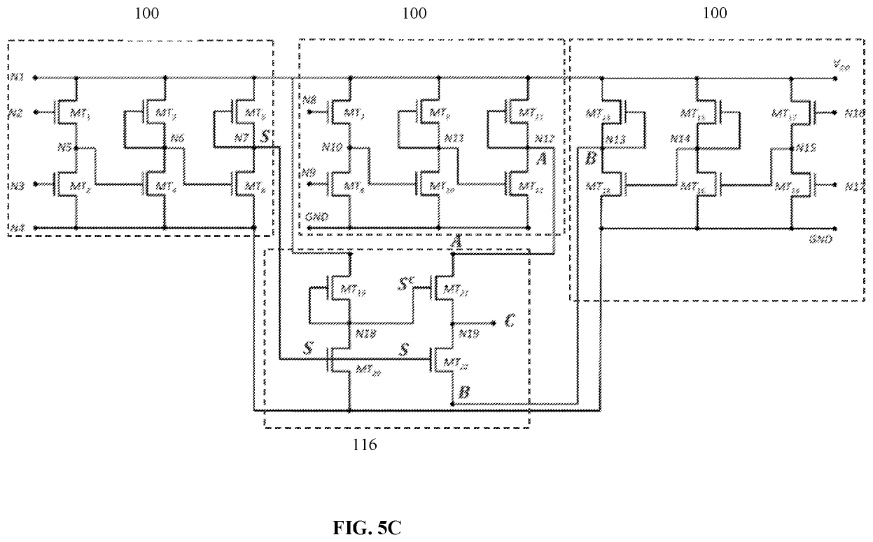

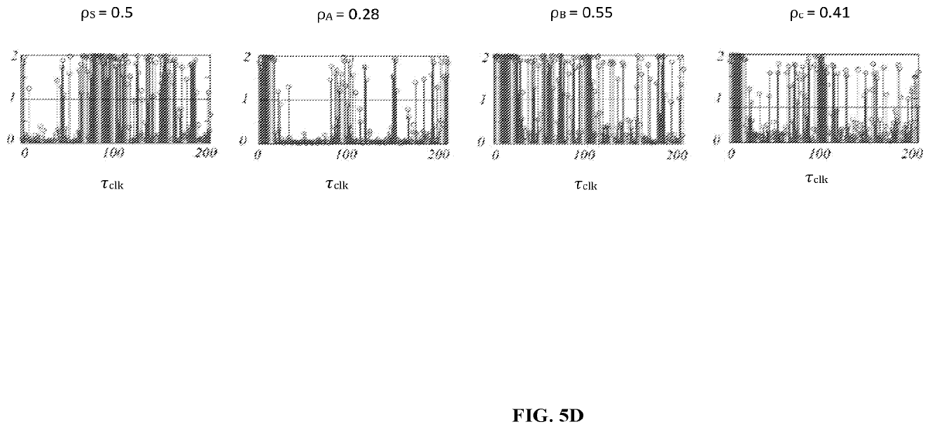

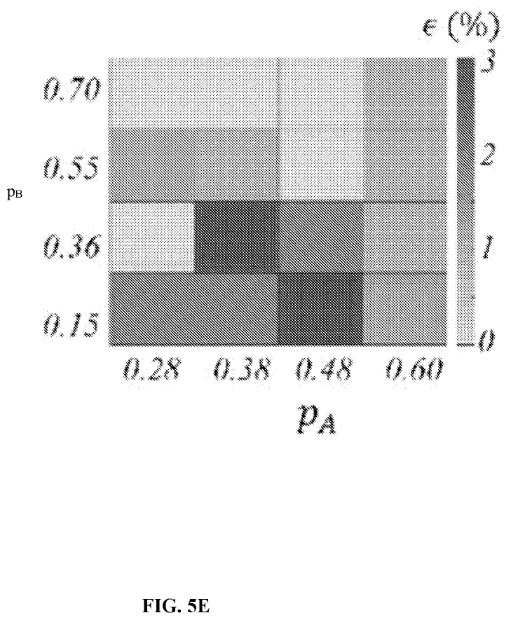

Referring to FIGS. 5A, 5B, and 5C, an exemplary embodiment can relate to a stochastic adder 114. The stochastic adder 114 can include a first s-bit generator 100 having plural memtransistors, comprising: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor can be stacked on a non-volatile and programmable local back-gate stack. Each memtransistor can have a 2D channel formed between its source and its drain. MT1-drain can be connected to: MT3-drain, MT5-drain, and node N1. MT1-gate is connected to node N2. MT1-source can be connected to: MT2-drain and MT4-gate via node N5. MT2-drain can be connected to MT4-gate via node N5. MT2-gate can be connected to node N3. MT2-source can be connected to: MT4-source, MT6-source, and node N4. MT3-drain can be connected to: MT1-drain, MT5-drain, and node N1. MT3-gate can be connected to MT6-gate via node N6. MT3-source can be connected to: MT6-gate via node N6 and MT4-drain via node N6. MT4-drain can be connected to: MT3-source via node N6, MT3-gate via node N6, and MT6-gate via node N6. MT4-gate can be connected to: MT1-source via node N5 and MT2-drain via node N5. MT4-source can be connected to: MT2-source, MT6-source, and node N4. MT5-drain can be connected to: MT1-drain, MT3-drain, and node N1. MT5-gate can be connected to MT6-drain via node N7. MT6-drain can be connected to: MT5-source via node N7 and MT5-gate via node N7. MT6-gate can be connected to: MT3-source via node N6, MT3-gate via node N6, and MT4-drain via node N6. MT6-source can be connected to: MT4-source, MT2-source, and node N4. The first s-bit generator 100 can be configured to generate an output S. The stochastic adder 114 can include a second s-bit generator 100 having plural memtransistors, comprising: a memtransistor, MT7, having a MT7-drain, a MT7-source, and a MT7-gate; a memtransistor, MT8, having a MT8-drain, a MT8-source, and a MT8-gate; a memtransistor, MT9, having a MT9-drain, a MT9-source, and a MT9-gate; a memtransistor, MT10, having a MT10-drain, a MT10-source, and a MT10-gate; a memtransistor, MT1, having a MT11-drain, a MT11-source, and a MT1-gate; and a memtransistor, MT12, having a MT12-drain, a MT12-source, and a MT12-gate. Each memtransistor can be stacked on a non-volatile and programmable local back-gate stack. Each memtransistor can have a 2D channel formed between its source and its drain. MT7-drain can be connected to: MT9-drain, MT11-drain, and node V_{DD}. MT7-gate can be connected to node N8. MT7-source can be connected to: MT8-drain and MT10-gate via node N10. MT8-drain can be connected to MT10-gate via node N10. MT2-gate can be connected to node N3. MT8-source can be connected to: MT10-source, MT12-source, and GND. MT9-drain can be connected to: MT7-drain, MT11-drain, and V_{DD}. MT9-gate can be connected to MT12-gate via node N11. MT9-source can be connected to: MT12-gate via node N11 and MT10-drain via node N11. MT10-drain can be connected to: MT9-source via node N11, MT9-gate via node N11, and MT12-gate via node N11. MT10-gate can be connected to: MT7-source via node N10 and MT8-drain via node N10. MT10-source i can be connected to: MT8-source, MT12-source, and GND. MT11-drain can be connected to: MT7-drain, MT9-drain, and V_{DD}. MT1-gate is connected to MT12-drain via node N12. MT12-drain can be connected to: MT11-source via node N12 and MT1-gate via node N12. MT12-gate can be connected to: MT9-source via node N11, MT9-gate via node N11, and MT10-drain via node N11. MT12-source can be connected to: MT10-source, MT8-source, and GND. The second s-bit generator 100 can be configured to generate an output A.

The stochastic adder 114 can include a third s-bit generator having plural memtransistors, comprising: a memtransistor, MT13, having a MT13-drain, a MT13-source, and a MT13-gate; a memtransistor, MT14, having a MT14-drain, a MT14-source, and a MT14-gate; a memtransistor, MT15, having a MT15-drain, a MT15-source, and a MT15-gate; a memtransistor, MT16, having a MT16-drain, a MT16-source, and a MT16-gate; a memtransistor, MT17, having a MT17-drain, a MT17-source, and a MT17-gate; and a memtransistor, MT18, having a MT18-drain, a MT18-source, and a MT18-gate. Each memtransistor can be stacked on a non-volatile and programmable local back-gate stack. Each memtransistor can have a 2D channel formed between its source and its drain. MT17-drain can be connected to: MT15-drain, MT13-drain, and V_{DD}. MT17-gate can be connected to node N16. MT17-source is connected to: MT18-drain and MT16-gate via node N15. MT18-drain can be connected to MT16-gate via node N15. MT18-gate can be connected to node N17. MT18-source can be connected to: MT16-source, MT14-source, and GND. MT15-drain can be connected to: MT17-drain, MT13-drain, and V_{DD}. MT15-gate is connected to MT14-gate via node N14. MT15-source can be connected to: MT14-gate via node N14 and MT16-drain via node N14. MT16-drain i can be connected to: MT15-source via node N14, MT15-gate via node N14, and MT14-gate via node N14. MT16-gate can be connected to: MT17-source via node N15 and MT18-drain via node N15. MT16-source can be connected to: MT14-source, MT18-source, and GND. MT13-drain can be connected to: MT17-drain, MT15-drain, and V_{DD}. MT13-gate can be connected to MT14-drain via node N13. MT14-drain can be connected to: MT13-source via node N13 and MT13-gate via node N13. MT14-gate can be connected to: MT15-source via node N14, MT15-gate via node N14, and MT16-drain via node N14. MT15-source can be connected to: MT16-source, MT18-source, and GND. The third s-bit generator 100 can be configured to generate an output B. The stochastic adder 114 can include a MUX gate 116 configured to receive output S, receive output A, receive output B, and generate an output C.

In some embodiments, the MUX gate 116 can include plural memtransistors, comprising: a memtransistor, MT19, having a MT19-drain, a MT19-source, and a MT19-gate; a memtransistor, MT20, having a MT20-drain, a MT20-source, and a MT20-gate; a memtransistor, MT21, having a MT21-drain, a MT21-source, and a MT21-gate; and a memtransistor, MT22, having a MT22-drain, a MT22-source, and a MT22-gate.

For the first s-bit generator 100: node N1 is connected to V_{DD}; node N7 is connected to MT20-gate; and node N4 is connected to GND. For the second s-bit generator 100: MT7-drain, MT9-drain, and MT11-drain are connected to MT19-drain; and node N12 is connected to MT21-drain. For the third s-bit generator 100: node N13 is connected to MT22-source. For the MUX gate 116: MT19-drain is connected to N1 and V_{DD}; MT19-gate is connected to: MT21-gate via node N18 and MT20-drain via node N18; MT19-source is connected to: MT21-gate via node N18 and MT20-drain via node N18; MT20-drain is connected to: MT19-gate via node N18, MT19-source via node N18, and MT21-gate via node N18; MT20-gate is connected to: node N7 and MT22-gate; MT20-source is connected to node N4 and GND; MT21-drain is connected to N12; MT21-gate is connected to: MT19-source via node N18, MT19-gate via node N18, and MT20-drain via node N18; MT21-source is connected to MT22-drain via node N19; MT22-drain is connected to MT21-source via node N19; MT22-gate is connected to MT20-gate; MT22-source is connected to node N13; and the MUX gate 116 outputs C at node N19.

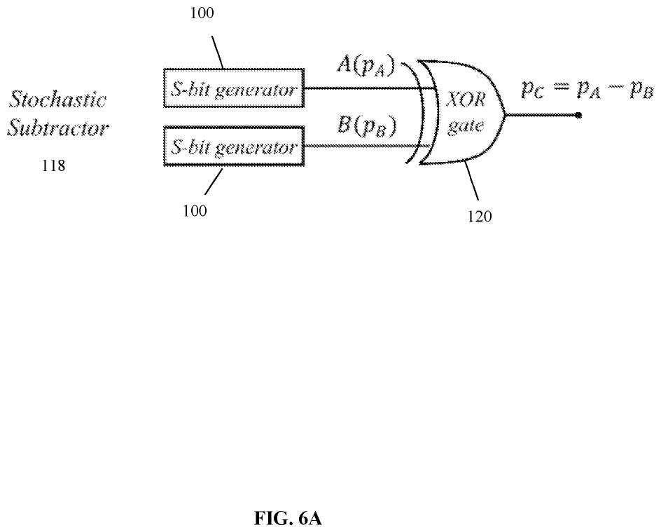

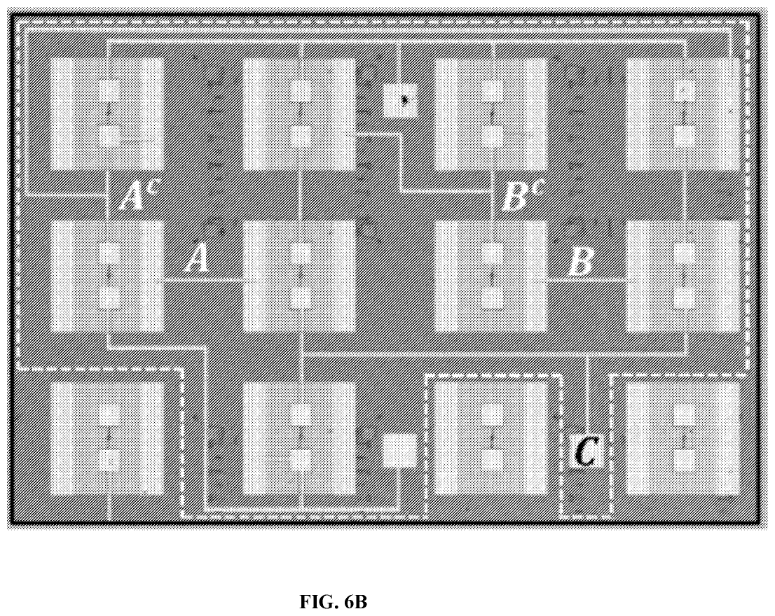

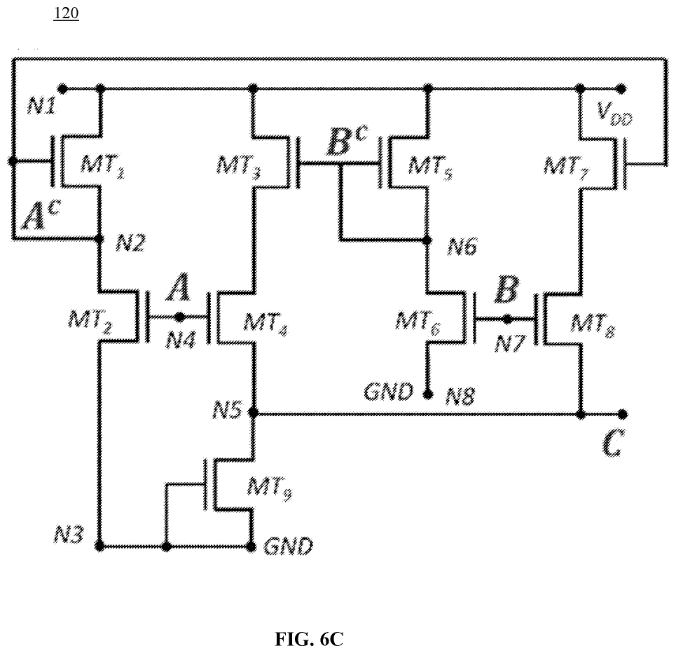

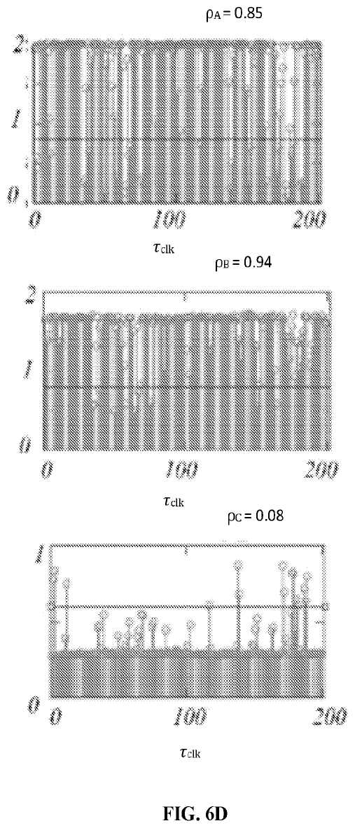

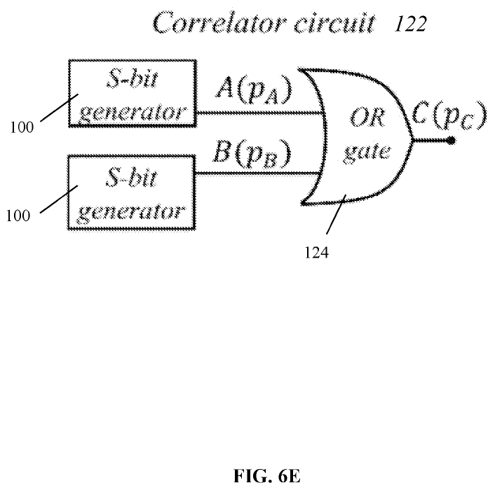

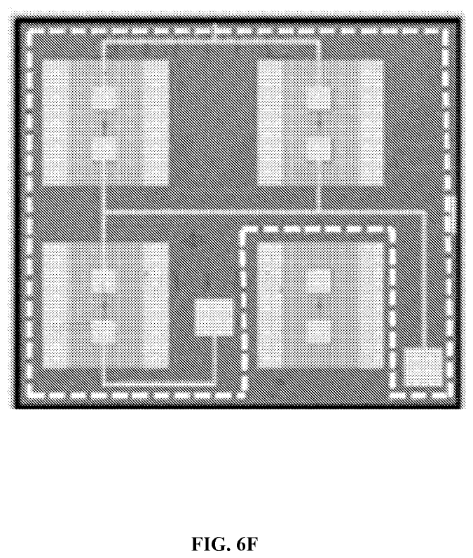

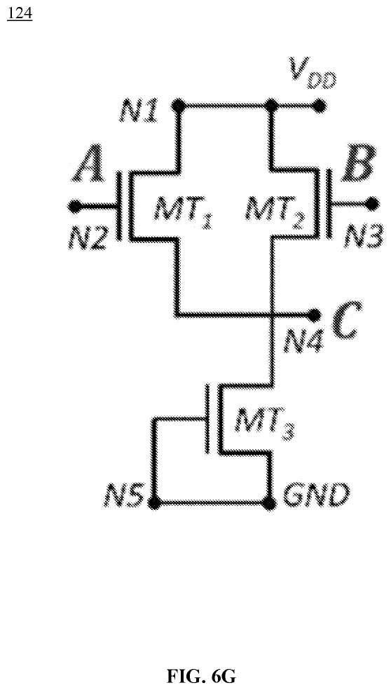

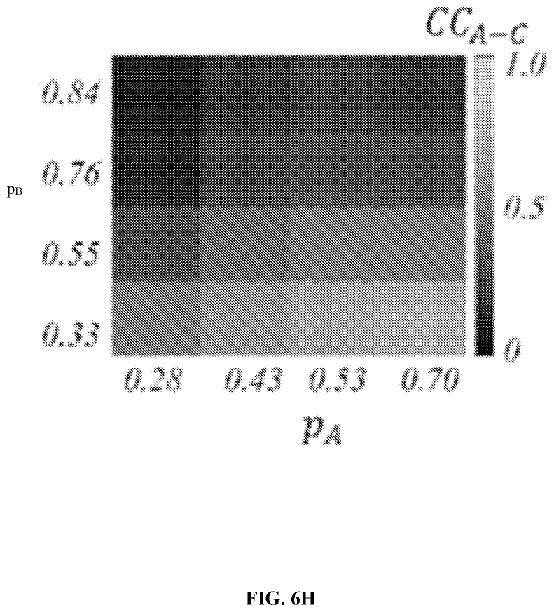

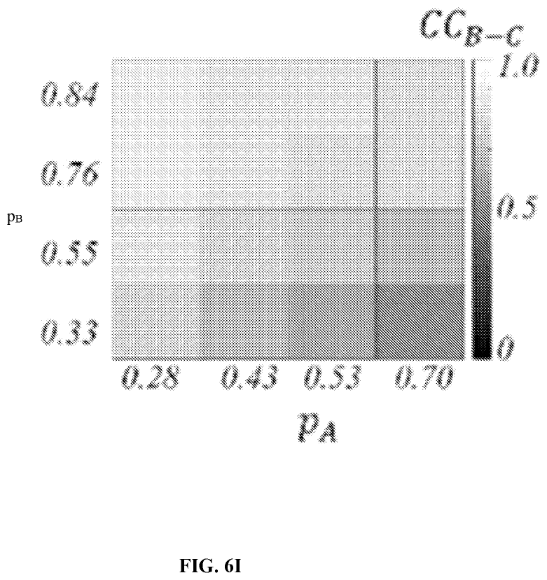

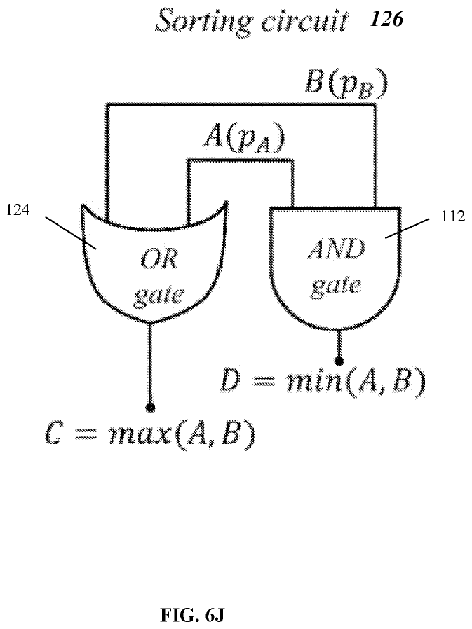

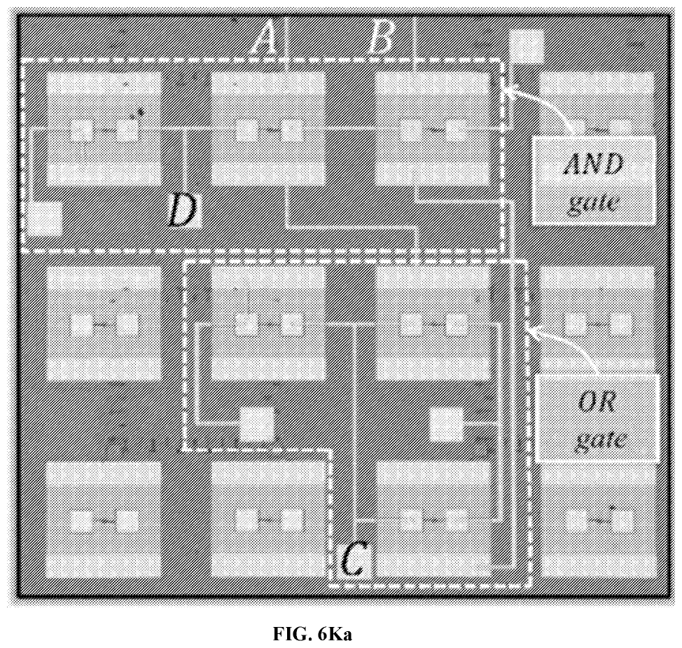

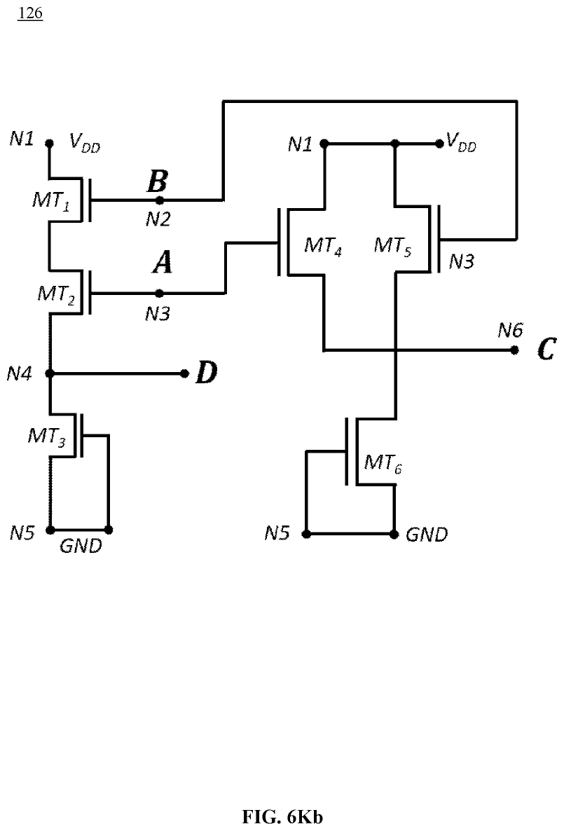

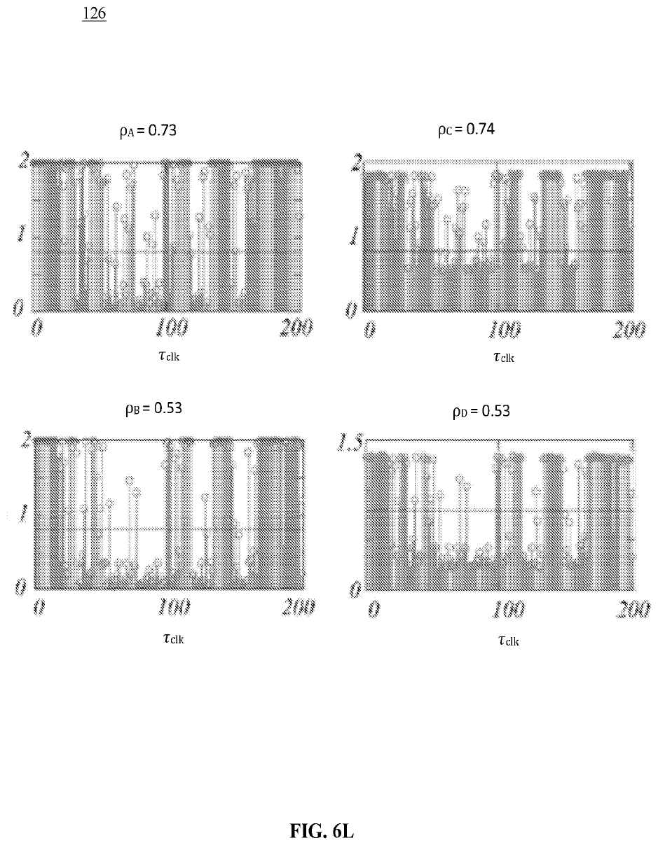

Referring to FIGS. 6A, 6B, and 6C, an exemplary embodiment can relate to a stochastic subtractor 118. The stochastic subtractor 118 can include a first s-bit generator 100 configured to generate output A, and a second s-bit generator 100 configured to generate output B, wherein output A and output B are correlated bit streams. The stochastic subtractor 118 can include an XOR gate 120, comprising plural memtransistors, the plural memtransistors including: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; a memtransistor, MT6, having a MT6-drain, a MT6-source, and a MT6-gate; a memtransistor, MT7, having a MT7-drain, a MT7-source, and a MT7-gate; and a memtransistor, MT8, having a MT8-drain, a MT8-source, and a MT8-gate; a memtransistor, MT9, having a MT9-drain, a MT9-source, and a MT9-gate. Each memtransistor can be stacked on a non-volatile and programmable local back-gate stack. Each memtransistor can have a 2D channel formed between its source and its drain. MT1-drain can be connected to: node N1, MT3-drain, MT5-drain, MT7-drain, and V_{DD}. MT1-gate can be connected to: MT7-gate and MT2-drain via node N2. MT1-source can be connected to MT2-drain via node N2. MT2-drain can be connected to: MT1-source via node N2 and MT1-gate via node N2. MT2-gate can be connected to MT4-gate via node N4. MT2-source can be connected to: MT9-gate via node N3 and GND. MT3-drain can be connected to: node N1, MT1-drain, MT5-drain, MT7-drain, and V_{DD}. MT3-gate can be connected to: MT5-gate and MT6-drain via node N6. MT3-source can be connected to MT4-drain. MT4-drain can be connected to MT3-source. MT4-gate can be connected to MT2-gate via node N4. MT4-source can be connected to: MT9-drain via node N5 and MT8-source via node N5. MT5-drain can be connected to: node N1, MT1-drain, MT3-drain, MT7-drain, and V_{DD}. MT5-gate can be connected to: MT3-gate and MT6-drain via node N6. MT5-source can be connected to: MT3-gate via node N6 and MT6-drain via node N6. MT6-drain can be connected to: MT5-source via node N6, MT5-gate via node N6, and MT3-gate via node N6. MT6-gate can be connected to: MT8-gate via node N7. MT6-source can be connected to: node N8 and GND. MT7-drain can be connected to: node N1, MT1-drain, MT3-drain, MT5-drain, and V_{DD}. MT7-gate can be connected to: MT1-gate, MT1-source, and MT2-drain via node N2. MT7-source can be connected to MT8-drain. MT8-drain can be connected to MT7-source. MT8-gate can be connected to MT6-gate via node N7. MT8-source can be connected to MT9-drain via node N5. MT9-drain can be connected to MT4-source via node N5 and MT8-source via node N5. MT9-gate can be connected to: node N3 and GND. MT9-source can be connected to: node N3 and GND. Output A can be received at node N4 and output B can be received at node N7. MT1 and MT2, together, can act as a NOT gate to invert output A to generate output A^{c}. MT5 and MT6, together, can act as a NOT gate to invert output B to generate Be. The XOR gate 120 can be configured to receive output A, receive output B, and generate an output C via node N5.

Referring to FIGS. 6E, 6F, and 6G, an exemplary embodiment relates to a stochastic correlator 122, comprising: a first s-bit generator 100 configured to generate output A, and a second s-bit generator 100 configured to generate output B, wherein output A and output B are uncorrelated bit streams. The stochastic correlator 122 can include an OR gate 124, comprising plural memtransistors, the plural memtransistors including: a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; Each memtransistor can be stacked on a non-volatile and programmable local back-gate stack. Each memtransistor can have a 2D channel formed between its source and its drain. MT1-drain can be connected to: node N1 and V_{DD}. MT1-gate is connected to node N2. MT1-source is connected to: MT2-source, node N4, and MT3-drain. MT2-drain can be connected to: node N1 and V_{DD}. MT2-gate can be connected to node N3. MT2-drain can be connected to: MT1-source, node N4, and MT3-drain. MT3-drain can be connected to MT1-source, MT2-source, and node N4. MT3-gate can be connected to node N5 and GND. MT3-source can be connected to GND. The OR gate 124 can be configured to receive output A at node N2, receive output B at node N3, and generate an output C via node N4.

Referring to FIGS. 6J and 6Ka, an exemplary embodiment relates to a stochastic sorter 126. The stochastic sorter 126 can include a first s-bit generator 100 configured to generate output A, and a second s-bit generator 100 configured to generate output B. The stochastic sorter 126 can include an OR gate 124 configured to receive output A, receive output B, and generate an output C that is a maximum value of output A and output B. The stochastic sorter 126 can include an AND gate 112 configured to receive output A, receive output B, and generate an output D that is a minimum value of output A and output B.

Referring to FIG. 6Kb, an exemplary stochastic sorter 126 can include plural memtransistors, the plural memtransistors including a memtransistor, MT1, having a MT1-drain, a MT1-source, and a MT1-gate; a memtransistor, MT2, having a MT2-drain, a MT2-source, and a MT2-gate; a memtransistor, MT3, having a MT3-drain, a MT3-source, and a MT3-gate; a memtransistor, MT4, having a MT4-drain, a MT4-source, and a MT4-gate; a memtransistor, MT5, having a MT5-drain, a MT5-source, and a MT5-gate; and a memtransistor, MT6, having a MT6-drain, a MT6-source, and a MT6-gate. Each memtransistor can be stacked on a non-volatile and programmable local back-gate stack. Each memtransistor can have a 2D channel formed between its source and its drain. MT1-drain can be connected to node N1 and V_{DD}. MT1-gate can be connected to MT5-gate via node N2 and node N3. MT1-source can be connected to MT2-drain. MT2-drain can be connected to MT1-source. MT2-gate can be connected to MT4-gate via node N3. MT2-source can be connected to MT3-drain via node N4. MT3-drain can be connected to MT2-source via node N4. MT3-gate can be connected to GND and MT3-source via node N5. MT3-source can be connected to GND via node N5 and MT3-gate via node N5. MT4-drain can be connected to node N1, V_{DD} via node N1, and MT5-drain via node N1. MT4-gate can be connected to MT2-gate via node N3. MT4-source can be connected to MT5-source, node N6, and MT6-drain. MT5-drain can be connected to node N1, V_{DD}, and MT4-drain via Node N1. MT5-gate can be connected to MT1-gate via node N2. MT5-source can be connected to MT4-source, node N6, and MT6-drain. MT6-drain can be connected to node N6, MT5-source, and MT4-source. MT6-gate can be connected to node N5 and GND via node N5. MT6-source can be connected to GND and node N5. Output A from the first s-bit generator can be received at node N3, output B from the second s-bit generator can be received at node N2, output C can be generated at node N6, and output D can be generated at node N4.

### EXAMPLES

The following discussion relates to exemplary implementations of embodiments of the devices, systems, circuits, and methods disclosed herein. It is understood that the following examples demonstrate exemplary implementations, and embodiments of the devices, systems, circuits, and methods disclosed herein are not meant to be limited to these examples.

As the energy and hardware investments necessary for conventional high-precision digital computing continues to explode in the emerging era of artificial intelligence, deep learning, and Big-data, a change in paradigm that can trade precision for energy and resource efficiency is being sought for many computing applications. Stochastic computing (SC) is an attractive alternative since unlike digital computers, which require many logic gates and a high transistor volume to perform basic arithmetic operations such as addition, subtraction, multiplication, sorting etc., SC can implement the same using simple logic gates. While it is possible to accelerate SC using traditional silicon complementary metal oxide semiconductor (CMOS) technology, the need for extensive hardware investment to generate stochastic bits (s-bit), the fundamental computing primitive for SC, makes it less attractive. Memristor and spin-based devices offer natural randomness, but depend on hybrid designs involving CMOS peripherals for accelerating SC, which increases area and energy burden. Embodiments disclosed herein overcome the limitations of existing and emerging technologies and experimentally demonstrate a standalone SC architecture embedded in memory based on two-dimensional (2D) memtransistors.

Embodiments of the monolithic and non-von Neumann SC architecture consume a miniscule amount of energy <1 nano Joules for s-bit generation and to perform arithmetic operations and occupy small hardware footprint highlighting the benefits of SC.

Stochastic computing (SC) is an attractive alternative, where arithmetic operations can be performed using simple logic gates yielding high energy and area efficiency. For example, a simple two-bit multiplication in a conventional CMOS based full adder circuit requires 78 transistors whereas a SC unit can execute the same operation using a single AND gate. Similarly, stochastic addition and subtraction can be performed using multiplexer (MUX) and XOR gates, respectively. The key difference is that unlike classical computing system which represents information in the form of binary logic (‘1’s and ‘0’s), SC encodes information through stochastic bit (s-bit) streams that are interpreted as probabilities that fall in the interval [0,1]. For instance, the bit-stream A={1 0 1 1 0 1 0 0} encodes the value ρ_{A}=0.5 since there are four 1's present within the bit-stream of length 8-bit. An attractive feature of SC is its resilience to error tolerance since there is no distinction between the most and the least significant bits, or in other words all s-bits carry equal weight. While promising, the application of SC has largely been limited to specialized domains such as image and audio processing where a finite amount of error or loss in precision is acceptable. Such limitations primarily stem from the requirement of having a much longer bit-stream for more accurate probability estimation that leads to a corresponding increase in the computation time and energy. Despite these shortcomings, SC is becoming popular for many AI applications, which deal with large volumes of audio-visual information. Note that the idea of SC is also rooted in bio-inspired computing since the brain can process information in the presence of noise, and can learn, adapt, and make right decisions to ensure the survival of the species at the cost of miniscule energy expenditure.

The concept of SC is well known and extensively studied. CMOS, memristor, and spintronics based SC architectures have already been demonstrated in the past. However, CMOS-based SC architectures require several hundred transistors to generate s-bits, which limits its area and energy efficiency. Stochastic switching in memristors offer an excellent mechanism to generate fast and random bits with the added benefits of high integration density since memristors can be scaled down to sub 10 nm. However, memristor-based SC architectures still require CMOS peripherals to control the probability of switching for the conversion of random bits into s-bits and for subsequent logic operations using those s-bits, which can ultimately limit the area and energy efficiency. Recently, spin-based magnetic random access memory (MRAM) devices and spin-orbit torque magnetic tunnel junctions (SOT-MTJ) have shown immense potential for SC since the probability of spin-flip can be controlled by externally driven current allowing seamless generation of s-bits. In addition, spin-based devices offer high switching speed, a simpler structure, high throughput, and better area and energy efficiency and are therefore, fundamentally superior in performance to CMOS-based alternatives. However, environmental, and electrical fluctuations can interfere and impact the spin-flip probability necessitating additional CMOS-based peripheral circuits to remove the bias. Although, recent demonstration of integer factorization using spin-based MRAM devices is a milestone achievement, the SC architecture utilized for such demonstration involves extensive CMOS peripherals since two-terminal MRAM devices suffer from similar limitations like the memristors.

Embodiments disclosed herein overcome the above-mentioned limitations by introducing a standalone SC architecture embedded in memory, which is based on two dimensional (2D) memtransistors. Memtransistors are programmable field effect transistors (FETs) made from ultra-thin body semiconducting channel material such as monolayer MoS₂ allowing aggressive channel length scaling owing to superior gate electrostatics. Our main contributions are 1) the realization of an area and energy efficient six-transistor (6T) s-bit generator circuit that exploits the inherent stochasticity in the carrier trapping and detrapping phenomena in the gate insulator of the 2D memtransistors and combines it with an inverting amplifier and a programmable thresholding inverter to obtain s-bits and 2) integration of s-bit generators with 2D memtransistor based logic gates such as AND, MUX, XOR, and OR gates to demonstrate arithmetic operations such as addition, subtraction, multiplication, and sorting.

### Fabrication and Characterization of 2D Memtransistors

FIG. 2A shows the optical image of a 2D memtransistor based hardware platform for the acceleration of the SC architecture, and FIG. 2B shows the optical image and corresponding 3D schematic of a representative 2D memtransistor based on monolayer MoS₂, which are locally back-gated using a stack comprising of atomic layer deposition (ALD) grown 50 nm Al₂O₃ on sputter deposited 40/30 nm Pt/TiN. All back-gate islands were placed on a commercially purchased SiO_{2/p}⁺⁺—Si substrate. The stochastic conductance fluctuation in monolayer MoS₂ and analog and non-volatile programming capability offered by the Al₂O₃/Pt/TiN gate stack are central to the non-von Neumann SC architecture. The monolayer MoS₂ was grown over large area via metal organic chemical vapor deposition (MOCVD) technique on sapphire substrate and subsequently transferred from the growth substrate to the SiO_{2/p}⁺⁺-Si substrate with predefined islands of Al₂O₃/Pt/TiN for 2D memtransistor fabrication. Details on monolayer MoS₂ synthesis, film transfer, and fabrication of the local back-gate gate islands, MoS₂ memtransistors, and SC architecture are discussed later. FIG. 2C shows the transfer characteristics, e.g., source to drain current (I_{DS}) versus local back-gate voltage (V_{BG}) measured using source to drain bias, V_{DS}=1 V, in linear and logarithmic scale for a representative MoS₂ memtransistor with channel length, L=1 μm, and channel width, W=5 μm.

As expected, n-type transport is observed in MoS₂, which is attributed to the pinning of the metal Fermi level near the conduction band. Nevertheless, MoS₂ memtransistor exhibits excellent electrostatic gate control with current on/off ratio (r_{ON/OFF}) ˜10⁶, subthreshold slope (SS) ˜370 m V/decade averaged over 4 orders of magnitude change in I_{DS}, minimal gate hysteresis when measured in air, and low gate leakage current. The threshold voltage (V_{TH}) was found to be ˜2 V extracted at iso-current of 100 nA/μm and the electron field effect mobility (μ_{FE}) extracted from the peak trans-conductance was found to be ˜5 cm²/V−s. FIG. 2D shows the output characteristics, e.g., I_{DS} versus V_{DS} for different V_{BG} for the same MoS₂ memtransistor. The on current (I_{ON}) reached as high as ˜40 μA/μm for an inversion carrier density of ˜1.4×10¹²/cm² at V_{DS}=5 V. FIG. 2E shows the device-to-device variation in the transfer characteristics across 50 2D memtransistors and FIG. 2F shows the corresponding histogram of extracted μ_{FE} with mean of ˜3.8 cm²V⁻¹s⁻¹ and standard deviation of 1.2 cm²V⁻¹s⁻¹. These results indicate relatively high quality and uniform monolayer film growth using MOCVD, relatively damage-free film transfer, and clean memtransistor fabrication processes.

Finally, FIGS. 2G, 2H, and 2I, respectively, show the analog programming, erase, and non-volatile retention capability of the 2D memtransistor. When the 2D memtransistor is subjected to negative “Write” (V_{P}) and positive “Erase” (V_{E}) voltage pulses of different amplitudes ranging from 6 V to 15 V applied to the local back-gate electrode, each for a duration of τ_{P/E}=100 μs, the transfer characteristics show shift in V_{TH}, which can be attributed to charge trapping/detrapping at and near the MoS₂/Al₂PO₃ interface. Negative shift in the in the transfer characteristics with increasing magnitude of V_{P} and positive shift with increasing magnitude of V_{E} are indicative of electron trapping and de-trapping in the local back-gate stack, respectively. Interestingly, the trapping and de-trapping processes were found to be non-volatile as shown in FIG. 11 for 4 representative programmed and erased states for 100 seconds. We also found that the device is capable of retaining programmed conductance states for more than 10 hours. While it is generally desirable to improve memory retention, the memory retention was found to be adequate for the purposes of SC.

Programming Stochasticity in 2D Memtransistor and s-Bit Generation

Generation of high-quality random bits is a pre-requisite for reducing computational inaccuracies at the output of any stochastic operation. Here, we exploit the inherent stochasticity in the carrier trapping and detrapping phenomena in the gate oxide of the 2D memtransistor as the source of true randomness. FIG. 3A shows the transfer characteristics of a representative MoS₂ memtransistor, measured each time after the application of V_{P}=−10 V and V_{E}=10 V each for τₛ=100 μs, for a total of 100 cycles. FIG. 3A also shows the distribution of Gur measured using V_{BG}=0 V. Clearly, the cycle-to-cycle variability in post-programmed and post-reset GMT follow Gaussian random distributions. While programming stochasticity is detrimental for conventional computing, it offers unique opportunity for SC.

In order to translate the conductance fluctuation into s-bits, we deploy a module having six memtransistors (MT1, MT2, MT3, MT4, MT5, and MT6) as shown using the optical image and corresponding circuit diagram in FIGS. 3B and 3C, respectively. The voltage waveforms applied to the nodes, N1, N2, N3, and N4 are V_{N1}, V_{N2}, V_{N3}, and V_{N4} respectively. Note that during each clock cycle (τ_{clk}), V_{N1} toggles between 0 V, 0 V, and V_{DD}=2 V and V_{N2} toggles between V_{P}=˜7 V, V_{E}=10 V, and V_{R}=1 V, whereas V_{N3}, and V_{N4} are held constant at 1V and 0 V, respectively. This is done to program and reset MT1 and then readout the voltage at node, N5, i.e., V_{N5} during each (τ_{clk}). Since MT1 and MT2 are connected in series, V_{N5} is determined by their corresponding conductance values, e.g., G_{MT1} and G_{MT2}. As G_{MT1} fluctuates from cycle to cycle, so does V_{N5} as shown in FIG. 3D. FIG. 3E shows the histogram of V_{N5}, which follows a random Gaussian distribution with mean, μ_{VN5}=0.27 V and standard deviation, σ_{VN5}=0.05 V.

Next the Gaussian distribution is broadened by using an inverting amplifier constructed using MT3 and MT4. Note that the local back-gate of MT3 is shorted to its source at node, N6. This ensures that MT3 operates as a depletion mode (normally on) transistor or as a load resistor. FIG. 3F shows the output, V_{N6}, as a function of the input, V_{N5}. The slope of the curve is referred to as the gain of the amplifier, and higher the gain wider is the broadening of the Gaussian. We achieved a gain of ˜7, which was sufficient for the hardware acceleration of SC. The gain can be increased by cascading multiple amplifiers; however, it adds area and energy overhead. FIG. 3G shows V_{N6} corresponding to V_{N5} in FIGS. 3D, and 3H shows the histogram of V_{N6} which follows a random Gaussian distribution with mean, μ_{VN6}=1.01 V and an increased standard deviation of σ_{VN6}=0.35 V.

To transform the analog fluctuations seen in V_{N6} into s-bits, we use a thresholding inverter constructed using MT5 and MT6. FIG. 3I shows the output, V_{N7}, as a function of the input, V_{N6} for different inversion threshold, V_{IT}, which is defined as the magnitude of V_{N6} at which V_{N7} reaches V_{DD}/2. Note that the programmability of V_{IT} is a critical feature that distinguishes 2D memtransistor based inverters from conventional CMOS-based inverters and allows us to seamlessly obtain the s-bits. FIG. 2J shows V_{N7} corresponding to V_{N6} in FIG. 2G for different V_{IT}, and FIG. 2K shows the probability of obtaining ‘1’ in the bit stream (pₛ) as a function of V_{IT}. As expected, if V_{IT} is too low, then almost all V_{N6} values corresponding to the Gaussian distribution in FIG. 2H translate into V_{N7}˜0 V, which is reflected as near zero pₛ. Similarly, if V_{IT} is too high, then almost all V_{N6} values translate into V_{N7}˜2 V leading to pₛ=1. Between these two extremes, pₛ increases monotonically with V_{IT}. This clearly shows that we are able to convert the cycle-to-cycle random conductance fluctuations in 2D memtransistor into s-bits with reconfigurable pₛ that lie between [0,1] using the circuit based on 6 2D memtransistors.

The average energy expenditure for s-bit generation (E_{s-bit}) was calculated using:

$${E}_{s - bit} = \frac{1}{2} {C}_{G} [ {V}_{P}^{2} + {V}_{E}^{2} + {V}_{DD}^{2} ] + \frac{1}{N} {\sum }_{i = 1}^{N} {I}_{N 1 N 4 - i} {V}_{DD} {τ}_{clk} ; {C}_{G} = {ε}_{0} {ε}_{ox} WL / {t}_{ox}$$

C_{G} is the gate capacitance, I_{NIN4-i} is the current flowing through the s-bit generator during each τ_{clk}, ε₀=8.85×10⁻¹² F/m is the vacuum permittivity, and ε_{0X}=10, and t₀=50 nm are, respectively, the relative permittivity and thickness of Al₂O₃. We found that E_{s-bit} <2 pJ/clock-cycle, which supports our claim on energy efficient s-bit generation. Note that the second term in the equation is more than three orders of magnitude smaller, ˜1 fJ (we have used N=100 to calculate the average current in the s-bit generator per clock cycle). Therefore, it is possible to reduce the energy expenditure even further through scaling of t₀ₓ which will scale the program/erase voltages accordingly. Also note that each memtransistor has an active device area that is ˜5 μm² excluding the large contact pads. Therefore, the active footprint of the s-bit generator is only 30 μm². Given that monolayer 2D materials offer aggressive dimensional scalability, it is possible to reduce the active footprint significantly without compromising the quality of the s-bits.

### Stochastic Arithmetic Modules

### Multiplication:

Stochastic multiplication can be accomplished using a simple AND gate as shown in FIG. 4A. The stochastic output, C(p_{C}), of an AND gate with two stochastic input variables, A(p_{A}) and B(p_{B}), is given by:

$$C = AB$$

$${p}_{C} = {p}_{A} {p}_{B}$$

p_{A} p_{B}, and p_{C}, are the probabilities associated with the random variables, A, B, and C respectively. These equations are valid if and only if the random variables, A and B, are mutually independent or uncorrelated.

FIGS. 4B and 4C, respectively, show the optical image and corresponding circuit configuration of a stochastic multiplier having a 2 s-bit generator and an AND gate with a total of 15 memtransistors. The AND gate has of 3 memtransistors, MT7, MT8, and MT9. Inputs, A and B, are applied to the local back-gates of MT7 and MT8, which are connected in series with MT9 at node N8. The source and gate terminals of MT9 are shorted and connected to the ground. As such, MT9 operates as a load resistor. The output, C, of the AND gate is obtained at node N8. FIG. 4D shows the representative stochastic bit-streams for the random variables, A(p_{A}=0.6) and B(p_{B}=0.74) obtained from their respective s-bit generators by programming V_{IT} and the corresponding output bit-stream for C with p_{C}=0.46. FIG. 4E shows the colormaps of percentage errors (E) obtained for different combinations of p_{A} and p_{B}. We have used bit-streams of length 200-bit to evaluate the corresponding probability values.

$$ϵ = \vert 1 - \frac{{( {p}_{C} )}_{obtained}}{{( {p}_{C} )}_{expected}} \vert \times 100 \%$$

(p_{C})_{obtained} and (p_{C})_{expected} are the experimentally obtained and theoretically predicted output of the stochastic computation.

As mentioned earlier, to obtain accurate multiplication product, A and B must be mutually independent. FIG. 4F shows the colormap of correlation coefficient (CC) between the s-bit streams used as A and B. Low CC values close to zero confirm mutual independence of A and B, which translate into accurate multiplication results obtained in FIG. 4E. Clearly, the 15 memtransistor circuit is able to perform stochastic multiplication with high accuracy. Note that the accuracy can be increased by increasing the length of s-bit streams at the expense of longer computation time since one s-bit is generated every τ_{clk}. The average energy expenditure for the multiplication operation is ˜0.8 nJ, when 200 τ_{clk} are used. Certainly, the energy expense can be reduced by reducing the length of the s-bit streams at the cost of reduced precision.

### Addition:

Stochastic addition operation can be accomplished using a MUX as shown in FIG. 5A. The stochastic output, C(p_{C}), of a MUX with two stochastic input variables, A(p_{A}) and B(p_{B}), and a stochastic select line, S(pₛ) is given by:

$$C = SA + {S}^{C} B$$

$${p}_{C} = {p}_{S} {p}_{A} + ( 1 - {p}_{S} ) {p}_{B}$$

$${p}_{C} = 0.5 ( {p}_{A} + {p}_{B} ) ; \qquad if {p}_{S} = 0.5$$

Clearly, for pₛ=0.5, one can achieve scaled addition. FIGS. 5B and 5C, respectively, show the optical image and corresponding circuit configuration of a stochastic adder consisting of 3 s-bit generator modules and one 2×1 MUX with a total of 22 memtransistors. The 2×1 MUX has of 4 memtransistors, MT19, MT20, MT21, and MT22. Note that MT19 and MT20 form a NOT gate with stochastic variable S as the input and Se as the output. S and S^{c} are applied to the local back-gates of MT21 and MT22, respectively, which are connected in series at node N19. The stochastic variable, A, is connected to the source terminal of MT21 at node N12, whereas the stochastic variable, B, is connected to the drain terminal of MT22 at node N13. The output of the MUX, i.e., C is obtained at node N19. FIG. 5D shows the representative stochastic bit-streams for the random variables S(pₛ=0.5), A(p_{A}=0.28), and B(p_{B}=0.55) obtained from their respective s-bit generation modules at nodes N7, N12, and N13 and the corresponding output bit-stream for C with p_{C}=0.41. IG. 5E shows the colormaps of percentage errors (ε) for scaled addition for different combinations of p_{A}, p_{B}, for pₛ˜0.5. Clearly, the 22 memtransistor module is able to perform stochastic addition with high accuracy. The average energy expenditure for the scaled addition operation is ˜1.2 nJ.

### Subtraction:

While the circuits used for stochastic multiplication and addition require the stochastic inputs to be independent or uncorrelated to achieve accurate results, stochastic subtraction benefits greatly from the correlation between the stochastic inputs. In fact, correlated inputs can drastically alter the functionality of a stochastic circuit thereby simplifying the hardware acceleration of specific arithmetic operations. For example, if a XOR gate (FIG. 6A) is implemented using two uncorrelated stochastic input variables, A(p_{A}) and B(p_{B}), the stochastic output, C(p_{C}) will be given by:

$$C = {AB}^{C} + {A}^{C} B$$

$${p}_{C} = {p}_{A} ( 1 - {p}_{B} ) + {p}_{A} ( 1 - {p}_{B} )$$

However, when A and B are highly correlated, it implements absolute-valued subtraction:

$${p}_{C} = \vert {p}_{A} - {p}_{B} \vert$$

As an example, if A=01110110 and B=011000100 are two correlated stochastic streams representing p_{A}=5/8 and p_{B}=3/8, then C=00010010 and p_{C}=2/8. Note that conventional implementation of this function requires one NOT gate, one 2×1 MUX, and one finite state machine (FSM), increasing the area and energy overhead.

FIG. 6B and FIG. 6B, respectively, show the optical image and corresponding circuit configuration of a XOR gate with a total of 9 memtransistors. Note that, memtransistor pairs, MT1 and MT2, and MT5 and MT6 are NOT gates used to invert A to A^{c} and B to B^{c}, respectively. A and B^{c} are applied to the local back-gates of MT3 and MT4, respectively, which are connected in series. Similarly, A and B are applied to the local back-gates of MT7 and MT8, respectively, which are also connected in series. Finally, the series connection of MT3 and MT4, and MT7 and MT8 are connected in parallel between node, N1 and N5. The drain terminal of MT9 is connected to N5, whereas the source and gate terminals are shorted to the ground. The overall circuit accomplishes the XOR logic for the inputs, A and B at node N5. FIG. 6D shows the representative stochastic bit-streams for the correlated random variables A(p_{A}=0.85), B(p_{B}=0.93), and the output of the XOR gate, C(p_{C}=0.08), which is close to |p_{A}˜p_{B}|. Clearly, the 9 memtransistor circuit is able to perform stochastic subtraction when the stochastic bit-streams are correlated. Note that the CC between A and B was intentionally made high, ˜0.88, by using a correlator circuit described below.

While the s-bit generators produce uncorrelated bit-streams, correlated random variables can be created by using an OR gate as shown in FIG. 6E. The optical image and corresponding circuit configuration of the OR gate comprising of 3 memtransistors are shown in FIGS. 6F and 6G, respectively. Two mutually independent or uncorrelated stochastics inputs, A and B, obtained from the s-bit generators are applied to the local back-gates of MT1 and MT2, which are connected in parallel among themselves and in series with MT3. As explained earlier, MT3 operates as a load resistor and the entire circuit serves as an OR gate. Interestingly, the output, C, obtained at node, N4 becomes correlated with either or both, A and B. FIGS. 6H-6I show the correlation coefficient between C and A, i.e., CC_{A-C} and C and B, i.e., CC_{B-C}, respectively, for different values of p_{A} and p_{B}. Clearly, CC_{A-C} and CC_{B-C} values range from ˜0 to ˜1. Also note that lower p_{A} values ensure higher correlation between C and B and vice versa. Nevertheless, the correlator circuit allows us to obtain correlated bit-stream with desirable correlation coefficients. The average energy expenditure for obtaining correlated bit stream is ˜0.8 nJ.

### Sorting:

As we have shown earlier, an AND gate functions as a stochastic multiplier for uncorrelated bit-streams. However, when the inputs become highly correlated, it gives the minimum of the two stochastic streams. As an example, if A=01101110 and B=01100100 are two correlated stochastic streams representing p_{A}=5/8 and p_{B}=3/8, then C=01100100 and p_{C}=3/8. Similarly, an OR gate, gives the maximum value of two stochastic streams, e.g., C=01101110 and p_{C}=5/8. This is in contrast to conventional implementation with uncorrelated inputs that require FSM-based stochastic hyperbolic tangent (tanh) function along with the three MUXs, which again increases area and energy overhead. FIGS. 6J and 6K, respectively, show the schematic and optical image of a sorting circuit e.g., finding the minimum and maximum between two stochastic variables, A and B. The circuit has of 6 memtransistors. FIG. 6L shows the representative stochastic bit-streams for the correlated random variables A, B, and the sorted output C for maximum and D for minimum values, respectively.

Table 1 summarizes the SC architectures for different arithmetic operations involving medium scale integration (MSI) of 2D memtransistors along with their respective energy expenditure.

TABLE 1
Summary of the SC architecture for different arithmetic operations

| | | | | Average |
|---|---|---|---|---|
| | # of s-bit | Logic | | energy |
| Arithmetic operation | generators | gates | # of memtransistors | expenditure |
| Multiplication | 2 | AND | 15 | ~0.8 nJ |
| Addition | 3 | 2 × 1 MUX | 22 | ~1.2 nJ |
| Subtraction | 2 | XOR | 24 | ~0.8 nJ |
| (correlated s-bits) | | | (including correlator circuit) | |
| Sorting | 2 | OR, AND | 21 | ~0.8 nJ |
| (correlated s-bits) | | | (including correlator circuit) | |

It is contemplated to expand the SC architecture to accelerate Bayesian neural networks, invertible logic, and solve various combinatorial optimization problems such as the traveling salesman problem. While it is contemplated to realize all peripherals using 2D memtransistors, 2D memtransistor-based stochastic computing hardware can benefit in the short-term from integration with mature Si CMOS technology. In fact, it is possible that the 2D memtransistor and CMOS technology can synergistically co-exist. Also note that very large-scale integration (VLSI) of 2D memtransistors is non-trivial as multiple challenges must be overcome. While there has been tremendous progress on large-area growth of a wide range of 2D materials, there is still scope to minimize growth defects to achieve higher performance and increase growth uniformity to ensure low device-to-device variation. At the same time, large area transfer of 2D materials must be improved for cleaner and mechanical damage-free transfer ensuring high yield during device fabrication. Finally, the future roadmap for 2D memtransistors will involve scaling of channel length and oxide thickness. While earlier experimental reports and theoretical projections from literature do indicate that 2D material-based field effect transistors (FETs) can meet the requirements set forth by the International Roadmap for Devices and Systems (IRDS 2028), programmability of scaled memtransistors may need to be investigated further.

As can be appreciated from the disclosure presented herein, the cycle-to-cycle variability in the programmed conductance of monolayer MoS₂ based 2D memtransistors can be exploited and translated the same into s-bits with reconfigurable probability of obtaining ‘1’ in the bit-stream using a s-bit generator circuit comprising of 6 memtransistors and subsequently combined the s-bit generator with 2D memtransistor based logic gates to demonstrated a standalone SC architecture that can perform accurate arithmetic operations such as addition, subtraction, multiplication, and sorting. The SC architecture consumes miniscule energy ˜1 nano Joules to perform arithmetic operations and uses limited numbers of memtransistors with small active-area footprint. Embodiments herein offer a way to accelerate SC on a non-von Neumann platform based on novel 2D materials and devices.

### Methods

### Fabrication of Local Back-Gate Islands:

To define the back-gate island regions, the substrate 285 nm SiO₂ on p⁺⁺-Si was spin coated with bilayer photoresist consisting of Lift-Off-Resist (LOR 5A) and Series Photoresist (SPR 3012) baked at 185° C. and 95° C., respectively. The bilayer photoresist was then exposed to Heidelburg Maskless Aligner (MLA 150) to define the island and developed using MF CD26 microposit, followed by a de-ionized (DI) water rinse. The back gate electrode of 20/50 nm TiN/Pt was deposited using reactive sputtering. The photoresist was removed using acetone and Photo Resist Stripper (PRS 3000) and cleaned using 2-propanol (IPA) and DI water. Atomic layer deposition (ALD) process was then implemented to grow 50 nm Al₂O₃ on the entire substrate including the island regions. To access the individual Pt back-gate electrodes etch patterns were defined using the same bilayer photoresist consisting of LOR 5A and SPR 3012. The bilayer photoresist was then exposed to MLA 150 and developed using MF CD26 microposit. 50 nm Al₂O₃ was subsequently dry etched using the BCl₃ chemistry at 5° C. for 20 seconds, which was repeated four times to minimize heating in the substrate. Next, the photoresist was removed to give access to the individual Pt electrodes.

### Large Area Monolayer MoS₂ Film Growth:

Monolayer MoS₂ was deposited on epi-ready 2″ c-sapphire substrate by metalorganic chemical vapor deposition (MOCVD). An inductively heated graphite susceptor equipped with wafer rotation in a cold-wall horizontal reactor was used to achieve uniform monolayer deposition as previously described. Molybdenum hexacarbonyl (Mo(CO)₆) and hydrogen sulfide (H2S) were used as precursors. Mo(CO)₆ maintained at 10° C. and 650 Torr in a stainless-steel bubbler was used to deliver 1.1×10⁻³ sccm of the metal precursor for the growth, while 400 sccm of H₂S was used for the process. MoS₂ deposition was carried out at 1000° C. and 50 Torr in H₂ ambient, where monolayer growth was achieved in 18 min. The substrate was first heated to 1000° C. in H₂ and maintained for 10 min before the growth was initiated. After growth, the substrate was cooled in H₂S to 300° C. to inhibit decomposition of the MoS₂ films.

### MoS₂ Film Transfer to Local Back-Gate Islands:

To fabricate the 2D memtransistors, MOCVD grown monolayer MoS₂ film was transferred from the sapphire to SiO_{2/p}⁺⁺-Si substrate with local back-gate islands using PMMA (polymethyl-methacrylate) assisted wet transfer process. First, MoS₂ on sapphire substrate was spin coated with PMMA and then baked at 180° C. for 90 s. The corners of the spin-coated film were scratched using a razor blade and immersed inside 1 M NaOH solution kept at 90° C. Capillary action causes the NaOH to be drawn into the substrate/film interface, separating the PMMA/MoS₂ film from the sapphire substrate. The separated film was rinsed multiple times inside a water bath and finally transferred onto the SiO_{2/p}⁺⁺-Si substrate with local back-gate islands and then baked at 50° C. and 70° C. for 10 min each to remove moisture and residual PMMA, ensuring a pristine interface.

### Fabrication of 2D Memtransistors:

To define the channel regions for the memtransistors, the substrate was spin-coated with PMMA and baked at 180° C. for 90 s. The resist was then exposed to electron beam (e-beam) and developed using 1:1 mixture of 4-methyl-2-pentanone (MIBK) and 2 propanol (IPA). The monolayer MoS₂ film was subsequently etched using sulfur hexafluoride (SF6) at 5° C. for 30 s. Next, the sample was rinsed in acetone and IPA to remove the e-beam resist. To define the source and drain contacts, sample is then spin coated with methyl methacrylate (MMA) followed by A3 PMMA. Then using e-beam lithography source and drain contacts are patterned and developed by using 1:1 mixture of MIBK and IPA for 60s. 40 nm of Nickel (Ni) and 30 nm of Gold (Au) are deposited using e-beam evaporation. Finally, lift-off process is performed to remove the evaporated Ni/Au except from the source/drain patterns by immersing the sample in acetone for 30 min followed by IPA for another 30 mins. Each island contains one memtransistor to allow for individual gate control.

### Monolithic Integration:

To define the connections between the respective memtransistors the substrate was spin coated with MMA and PMMA, followed by the e-beam lithography and developing using 1:1 mixture of MIBK and IPA, and e-beam evaporation of 60 nm Au. Finally, the e-beam resist was rinsed away by lift-off process using acetone and IPA.

### Electrical Characterization:

Electrical characterization of the fabricated devices is performed using Lake Shore CRX-VF probe station under atmospheric condition using a Keysight B1500A parameter analyzer.

### Observation of Rich Defect Dynamics in Monolayer MoS₂

Defects play a pivotal role in limiting the performance and reliability of most nanoscale devices. Field effect transistors (FETs) based on atomically thin two-dimensional (2D) semiconductors such as monolayer MoS₂ are no exceptions. Probing defect dynamics in 2D FETs is, therefore, of significant interest. This study presents a comprehensive insight into various defect dynamics observed in monolayer MoS₂ FETs at varying gate biases and temperatures. The measured source to drain currents exhibit random telegraph signals (RTS) owing to the transfer of charges between the semiconducting channel and individual defects. Based on the modeled temperature and gate bias dependence, oxygen vacancies or aluminum interstitials are probable defect candidates. Several types of RTSs are observed including anomalous RTS and giant RTS indicating local current crowding effects and rich defect dynamics in monolayer MoS₂ FETs. This study explores defect dynamics in large area-grown monolayer MoS₂ with ALD-grown Al₂O₃ as the gate dielectric.

According to the International Roadmap for Devices and Systems (IRDS), atomically thin and semiconducting transition metal dichalcogenides (TMDCs) such as monolayer MoS₂ are promising alternatives to silicon for both low-power and high-performance logic devices at advanced technology nodes. Recent developments in high-performance field effect transistors (FETs) based on large-area synthesized monolayer MoS₂ and demonstration of integrated circuits for digital, analog, radio frequency (RF), and brain-inspired electronics justify its inclusion in the IRDS. Unsurprisingly, most studies on MoS₂ FETs focus on improvement in large area growth, optimization of transfer and fabrication process flow, contact and mobility engineering, the realization of scaled devices, etc., to meet the theoretical performance limit predicted by numerical simulations. However, less emphasis is laid on understanding the nature and origin of defects in MoS₂ FETs, which can ultimately limit performance and raise reliability concerns.

Defects in MoS₂ FETs can reside in the semiconducting channel such as sulfur vacancies, at the channel/dielectric interface, or in the dielectric stack. Their origin can be ascribed to growth imperfection, film transfer, fabrication processes, and fundamental properties of the gate dielectrics and their distinct defect bands. During device operation, these defects can exchange charges with the channel, affecting the device performance and reliability. Most reliability studies on MoS₂ FETs involve the investigation of bias temperature instabilities (BTI), which occur due to charge trapping in the oxide or at the trapping sites introduced by adsorbates and water molecules at the interface. Charge trapping can lead to a decrease in the field effect mobility, worsening of the subthreshold slope, hysteresis in the device transfer characteristics, as well as permanent or partially recoverable threshold voltage shifts.

Whereas BTI is a useful approach to studying the reliability of 2D FETs, a better understanding of the physical mechanisms of charge trapping and the nature of the involved defects can be obtained via the characterization of individual defects. Such characterization, however, requires ultra-scaled devices, which contain only a few defects within the channel area. In particular, when a single defect dominates the device response, discrete steps can be observed in the measured source to drain currents resulting in a random telegraph signal (RTS). Statistical analysis of RTS allows for the extraction of the capture and emission time constants, trap level, activation energy, and even the physical location of the defects offering insights into the microscopic properties of the defects.

Stampfer, B. et al. observed RTS from single defects in scaled FETs based on exfoliated multilayer MoS₂ with 50 nm×50 nm channel area. They found these defects are located either in the bulk SiO₂, which was used as the back gate dielectric, or at the SiO₂/MoS₂ interface, or on top of the channel arising from adsorbed water molecules and processing contaminants. Fang, N et al. and Li, L. et al. were also able to observe RTS in exfoliated mono- and multilayer MoS₂ FETs despite relatively large channel area (˜10-100 μm²), but at low temperatures <100 K. Interestingly, to the best of our knowledge, there is no report of observation of RTS in large area synthetic monolayer MoS₂ FETs, although previous works involving high-resolution transmission electron microscopy (TEM) and scanning tunneling microscopy (STM) have suggested sulfur monovacancies as the most abundant defect type in synthetic MoS₂.

This study reports the observation of RTS in metal-organic chemical vapor deposition (MOCVD) grown monolayer MoS₂-based FETs at varying gate biases and temperatures. By modeling the bias- and temperature dependence of the capture and emission time constants with a non-radiative multi-phonon model (NMP), possible defect candidates for the charge trapping in the Al₂O₃ gate oxide and their electronic and vibrational properties are identified. Several types of RTS are observed including anomalous RTS and giant RTS indicating local current crowding effects and rich defect dynamics in synthetic monolayer MoS₂ FETs using Al₂O₃ as a gate dielectric.

### Characterization of MOCVD-Grown Monolayer MoS₂ Films

FIGS. 7A-7I show fabrication and characterization of monolayer MoS₂ field effect transistor (FET). FIG. 7A shows Raman spectra obtained from MoS₂ film showing the characteristic in-plane

$${E}_{2 g}^{1} ,$$

out-of-plant A_{1g} Hours at 384 cm⁻¹ and 402 cm⁻¹ respectively, with a peak-to-peak distance of ˜18 cm⁻¹. Raman maps for (FIG. 7B)

$${E}_{2 g}^{1}$$

and (FIG. 1C) A_{1q} peak positions measured over a 50 μm×50 μm area. The mean and standard deviation values are shown in the inset. FIG. 7D shows photoluminescence (PL) spectra with characteristic monolayer peak at 1.82 eV. FIG. 7E shows a colormap for the PL peak position, measured over a 50 μm×50 μm area. The mean PL peak position was found to be at ˜1.83 eV with a standard deviation of ˜0.001 eV. FIG. 7 F shows atomic force microscopy (AFM) micrographs of the MoS₂ film indicating a coalesced monolayer film with a few oriented bilayer domains on top and a thickness of ˜0.7 nm. FIG. 7G shows a schematic of the MoS₂ FET with 50 nm atomic layer deposition grown Al₂O₃ as the gate dielectric and Pt/TiN/p⁺⁺-Si as the back-gate. The channel length (L) and width (W) were defined to be 500 nm and 5 μm, respectively. FIG. 7H shows transfer characteristics i.e., source-to-drain current (I_{DS}) versus back-gate voltage (V_{BG}) measured at a source-to-drain voltage, V_{DS}=1 V, for a representative MoS₂ FET at room temperature (T=300 K). FIG. 7I shows output characteristics, i.e., I_{DS} versus Vos measured using different V_{BG} for the same representative FET.

The monolayer MoS₂ utilized for this study was grown using MOCVD on 1 cm² c-plane sapphire substrates at a temperature of 1000° C. To ascertain the quality of the MoS₂ film used in this study, material characterization was performed using Raman spectroscopy and atomic force microscopy (AFM). FIG. 7A shows the Raman spectra obtained from a representative MoS₂ film where the characteristic in-plane

$${E}_{2 g}^{1}$$

mode and out-of-plant A_{1g} mode was observed at 384 cm⁻¹ and 402 cm⁻¹ respectively, with a peak-to-peak distance of ˜18 cm⁻¹. FIGS. 7B and 7C show the Raman maps for

$${E}_{2 g}^{1}$$

and A_{1g} peak positions measured over a 50 μm×50 μm area, respectively. The mean and standard deviation values for

$${E}_{2 g}^{1}$$

and A_{1g} were found to be ˜383.7 cm⁻¹ and ˜0.17 cm⁻¹ and ˜401.8 cm⁻¹ and 0.14 cm⁻¹, respectively. FIG. 7D shows the photoluminescence (PL) spectra with a characteristic monolayer peak at 1.82 eV. FIG. 7E shows the colormap for the PL peak position, measured over a 50 μm×50 μm area. The mean PL peak position was found to be at ˜1.83 eV with a standard deviation of ˜0.001 eV. The surface morphology and thickness of the film were characterized by AFM. FIG. 7F shows the AFM micrographs of the MoS₂ film indicating a coalesced monolayer film with a few oriented bilayer domains on top and a thickness of ˜0.7 nm. The underlying morphology in the monolayer region arises from steps in the sapphire substrate. Nevertheless, the results of the material characterization indicate the high-quality growth of the films.

### Fabrication and Characterization of Monolayer MoS₂ FETs

Monolayer MoS₂ FETs employed for this study use a global back-gated architecture with 50 nm atomic layer deposition grown Al₂O₃ as the gate dielectric, and Pt/TiN/p⁺⁺-Si as the back-gate electrode. FIG. 7G shows the schematic for the MoS₂ FET. The monolayer MoS₂ films were transferred from the growth substrates (sapphire) onto the target substrates via the poly methyl methacrylate (PMMA)-assisted wet-transfer process. Following the transfer, electron beam (e-beam) lithography and dry etching using SF₆ plasma were used to isolate the channel area. The channel length (L) and width (W) were defined to be 500 nm and 5 μm, respectively. Next, the source and drain contacts were defined using another set of e-beam exposures. Finally, e-beam evaporation was performed to sequentially deposit 40 nm Ni and 30 nm Au to serve as the contacts for the FETs. FIG. 7H shows the transfer characteristics i.e., source-to-drain current (I_{DS}) versus back-gate voltage (V_{BG}) measured at a source-to-drain voltage, I_{DS}=1 V, for a representative MoS₂ FET at room temperature (T 300 K). As expected, monolayer MoS₂ FETs exhibit dominant n-type transport owing to the pinning of the metal Fermi level close to the conduction band. FIG. 7I shows the output characteristics, i.e., I_{DS} versus V_{DS} measured using different V_{BG} for the same representative FET.

### Observation of RTS in Monolayer MoS₂ FETs

FIGS. 8A-8E show observation of random telegraph signals (RTS) in monolayer MoS₂ FET. FIG. 8A shows transfer characteristics of a monolayer MoS₂ FET measured using V_{DS}=1 V at different temperatures, T=15, 50, 100, 200, and 300 K and (FIG. 8B) corresponding I_{DS} sampled every τₛ=4 ms at V_{BG}=1.5, 1.5, 0.75, −0.25, and −2 V, respectively. RTS is observed for T<200 K. FIG. 8C shows power spectral density (PSD) obtained using the fast Fourier transform (FFT) of I_{DS} in FIG. 8B. Presence of RTS is associated with a Lorentzian profile in the frequency domain, i.e., slope=1/ƒ², whereas absence of RTS is associated with a flicker noise profile in the frequency domain, i.e., slope=1/ƒ. FIG. 8D shows a histogram plot for I_{DS} in FIG. 8B. Presence of RTS is associated with two distinct Gaussian distributions, whereas absence of RTS is associated with a single Gaussian distribution. FIG. 8E shows a Time Lag Plot (TLP) for I_{DS} in FIG. 8B. TLP involves the plotting of time-domain I_{DS} data in an x-y plane, where the x-values represent the i^{th} and the y-values represent the i+1^{th} time series data for I_{DS}. In a strictly, two-level state transition dynamics, corresponding to a single defect, one would expect a rectangular TLP with only the four corner points. However, at any finite temperature, the discrete current points transform into clusters, whereas the transition points get distributed along the arms of the rectangular feature. As the temperature increases, the clusters start to spread more and eventually coalesce into a single diagonal line as seen from the TLPs corresponding to the I_{DS} measured at T >200 K.

The impact of individual defects on silicon-based field effect transistors (FETs) has been extensively studied. It is well known that the capture and emission of charges by the defect sites lead to a shift in the threshold voltage (V_{TH}) of the device, which manifests as hysteresis in the FET transfer characteristics. The stochastic nature of charge carrier capture and emission can lead to temporal fluctuations in the source-to-drain current when measured at constant source-to-gate and source-to-drain biases. In fact, discrete steps can be observed in I_{DS} if only a handful of defects are present in the channel area and cause notable changes in the electrostatics of the device. Such an I_{DS} profile is referred to as RTS. This is generally the case in ultra-scaled devices where a reduction in the channel area leads to the confinement of a few defects with each defect having a considerable impact on the device characteristics. RTS can also be observed in relatively large-area devices when measured at low temperatures. This can be attributed to the fact that only a few defect states are energetically accessible for the charge carriers at low temperatures and that the current flow can be locally constrained, thereby causing sizable step heights.

FIG. 8A shows the dual-sweep transfer characteristics of a monolayer MoS₂ FET measured using V_{DS}=1 V at different temperatures, T=15, 50, 100, 200, and 300 K. While the transfer characteristics, measured at all temperatures, show hysteresis, discrete steps are observed only at low temperatures, i.e., T 300 K as highlighted in the insets of FIG. 8A. FIG. 8B shows the I_{DS} sampled every τₛ=4 ms at V_{BG} 1.5, 1.5, 0.75, −0.25, and −2 V for T=15, 50, 100, 200, and 300 K, respectively. Clearly, strong RTS signals are observed for T 200 K. Note that different V_{BG} biases were chosen for the RTS measurements to ensure a similarly large I_{DS} range, hence a comparison of the RTS close to Vₜₕ. As expected, the RTS signal is most prevalent at 15 K and gradually disappears with increasing T and completely vanishes for T 300 K. The temperature dependence of RTS can also be explained by analyzing the frequency spectrum of the time-domain I_{DS} measurements. FIG. 8C shows the power spectral density (PSD) obtained using the fast Fourier transform (FFT) of I_{DS} in FIG. 8B. Note that, the PSD shows characteristics 1/ƒ profile for T≥200 K, whereas a Lorentzian profile (slope=1/ƒ²) is observed for T 200 K. This can be explained using the Mcwhorter model, which states that carrier capture and emission by defect states in the dielectric are elastic tunneling events and each event is associated with a characteristic time constant that is related to the depth profile of the corresponding defect. These discrete tunneling events manifest as RTS in the time domain and as a Lorentzian spectrum in the frequency domain. Furthermore, the summation of all RTS events, each with different characteristic time constants, is the origin of the universally observed 1/ƒ noise spectra in the frequency domain. In other words, at low temperatures, i.e., for T 1/ƒ 200 K, only one or few energetically active defect states are accessible for carrier capture and emission leading to discrete state fluctuations or RTS in the time domain and Lorentzian spectrum in the frequency domain, whereas, at higher temperatures, more defect states are accessible resulting in the superposition of several discrete state RTS that leads to continuous fluctuations in the time domain and 1/ƒ spectra in the frequency domain. Note that the elastic tunneling model cannot explain either the difference in capture and emission time constants which are typically observed or the pronounced temperature dependence of the capture time. To explain the temperature dependence, Kirton and Uren realized that the model needs to account for the structural relaxations at the defect site by introducing a phenomenological Boltzmann factor. Their model was further refined in the non-radiative multi-phonon (NMP) model where the gate bias and temperature dependence of the time constants are correctly described based on phonon-mediated structural relaxations at the defect site.

Another way to visualize the presence of RTS is to plot the histograms of the measured I_{DS} as shown in FIG. 8D. The presence of RTS is associated with the observation of two or more Gaussian distributions as seen from the histograms corresponding to I_{DS} measured at T=15, 50, and 100 K, whereas the absence of RTS is associated with a single Gaussian distribution as seen from the histograms corresponding to I_{DS} measured at T=200 and 300 K. Also note that the histogram plots for RTS traces with only two discrete states corresponding to the involvement of a single defect should translate into two delta distributions centered at the two current values. However, at a finite temperature, such distributions are always broadened into Gaussian distributions. With increasing temperature, the involvement of an increased number of defect states leads to broadening of the Gaussian distributions and introduction of additional distributions. Finally, at higher temperatures, e.g., for T <200 K, the analog and random fluctuations in I_{DS} convert the histogram plots into one unified Gaussian distribution. While the PSD and histogram plots are useful techniques, these are less effective in reducing the complexity of the RTS waveform, which is a major obstacle in understanding the defect dynamics in nanoscale devices.

To overcome the aforementioned challenge, Nagumo et. al have outlined the use of a Time Lag Plot (TLP). A TLP involves the plotting of time-domain I_{DS} data in an x-y plane, where the x-values represent the i^{th} and the y-values represent the i+1^{th} time series data for I_{DS}. FIG. 8E shows the TLP corresponding to the I_{DS} shown in FIG. 8B. In TLP, the points along the diagonal represent different current values, whereas the points outside the diagonals represent the state transitions. When RTS is present, multiple discrete clusters appear as can be seen in the TLP corresponding to the I_{DS} measured at T 200 K. In a strictly, two-level state transition dynamics, corresponding to a single defect, one would expect a rectangular TLP with only the four corner points. However, at any finite temperature, the discrete current points transform into clusters, whereas the transition points get distributed along the sides of the rectangular frame. As the temperature increases, the clusters start to spread more and eventually coalesce into a single diagonal line as seen from the TLPs corresponding to the I_{DS} measured at T <200 K. Furthermore, TLPs also offer insights into how long the system spends on one of the two states as well as how often state transitions take place. In other words, it provides a visual representation of the carrier capture and emission by the defect states.

A central drawback of the histogram and TLP methods is their reliance on absolute values of the signal for obtaining defect states. For example, a small drift of the drain current level over time can easily obfuscate defect states with smaller step heights, reducing the overall number of detected defects. Furthermore, both methods require a relatively high signal-to-noise ratio to work. To overcome these difficulties, edge detection algorithms can be used to obtain the positions and amplitudes of the discrete steps in the RTS. In this work, the Canny edge-detection algorithm was used to detect step edges based on a Gaussian derivative as a filter function.

### Gate-Bias-Dependent RTS for Extracting the Physical Location of Defects

FIGS. 9A-9G show gate-bias dependent RTS for extracting energetic and physical location of defect. FIG. 9A shows RTS traces and FIG. 9B shows corresponding TLPs obtained for V_{BG}=0.5, 1, and 1.5 V at T=15 K. The V_{BG} range was chosen such that the two-state defect dynamics dominate. Here, the time spent in the lower state is referred to as the capture time and the time spent in the upper state as the emission time, i.e., τ_{c} and τₑ, respectively. Normalized histogram plots on a logarithmic time scale for (FIG. 9C) τ_{c} and (FIG. 9D) τₑ showing the probability density of observing an event with a certain time constant. Insets show the Gaussian kernel density estimates used for extracting t̅_̅{̅c̅}̅ and t̅ₑ̅. FIG. 9E shows t̅ₑ̅ and t̅_̅{̅c̅}̅ as a function V_{BG}. FIG. 9F shows the relative energetic location of the defect with respect to the Fermi level in the semiconducting channel, i.e., E_{T}−E_{F} as a function of V_{BG}. FIG. 9G shows t̅ₑ̅ and t̅_̅{̅c̅}̅ as a function of V_{BG} at temperatures of 15 K, 50 K and 100 K.

Further insights into the defect dynamics can be obtained by studying the impact of V_{BG} on the RTS. FIG. 9A shows the RTS traces obtained for V_{BG} 0.5, 1, 1.5 V at T=15 K and FIG. 9B shows the corresponding TLPs, respectively. While the TLPs mostly exhibit two major clusters along the diagonals, for some V_{BG} values a metastable state is observed in the TLPs. However, for ease of analysis, we will ignore these metastable states and consider the dynamics to be primarily dominated by two states. This will allow us to extract the average capture and emission time constants, i.e., τ̅_̅{̅c̅}̅ and τ̅ₑ̅, which in turn will offer insights into the energetic location of the defect state. For ease of reference, the cluster representing lower and higher current values in the TLP is denoted as states “0” and “1”, and the time spent in these two states are referred to as the capture and emission times, i.e., τ_{c} and τₑ, respectively. These times are evaluated as the difference between two subsequent step edges, detected with the Canny algorithm as shown in FIG. 9A, and their respective distributions shown in FIGS. 9C and 9D as probability density functions (PDFs) of the exponentially distributed τ_{c} and τₑ on a logarithmic scale. Based on the Gaussian fits, to the PDFs, τ̅_̅{̅c̅}̅ and τ̅ₑ̅ can be extracted. FIG. 9E shows τ̅_̅{̅c̅}̅ and τ̅ₑ̅ as a function of V_{BG}. It is known that the ratio of τ̅ₑ̅ and τ̅ₑ̅ reflects the energetic location of the defect states with respect to the Fermi level (E_{F}) in the semiconducting channel following:

$$\frac{\overline{{τ}_{c}}}{\overline{{τ}_{e}}} = exp ( \frac{{E}_{T} - {E}_{F}}{kT} )$$

E_{T} is the energy level of the trap and k is the Boltzmann constant. FIG. 9F shows E_{T}−E_{F} as a function of V_{BG}. Note that with increasing V_{BG}, τₑ is mostly constant, whereas τ_{c} decreases. This implies that at a lower V_{BG}, e.g., at 0.5 V, the defect state is mostly empty for t_{c}>τₑ, whereas at higher V_{BG}, e.g., at 2 V, the defect state is mostly occupied as the emission time is longer than the capture time (τₑ>τ_{c}). Finally, from the slope of FIG. 9F, we can determine the physical location (λ) of the defect with respect to the thickness (tₒₓ) of the oxide using:

$$\frac{λ}{{t}_{ox}} = - \frac{kT}{q} \frac{\partial ln ( \frac{\overline{{τ}_{c}}}{\overline{{τ}_{e}}} )}{\partial {V}_{BG}}$$

We found that λ2˜1.2 nm from the interface.

As a next step, we have applied the Canny algorithm and the formalism to extract the capture and emission time constants as described above to analyze the time constants as a function of the gate bias and the temperature as shown in FIG. 9G. During the analysis we found that for increasing temperatures, e.g., 100 K and above, the time constants of the observed defect become increasingly fast, faster than the sampling time of τₛ=4 ms. For extracting time constants to a high degree of certainty they must be slower than about ten times the sampling time, as shown in FIG. 9G.

### Modeling RTS for Extracting the Vibronic Defect Properties

FIG. 10A-10G shows modeling the temperature and gate-bias dependence to extract vibronic defect properties. FIG. 10A shows a configuration coordinate diagram for the transition of the defect configuration between the charged and the uncharged states. FIG. 10B shows a band diagram for Al₂O₃ and MoS₂ showing the energetic alignment of the trap level E_{T}, that is shifted by the applied gate bias at a gate contact to the left of the diagram. Modeled time constants as a function of temperature for different gate biases of (FIG. 10C) V_{BG}=0.5 V, (FIG. 10D) 0.75 V, (FIG. 10E) 1 V and (FIG. 10F) 1.25 V. For a relaxation energy of Eᵣₑₗₐₓ=0.31 eV and a configuration coordinate distance of ΔQ=2.03 Å\sqrt{u}, the root mean square error amounts to 0.15 s. FIG. 10G shows the shift E_{T} of the charged state α as a function of the gate bias corresponds to a distance of 1.1 nm for the charge trap from the interface.

For learning more about the atomic nature of the defect, we model the temperature and bias dependence of the capture and emission time constants using the NMP model. When an electron is exchanged between a charge reservoir, like the conduction band of MoS₂, and a local point defect in the vicinity, this charge transfer is accompanied by local deformations and relaxations of the defect sites. Hence, for accurately modeling RTS, electron-phonon coupling must be described, accounting for both the movement of electrons and nuclei. The atomic movements are represented within diabatic potential energy curves (i.e., crossing potential energy surfaces at a fixed charge state) along the reaction path of the charge transfer reaction. Such a configuration coordinate diagram for an oxide defect is shown in FIG. 10A. The transition takes place between the state a where the defect has captured an electron and the state β where there is no electron at the defect site. Both equilibrium states of the defect are approximated using a parabola. If a potential is applied to the gate, the potential shift of the parabola describing state α is given by the potential shift of the trap level within the oxide as shown in FIG. 10B.

$$\frac{{dE}_{T}}{{dV}_{g}} = \frac{q λ}{{t}_{ox}} ( 1 - \frac{d {ψ}_{S}}{{dV}_{G}} ) \approx \frac{q λ}{{t}_{ox}} ,$$

with the surface potential Ψ_{S}, an expression that is equivalent to

$$\frac{λ}{{t}_{ox}} = - \frac{kT}{q} \frac{\partial ln ( \frac{\overline{{τ}_{c}}}{\overline{{τ}_{e}}} )}{\partial {V}_{BG}}$$

under the assumption of a constant surface potential in accumulation.

In the following, we evaluate this expression by modeling the temperature dependence of the capture and emission time constants for varying gate biases in a full quantum mechanical NMP model. The background, assumptions, and derivation of this model are described in more detail in the Methods section. The NMP transition rates are the inverse of the experimentally determined capture and emission time constants k_{C}=1/τ_{c}=kᵢⱼ and are given by,

$${k}_{ij} = {A}_{ij} {f}_{ij}^{LSF} , {f}_{ij}^{LSP} = {ave}_{α} ( {\sum }_{β} {\vert 〈 {η}_{i , α} \vert {η}_{j , β} 〉 \vert}^{2} δ ( {E}_{i , α} - {E}_{j , β} ) ) ,$$

$${A}_{ij} = \frac{2 π}{h} {\vert 〈 {ϕ}_{i} \vert {H}_{e , i} \vert {ϕ}_{j} 〉 \vert}^{2} ,$$

with the electronic wave functions Φᵢ, Φⱼ, the vibrational states η_{i.α}, η_{i.β}, describing the nuclei configurations, the electronic matrix element Aᵢⱼ determined by the electronic Hamiltonian Hₑₗ, and the line-shape function

$${f}_{ij}^{LSF}$$

governing the vibrational interactions. Aᵢⱼ can, in good approximation, be evaluated by the tunneling factor for the electron from the delocalized state at the band edge to the defect site within the Wentzel-Kramers-Brillouin (WKB) approximation. As such, Aᵢⱼ is temperature independent. Hence, when studying the temperature dependence of the charge capture and emission processes the line shape function needs to be evaluated. The vibrational wave functions of the two involved defect configurations can overlap not only at but also below the intersection point of the two parabolas, as shown in FIG. 10A. These overlaps allow the system to transition at an effectively lower barrier, a phenomenon which is termed “nuclear tunneling”. To model the charge transfer rates at cryogenic temperatures, the line shape function as given above is evaluated for the two harmonic defect states, governed by the properties of the two parabolas in FIG. 10A. First, they depend on the shift of the parabola of the charged state E_{T} as a function of the gate bias V_{BG}. Second, the cryogenic lineshape function depends on the distance of the two parabolas and hence on the difference in the configuration coordinate ΔQ. Third, the transition rates depend on the shape of the parabolas, which is determined by the relaxation energy Eᵣₑₗₐₓ=C_{α}(ΔQ)², where c_{α} is the curvature of the parabola describing state a. The temperature dependence of the time constants in FIG. 9G is modeled with three parameters E_{T}, ΔQ, and Eᵣₑₗₐₓ. Out of these Er depends on the gate bias, hence, we can fit the temperature dependence for varying V_{BG} values with the same values for ΔQ and Eᵣₑₗₐₓ in FIGS. 10C-10F with a small root mean squared error of 0.15 s. Hence, these two parameter-sets determine boundaries for the possible ranges of the parameter values. Based on the slope of the trap level shift E_{T} as a function of the applied gate voltage ΔV_{g} shown in FIG. 10G, an interface distance can be estimated to be within the range of 1.1 nm and 1.2 nm. The trap level of the active defect was determined to be about 0.01 eV above the conduction band edge of MoS₂, which is about 3.9 eV above the valence band edge of Al₂O₃. All the vibrational and electronic properties of the observed defects, causing RTS are summarized in Table 2.

TABLE 2
Defect parameters of the charge trap causing the RTS signal

| Defect parameter | Lower limit | | Upper limit | |
|---|---|---|---|---|
| Relaxation energy Eᵣₑₗₐₓ | 0.3 | eV | 1 | eV |
| Configuration coordinate distance ΔQ | 2 Å√u | | 2.4 Å√u | |
| Trap level E_{T} above Al₂O₃ E_{VB} | 3.9 | eV | 4 | eV |
| Interface distance d | 1.1 | nm | 1.2 | nm |

Parameters were extracted based on the modeled line shape function describing the low-temperature vibrational response of the charge transfer.

Firstly, the distance of more than 1 nm from the interface shows that we are likely dealing with an oxide defect within the Al₂O₃ gate oxide which causes the observed RTS. The extracted defect level E_{T} is within a range that corresponds to the defect levels of an oxygen vacancy or an aluminum interstitial. The vibronic properties on the other hand (i.e., the small dQ) show that the charge transfer is dominated by nuclear tunneling, leading to the observed temperature independence at low temperatures. In non-glass-forming oxides, like Al₂O₃ or HfO₂, the relaxation energies of point defects are typically on the order of about 1 eV, further confirming the hypothesis an oxygen vacancy or Al interstitial in the ALD-deposited Al₂O₃ causing the RTS.

### Observation of Giant and Anomalous RTS

FIGS. 11A-11E show rich defect dynamics in monolayer MoS₂ FET. FIG. 11A shows giant RTS measured at T=15 K at a V_{BG}=1.5 V. The

$$\frac{Δ {I}_{DS}}{{I}_{DS}}$$

was found to be ˜80% FIG. 11B shows

$$\frac{Δ {I}_{DS}}{{I}_{DS}}$$

as a function of V_{BG}. RTS is expected if the number of defects within the device falls into the red shaded area, the single defect limit as shown in FIG. 11D. For the MoS₂/Al₂O₃FETs studied here, 20,000 active defects are expected to be located within the device area. As the single-defect limit is not reached, an effectively locally narrowed channel region is observed. The border trap densities shown as symbols are taken from literature. Anomalous RTS and corresponding TLPs showing (FIG. 11E) three discrete current levels. The RTS and the corresponding TLP in FIG. 11E indicate the involvement of a metastable state in addition to one regular trap state.

Giant RTS have been reported in the past for scaled Si FETs as well as carbon nanotube (CNT) FETs. Campbell et. al have observed giant RTS in the sub-threshold operation regime in a scaled n-type Si FET. Their RTS trace revealed

$$\frac{Δ {I}_{DS}}{{I}_{DS}} > 25 \%$$

where, ΔI_{DS} corresponds to the difference between the two discrete current levels. Similarly, Asenov et. al have reported

$$\frac{Δ {I}_{DS}}{{I}_{DS}} \sim 60 \%$$

in sub-100 nm Si FETs with dopant atoms. Fantini et. al have investigated the RTS as a function of carrier concentration. Their study revealed that the measured RTS had an amplitude that was an order of magnitude higher than what was predicted by the classical theory of carrier number and correlated mobility fluctuations. Beyond Si FETs, Liu et. al observed giant RTS in ultra-scaled CNT FETs with

$$\frac{Δ {I}_{DS}}{{I}_{DS}}$$

as high as 60%. FIG. 11A shows the giant RTS obtained from our relatively large area monolayer MoS₂ FETs measured at T=15 K at a V_{BG}=1.5 V. The

$$\frac{Δ {I}_{DS}}{{I}_{DS}}$$

was found to be ˜80%. FIG. 11B shows the corresponding TLP indicating the two discrete current levels. FIG. 11C shows

$$\frac{Δ {I}_{DS}}{{I}_{DS}}$$

as a function of V_{BG}. Clearly, the RTS strength diminishes as the device is biased from the subthreshold into the on-state.

In general, it should be noted that the observation of an RTS signal in these large area devices is unusual, even more so in the large step heights. For typical defect densities of 8·10¹¹ cm⁻² there should be as many as 20,000 defects within the device area of 2.5 μm². This approximate number is considerably above the single-defect limit of around 100 defects where one would expect to see charge capture and emission by single defects as RTS for specific bias and temperature conditions, see FIG. 11D. The observation of single defect charge capture and emission is a strong indication that the channel is narrowed considerably at a certain point because of local defects, thereby reducing the effective active area of the MoS₂ FETs. In addition, the observed step heights of the RTS signals are much larger than what would be expected for devices with an area of 2.5 μm². In general, the step heights scale proportionally to the area of the FETs, as in a narrower and shorter channel one defect has a larger impact on the electrostatics and the current flow. Hence, the observed large step heights must be explained by a defect located within the MoS₂ FET which is particularly critical for the current conduction. Based on these considerations, it seems plausible that the defect observed here is either an O-vacancy or an AI-interstitial close to the surface of Al₂O₃ which is aligned close to a step edge of bilayer islands on top of MOCVD-grown monolayer MoS₂ film, as the conduction of current across different layers is much smaller than within the layer. Moreover, potential contaminants at the interface of the wet-transferred MOCVD-grown MoS₂ and the Al₂O₃ could also locally confine the current flow in the device. In addition, an oxide defect close to the source contact of the FET would cause larger step heights, as the charge injection over the Schottky barriers is a limiting factor in 2D TMD-based FETs. All the above factors could contribute to the effect of current crowding where the effective width of the FET is much narrower than the nominal 5 μm.

Apart from the normal two-state RTS induced by a single defect having two discrete current levels, more complex RTS with multiple states have been observed in our monolayer MoS₂ FETs. These include RTS with three, four, and five discrete current levels. These types of RTS fall under the category of anomalous RTS with varying numbers of metastable states and have been reported in the literature. FIG. 11E shows the RTS traces and corresponding TLPs for three discrete current levels are shown. Usually, a single trap state causes RTS with two current levels, whereas n trap states should lead to 2ⁿ current levels in the RTS and 2ⁿ clusters in the TLP. The involved states can be metastable and are linked to each other either via pure thermal transitions or charge transitions. In the first case, only a reconfiguration of the defect configuration takes place, whereas, in the charge transition, this is accompanied by an electron capture or emission event. For example, the RTS and the corresponding TLP in FIG. 11E indicate the involvement of a metastable state in addition to one regular trap state, hence when the trap has captured an electron it can either stabilize in the metastable state 2 or relax into state 3. These transitions are modeled within a Hidden Markov Model by connecting these three states in a Markov chain. However, the more states are involved, the more statistics are required to extract the average capture and emission time constants as well as trap properties of all the involved states. In addition, more visible states in the signal render it increasingly difficult to distinguish between a defect with multiple states, or two independent active charge traps which are superimposed in the signal.

In conclusion, we have studied the dynamics of single defects in a large area grown monolayer MoS₂ FET. By changing the temperature and the gate bias we can observe diverse RTS and extract information on the energetics, vibrational properties, and physical location of the defect. In this way, we observed nuclear tunneling at low temperatures and could identify charge trapping at an Al interstitial or O vacancy at about 1.2 nm distance from the interface as a dominant defect candidate. In addition, the observation of RTS signals and large step heights in these large area 2D FETs, indicate that oxide traps in the vicinity to the Schottky barriers at the contacts or close to step edges in the bilayer islands on top of MOCVD-grown monolayer MoS₂ could cause current crowding, thereby effectively narrowing down the channel of the devices and increasing the step heights. Using detailed characterization and modeling techniques, we report the observation of RTS in FETs based on large area-grown monolayer MoS₂ with ALD-grown Al₂O₃ as the gate dielectric. We also discuss various characterization approaches utilized in this study for RTS analysis including PSD, TLP, histogram plots, edge detection methods, and non-radiative multiphonon models. Finally, we discuss several types of RTS including giant RTS, multi-state RTS, and anomalous RTS indicating rich defect dynamics in monolayer MoS₂ FETs.

### Methods

### Large-Area Monolayer MoS₂ Film Growth

Uniform monolayer MoS₂ films are grown on 1 cm² c-plane sapphire substrates (Cryscore Optoelectronic Ltd, 99.996% purity) using a custom-built metal-organic chemical vapor deposition (MOCVD) system. The MOCVD chamber is equipped with a stainless-steel bubbler containing 10 g of Mo(CO)₆ (99.99% purity, Sigma-Aldrich) which serves as the Mo precursor source, and a 500 ml H₂S (99.5%, Sigma-Aldrich) lecture bottle which provides sulfur during synthesis. Before introducing Mo(CO)₆ and H₂S, 2 s.l.m. of high-purity argon (Ar) gas, is continuously flown through the chamber, and serves as the main push gas to deliver precursors to the substrate. During film synthesis, chamber temperature and pressure are set to 1000° C. and 50 Torr, respectively. Like prior reports, we employ a multistep growth process comprising nucleation, ripening, and lateral growth stages to better control the nucleation rate on the sapphire substrates. Mo(CO)₆ is injected at flow rates of 1.5×10⁻³ and 7.5×10⁻⁴ sccm during the nucleation and lateral growth steps, respectively. H₂S flow is maintained at 20 sccm throughout the entire growth process. Complete monolayer coalescence is achieved after 42 minutes of total growth time.

### H₂S Annealing

H₂S annealing is performed ex-situ in the same MOCVD chamber used for MoS₂ film synthesis. Monolayer MoS₂ samples are placed on alumina crucibles (AdValue Tech, >99.6% purity) placed at the center of the hot zone. The furnace is ramped up to 500° C. (the annealing temperature) at a rate of 50° C./min. 40 sccm of H₂S and 2 s.l.m. are continuously flown through the chamber and serve as the S source and push gas, respectively. The annealing process is carried out at a pressure of 50 Torr for a total time of 30 minutes.

### Application Substrate Preparation and MoS₂ Film Transfer

To fabricate the 2D memtransistors, the MOCVD-grown monolayer MoS₂ film first had to be transferred from the sapphire growth substrate to the application substrate, which consisted of a global Al₂O₃/Pt/TiN/p⁺⁺-Si back-gate stack. The TiN and Pt layers were deposited using reactive sputtering with the underlying Si and a back-gate electrode, respectively. 50 nm of Al₂O₃ (εₒₓ≈10) was grown on the Pt electrode via atomic layer deposition (ALD) to act as the back-gate dielectric. Film transfer was performed using a polymethyl-methacrylate (PMMA)-assisted wet transfer process [63, 64]. First, the as-grown MoS₂ on the sapphire substrate was spin-coated with PMMA and baked at 150° C. for 90 s to ensure good PMMA/MoS₂ adhesion. The edges of the spin-coated film were then scratched using a razor blade and the substrate was immersed inside a deionized (DI) water bath held at 90° C. for 1 hr. Capillary action caused the water to be preferentially drawn into the substrate/MoS₂ interface, owing to the hydrophilic nature of sapphire and hydrophobic nature of MoS₂ and PMMA, separating the PMMA/MoS₂ stack from the sapphire substrate. The separated film was then fished from the water bath using the application substrate. Subsequently, the substrates were baked at 50° C. and 70° C. for 10 min each to remove moisture and promote film adhesion, thus ensuring pristine interfaces, before the PMMA was removed by immersing the samples in acetone for 12 hrs followed by a 30 min 2-propanol (IPA) clean.

### Fabrication of 2D FETs

To define the channel regions of the MoS₂ FETs discussed in this work, the application substrates, with MoS₂, transferred on top, were spin-coated with PMMA A6 (4000 RPM for 45 s) and baked at 180° C. for 90 s. The resist was then exposed using electron beam (e-beam) lithography and developed using a 1:1 mixture of 4-methyl-2-pentanone (MIBK) (60 seconds) and IPA (45 seconds). The exposed monolayer MoS₂ film was subsequently etched using a sulfur hexafluoride (SF₆) reactive ion etching (RIE) at 5° C. for 30 s; Next, the samples were rinsed in acetone and IPA to remove the e-beam resist. To define the source and drain contacts, samples were then spin-coated with a bilayer resist consisting of methyl methacrylate (MMA) and A3 PMMA. E-beam lithography was used to define the source and drain contacts and development was performed using the same 1:1 mixture of MIBK and IPA. E-beam evaporation was used to deposit the contact metals 40/30 nm Ni/Au. Finally, a lift-off process was performed to remove excess resist and metal by immersing the sample in acetone for 1 hr followed by IPA for another 30 mins.

### Raman and Photoluminescence (PL) Spectroscopy

Raman and PL spectroscopy of the pre- and post-irradiation MoS₂ film were performed on a Horiba LabRAM HR Evolution confocal Raman microscope with a 532 nm laser. The power was 34 mW filtered at 5% to 1.7 mW. The objective magnification was 100× with a numerical aperture of 0.9, and the grating had a spacing of 1800 gr/mm for Raman and 300 gr/mm for PL.

### Electrical Characterization

Electrical characterization of the fabricated devices was performed in a Lake Shore CRX-VF probe station under atmospheric conditions using a Keysight B1500A parameter analyzer.

### NMP Model

The non-radiative multi-phonon model accounts for the electron-phonon coupling which drives the charge transfer between the atomic defect and the charge reservoir (i.e., conduction band) by modeling the reaction within diabatic potential energy curves in a parabolic approximation close to the minima of the potential energy curves. In a first-order perturbation approach, Fermi's golden rule can be applied to calculate the transition rate for the two states involved, consisting of both electrons, described by the electronic wave functions Φᵢ, Φⱼ, and nuclei states represented by the vibrational states η_{i.α}, η_{i.β},

$${k}_{i α , j β} = \frac{2 π}{ℏ} {\vert {M}_{i , α , j β} \vert}^{2} δ ( {E}_{i , α} - {E}_{j , β} ) , {\vert {M}_{i , α , j β} \vert}^{2} = 〈 {η}_{i , α} \vert 〈 {ϕ}_{i} \vert H \vert {ϕ}_{j} 〉 \vert {η}_{j , β} 〉 .$$

Here, the Hamiltonian H describes the interaction between the electronic states and the vibrational states, and the transitions occur where the energies of the states of the initial state E_{iα} and the final state E_{jβ} are the same. As the electronic states vary only weakly with the nuclei coordinates, the Franck-Condon principle can be applied, and the transition rate can be reformulated as a product of the electronic matrix element Aᵢⱼ and the lineshape function ƒᵢⱼ^{LSF}. While the matrix element describes the likelihood of an electronic transition, the line shape function contains all vibrational interactions caused by the lattice reconfigurations at the defect site. For describing these vibrational interactions, the sum over all modes β weighted by their respective occupation probabilities according to Boltzmann factors need to be formed and averaged over all populated initial states α. The NMP transition rates are the inverse of the experimentally determined capture and emission time constants k_{C}=1/τ_{c}=kᵢⱼ and are given by,

$${k}_{ij} = {A}_{ij} {f}_{ij}^{LSF} , {f}_{ij}^{LSP} = {ave}_{α} ( {\sum }_{β} {\vert 〈 {η}_{i , α} \vert {η}_{j , β} 〉 \vert}^{2} δ ( {E}_{i , α} - {E}_{j , β} ) ) ,$$

$${{A}_{ij} = \frac{2 π}{h} \vert 〈 {ϕ}_{i} \vert {H}_{e , i} \vert {ϕ}_{j} 〉 \vert}^{2} ,$$

with the electronic wave functions Φᵢ, Φⱼ, and the vibrational states η_{i.α}, η_{i.β}, describing the nuclei configurations. For more information about the evaluation of these expressions.

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the devices, systems, circuits, and methods of using and making the same disclosed herein have been discussed and illustrated, it is to be distinctly understood that the invention is not limited thereto but may be otherwise variously embodied and practiced within the scope of the following claims.

### REFERENCES

The following references are incorporated herein by reference in their entireties.
[1] D. A. Reed and J. Dongarra, “Exascale computing and big data,” Communications of the ACM, vol. 58, pp. 56-68, 2015.
[2] X.-k. Liao, K. Lu, C.-q. Yang, J.-w. Li, Y. Yuan, M.-c. Lai, et al., “Moving from exascale to zettascale computing: challenges and techniques,” Frontiers of Information Technology & Electronic Engineering, vol. 19, pp. 1236-1244 Oct. 1 2018.
[3] M. Yamaoka, T. Okuyama, S. Tanaka, M. Hayashi, and C. Yoshimura, “New computing paradigm for analyzing increasingly complex social infrastructure systems,” Hitachi Review, vol. 64, pp. 525-531, 2015.
[4] G. Indiveri and S.-C. Liu, “Memory and information processing in neuromorphic systems,” Proceedings of the IEEE, vol. 103, pp. 1379-1397, 2015.
[5] B. R. Gaines, “Stochastic computing,” in Proceedings of the Apr. 18-20, 1967, spring joint computer conference, 1967, pp. 149-156.
[6] W. Poppelbaum, C. Afuso, and J. Esch, “Stochastic computing elements and systems,” in Proceedings of the Nov. 14-16, 1967, fall joint computer conference, 1967, pp. 635-644.
[7] S. C. Smithson, N. Onizawa, B. H. Meyer, W. J. Gross, and T. Hanyu, “Efficient CMOS invertible logic using stochastic computing,” IEEE Transactions on Circuits and Systems I: Regular Papers, vol. 66, pp. 2263-2274, 2019.
[8] A. Ardakani, F. Leduc-Primeau, N. Onizawa, T. Hanyu, and W. J. Gross, “VLSI implementation of deep neural network using integral stochastic computing,” IEEE Transactions on Very Large Scale Integration (VLSI) Systems, vol. 25, pp. 2688-2699, 2017.
[9] P. Knag, W. Lu, and Z. Zhang, “A native stochastic computing architecture enabled by memristors,” IEEE Transactions on Nanotechnology, vol. 13, pp. 283-293, 2014.
[10] S. Gaba, P. Knag, Z. Zhang, and W. Lu, “Memristive devices for stochastic computing,” in 2014 IEEE International Symposium on Circuits and Systems (ISCAS), 2014, pp. 2592-2595.
[11] S. Gaba, P. Sheridan, J. Zhou, S. Choi, and W. Lu, “Stochastic memristive devices for computing and neuromorphic applications,” Nanoscale, vol. 5, pp. 5872-5878, 2013.
[12] R. Venkatesan, S. Venkataramani, X. Fong, K. Roy, and A. Raghunathan, “Spintastic: Spin-based stochastic logic for energy-efficient computing,” in 2015 Design, Automation & Test in Europe Conference & Exhibition (DATE), 2015, pp. 1575-1578.
[13] G. Finocchio, M. Di Ventra, K. Y. Camsari, K. Everschor-Sitte, P. K. Amiri, and Z. Zeng, “The promise of spintronics for unconventional computing,” arXiv preprint arXiv: 1910.07176, 2019.
[14] J. Hu, B. Li, C. Ma, D. Lilja, and S. J. Koester, “Spin-hall-effect-based stochastic number generator for parallel stochastic computing,” IEEE Transactions on Electron Devices, vol. 66, pp. 3620-3627, 2019.
[15] W. A. Borders, A. Z. Pervaiz, S. Fukami, K. Y. Camsari, H. Ohno, and S. Datta, “Integer factorization using stochastic magnetic tunnel junctions,” Nature, vol. 573, pp. 390-393, 2019.
[16] A. Alaghi and J. P. Hayes, “Survey of stochastic computing,” ACM Transactions on Embedded computing systems (TECS), vol. 12, pp. 1-19, 2013.
[17] P. Li, D. J. Lilja, W. Qian, K. Bazargan, and M. D. Riedel, “Computation on stochastic bit streams digital image processing case studies,” IEEE Transactions on Very Large Scale Integration (VLSI) Systems, vol. 22, pp. 449-462, 2013.
[18] P. Li and D. J. Lilja, “Using stochastic computing to implement digital image processing algorithms,” in 2011 IEEE 29th International Conference on Computer Design (ICCD), 2011, pp. 154-161.
[19] K. Yang, D. Fick, M. B. Henry, Y. Lee, D. Blaauw, and D. Sylvester, “16.3 A 23 Mb/s 23pJ/b fully synthesized true-random-number generator in 28 nm and 65 nm CMOS,” in 2014 IEEE International Solid-State Circuits Conference Digest of Technical Papers (ISSCC), 2014, pp. 280-281.
[20] W. Sun, B. Gao, M. Chi, Q. Xia, J. J. Yang, H. Qian, et al., “Understanding memristive switching via in situ characterization and device modeling,” Nature communications, vol. 10, pp. 1-13, 2019.
[21] A. Jaiswal, X. Fong, and K. Roy, “Comprehensive scaling analysis of current induced switching in magnetic memories based on in-plane and perpendicular anisotropies,” IEEE Journal on Emerging and Selected Topics in Circuits and Systems, vol. 6, pp. 120-133, 2016.
[22] A. Sengupta, P. Panda, P. Wijesinghe, Y. Kim, and K. Roy, “Magnetic tunnel junction mimics stochastic cortical spiking neurons,” Scientific reports, vol. 6, pp. 1-8, 2016.
[23] Z. Fu, Y. Tang, X. Zhao, K. Lu, Y. Dong, A. Shukla, et al., “An Overview of Spintronic True Random Number Generator,” Frontiers in Physics, vol. 9, p. 172, 2021.
[24] 2DCC. 2d-crystal-consortium. Available: https://www.mri.psu.edu/2d-crystal-consortium/user-facilities/thin-films/list-thin-film-samples-available
[25] A. Sebastian, R. Pendurthi, T. H. Choudhury, J. M. Redwing, and S. Das, “Benchmarking monolayer MoS2 and WS2 field-effect transistors,” Nature Communications, vol. 12, p. 693, 2021 Jan. 29 2021.
[26] S. Das, H.-Y. Chen, A. V. Penumatcha, and J. Appenzeller, “High performance multilayer MoS2 transistors with scandium contacts,” Nano letters, vol. 13, pp. 100-105, 2013.
[27] D. S. Schulman, A. J. Arnold, and S. Das, “Contact engineering for 2D materials and devices,” Chemical Society Reviews, vol. 47, pp. 3037-3058, 2018.
[28] S. Chuang, C. Battaglia, A. Azcatl, S. McDonnell, J. S. Kang, X. Yin, et al., “MoS2 p-type transistors and diodes enabled by high work function MoO x contacts,” Nano letters, vol. 14, pp. 1337-1342, 2014.
[29] A. Alaghi and J. P. Hayes, “Exploiting correlation in stochastic circuit design,” in 2013 IEEE 31st International Conference on Computer Design (ICCD), 2013, pp. 39-46.
[30] S. Das, A. Sebastian, E. Pop, C. J. Mcclellan, A. D. Franklin, T. Grasser, et al., “Transistors based on two-dimensional materials for future integrated circuits,” Nature Electronics, vol. 4, pp. 786-799, 2021 Nov. 1 2021.
[31] T. F. Schranghamer, M. Sharma, R. Singh, and S. Das, “Review and comparison of layer transfer methods for two-dimensional materials for emerging applications,” Chemical Society Reviews, 2021.
[32] Q. Smets, G. Arutchelvan, J. Jussot, D. Verreck, I. Asselberghs, A. N. Mehta, et al., “Ultra-scaled MOCVD MoS 2 MOSFETs with 42 nm contact pitch and 250 μA/μm drain current,” in 2019 IEEE International Electron Devices Meeting (IEDM), 2019, pp. 23.2. 1-23.2. 4.
[33] I. Asselberghs, Q. Smets, T. Schram, B. Groven, D. Verreck, A. Afzalian, et al., “Wafer-scale integration of double gated WS2-transistors in 300 mm Si CMOS fab,” pp. 40.2.1-40.2.4, 2020.
[34] T. kumar Agarwal, B. Soree, I. Radu, P. Raghavan, G. Iannaccone, G. Fiori, et al., “Material-device-circuit co-optimization of 2D material based FETs for ultra-scaled technology nodes,” Scientific reports, vol. 7, pp. 1-7, 2017.
[35] D. E. Nikonov and I. A. Young, “Benchmarking of beyond-CMOS exploratory devices for logic integrated circuits,” IEEE Journal on Exploratory Solid-State Computational Devices and Circuits, vol. 1, pp. 3-11, 2015.
[36] S. S. Sylvia, K. Alam, and R. K. Lake, “Uniform benchmarking of low-voltage van der Waals FETs,” IEEE Journal on Exploratory Solid-State Computational Devices and Circuits, vol. 2, pp. 28-35, 2016.
[37] Y. Xuan, A. Jain, S. Zafar, R. Lotfi, N. Nayir, Y. Wang, et al., “Multi-scale modeling of gas-phase reactions in metal-organic chemical vapor deposition growth of WSe2,” Journal of Crystal Growth, vol. 527, 2019.
[38] D. Jayachandran, A. Oberoi, A. Sebastian, T. H. Choudhury, B. Shankar, J. M. Redwing, et al., “A low-power biomimetic collision detector based on an in-memory molybdenum disulfide photodetector,” Nature Electronics, vol. 3, pp. 646-655, 2020 Oct. 1 2020.
[39] A. Dodda, A. Oberoi, A. Sebastian, T. H. Choudhury, J. M. Redwing, and S. Das. “Stochastic resonance in MoS₂ photodetector,” Nature Communications, vol. 11, p. 4406, 2020 Sep. 2 2020.
[40] S. Das et al., “Transistors based on two-dimensional materials for future integrated circuits,” Nature Electronics, vol. 4, no. 11, pp. 786-799, 2021 Nov. 1 2021, doi: 10.1038/s41928-021-00670-1.
[41] D. Akinwande et al., “Graphene and two-dimensional materials for silicon technology,” Nature, vol. 573, no. 7775, pp. 507-518, 2019.
[42] M. Chhowalla, D. Jena, and H. Zhang, “Two-dimensional semiconductors for transistors,” Nature Reviews Materials, vol. 1, no. 11, pp. 1-15, 2016.
[43] K. Zhu et al., “The development of integrated circuits based on two-dimensional materials,” Nature Electronics, vol. 4, no. 11, pp. 775-785, 2021 Nov. 1 2021, doi: 10.1038/s41928-021-00672-z.
[44] S. Wachter, D. K. Polyushkin, O. Bethge, and T. Mueller, “A microprocessor based on a two-dimensional semiconductor,” Nature communications, vol. 8, p. 14948, 2017.
[45] Q. Gao, Z. Zhang, X. Xu, J. Song, X. Li, and Y. Wu, “Scalable high performance radio frequency electronics based on large domain bilayer MoS₂,” Nature Communications, vol. 9, no. 1, p. 4778, 2018 Nov. 14 2018, doi: 10.1038/s41467-018-07135-8.
[46] D. K. Polyushkin et al., “Analogue two-dimensional semiconductor electronics,” Nature Electronics, vol. 3, no. 8, pp. 486-491, 2020 Aug. 1 2020, doi: 10.1038/s41928-020-0460-6.
[47] Y. Zheng, H. Ravichandran, T. F. Schranghamer, N. Trainor, J. M. Redwing, and S. Das, “Hardware implementation of Bayesian network based on two-dimensional memtransistors,” Nature Communications, vol. 13, no. 1, p. 5578, 2022 Sep. 23 2022, doi: 10.1038/s41467-022-33053-x.
[48] A. Sebastian et al., “Two-dimensional materials-based probabilistic synapses and reconfigurable neurons for measuring inference uncertainty using Bayesian neural networks,” Nature communications, vol. 13, no. 1, pp. 1-10, 2022.
[49] A. Sebastian, S. Das, and S. Das, “An Annealing Accelerator for Ising Spin Systems Based on In-Memory Complementary 2D FETs,” Advanced Materials, https://doi.org/10.1002/adma.202107076 vol. 34, no. 4, p. 2107076, 2022 Jan. 1 2022, doi: https://doi.org/10.1002/adma.202107076.
[50] R. Pendurthi et al., “Heterogeneous Integration of Atomically Thin Semiconductors for Non-von Neumann CMOS,” Small, p. 2202590, 2022.
[51] A. Dodda, N. Trainor, J. Redwing, and S. Das, “All-in-one, bio-inspired, and low-power crypto engines for near-sensor security based on two-dimensional memtransistors,” Nature communications, vol. 13, no. 1, pp. 1-12, 2022.
[52] S. Chakrabarti et al., “Logic Locking of Integrated Circuits Enabled by Nanoscale MoS₂-Based Memtransistors,” ACS Applied Nano Materials, 2022 Oct. 4 2022, doi: 10.1021/acsanm.2c02807.
[53] A. Sebastian, R. Pendurthi, T. H. Choudhury, J. M. Redwing, and S. Das, “Benchmarking monolayer MoS2 and WS2 field-effect transistors,” Nature Communications, vol. 12, no. 1, p. 693, 2021 Jan. 29 2021, doi: 10.1038/s41467-020-20732-w.
[54] A. Oberoi, A. Dodda, H. Liu, M. Terrones, and S. Das, “Secure Electronics Enabled by Atomically Thin and Photosensitive Two-Dimensional Memtransistors,” ACS Nano, vol. 15, no. 12, pp. 19815-19827, 2021 Dec. 28 2021, doi: 10.1021/acsnano.1c07292.
[55] D. Jayachandran et al., “A low-power biomimetic collision detector based on an in-memory molybdenum disulfide photodetector,” Nature Electronics, vol. 3, no. 10, pp. 646-655, 2020 Oct. 1 2020, doi: 10.1038/s41928-020-00466-9.
[56] D. Geng and H. Y. Yang, “Recent advances in growth of novel 2D materials: beyond graphene and transition metal dichalcogenides,” Advanced Materials, vol. 30, no. 45, p. 1800865, 2018.
[57] T. F. Schranghamer, M. Sharma, R. Singh, and S. Das, “Review and comparison of layer transfer methods for two-dimensional materials for emerging applications,” Chemical Society Reviews, 2021.
[58] M. Lanza, Q. Smets, C. Huyghebaert, and L. J. Li, “Yield, variability, reliability, and stability of two-dimensional materials based solid-state electronic devices,” Nat Commun, vol. 11, no. 1, p. 5689 Nov. 10 2020, doi: 10.1038/s41467-020-19053-9.
[59] P.-C. Shen et al., “Ultralow contact resistance between semimetal and monolayer semiconductors,” Nature, vol. 593, no. 7858, pp. 211-217, 2021 May 1 2021, doi: 10.1038/s41586-021-03472-9.
[60] S.-L. Li, K. Tsukagoshi, E. Orgiu, and P. Samorì, “Charge transport and mobility engineering in two-dimensional transition metal chalcogenide semiconductors,” Chemical Society Reviews, vol. 45, no. 1, pp. 118-151, 2016.
[61] D. S. Schulman, A. J. Arnold, and S. Das, “Contact engineering for 2D materials and devices,” Chem Soc Rev, Mar. 2 2018, doi: 10.1039/c7cs00828g.
[62] I. Asselberghs et al., “Scaled transistors with 2D materials from the 300 mm fab,” pp. 67-68, 2020, doi: 10.1109/snw50361.2020.9131651.
[63] Q. Smets et al., “Ultra-scaled MOCVD MoS 2 MOSFETs with 42 nm contact pitch and 250 μA/μm drain current,” in 2019 IEEE International Electron Devices Meeting (IEDM), 2019: IEEE, pp. 23.2. 1-23.2. 4.
[64] R. Degraeve et al., “Trap spectroscopy by charge injection and sensing (TSCIS): A quantitative electrical technique for studying defects in dielectric stacks,” in 2008 IEEE International Electron Devices Meeting, 2008: IEEE, pp. 1-4.
[65] Y. Y. Illarionov et al., “Energetic mapping of oxide traps in MoS₂ field-effect transistors,” 2D Materials, vol. 4, no. 2, p. 025108, 2017.
[66] Y. Y. Illarionov et al., “The role of charge trapping in MoS2/SiO2 and MoS₂/hBN field-effect transistors,” 2D Materials, vol. 3, no. 3, p. 035004, 2016.
[67] D. K. Schroder and J. A. Babcock, “Negative bias temperature instability: Road to cross in deep submicron silicon semiconductor manufacturing,” J Appl Phys, vol. 94, no. 1, pp. 1-18, 2003.
[68] Y. Guo et al., “Charge trapping at the MoS2-SiO2 interface and its effects on the characteristics of MoS2 metal-oxide-semiconductor field effect transistors,” Appl Phys Lett, vol. 106, no. 10, p. 103109, 2015.
[69] Y. Park, H. W. Baac, J. Heo, and G. Yoo, “Thermally activated trap charges responsible for hysteresis in multilayer MoS2 field-effect transistors,” Appl Phys Lett, vol. 108, no. 8, p. 083102, 2016.
[70] D. J. Late, B. Liu, H. S. S. R. Matte, V. P. Dravid, and C. N. R. Rao, “Hysteresis in single-layer MoS₂ field effect transistors,” ACS Nano, vol. 6, no. 6, pp. 5635-41, 2012, doi: 10.1021/nn301572c.
[71] A. J. Arnold, A. Razavieh, J. R. Nasr, D. S. Schulman, C. M. Eichfeld, and S. Das, “Mimicking Neurotransmitter Release in Chemical Synapses via Hysteresis Engineering in MoS2 Transistors,” ACS nano, vol. 11, no. 3, pp. 3110-3118, 2017.
[72] T. Grasser, “Stochastic charge trapping in oxides: From random telegraph noise to bias temperature instabilities,” Microelectronics Reliability, vol. 52, no. 1, pp. 39-70, 2012.
[73] Y. Yuzhelevski, M. Yuzhelevski, and G. Jung, “Random telegraph noise analysis in time domain,” Review of Scientific Instruments, vol. 71, no. 4, pp. 1681-1688, 2000.
[74] A. Grill et al., “Characterization and modeling of single defects in GaN/AlGaN fin-MIS-HEMTs,” in 2017 IEEE International Reliability Physics Symposium (IRPS), 2017: IEEE, pp. 3B-5.1-3B-5.5.
[75] B. Stampfer et al., “Characterization of Single Defects in Ultrascaled MoS2 Field-Effect Transistors,” ACS Nano, vol. 12, no. 6, pp. 5368-5375, 2018, doi: 10.1021/acsnano.8b00268.
[76] F. Nan, K. Nagashio, and A. Toriumi, “Subthreshold transport in mono- and multilayered MoS2 FETs,” Appl Phys Express, vol. 8, no. 6, p. 065203, 2015.
[77] N. Fang, K. Nagashio, and A. Toriumi, “Experimental detection of active defects in few layers MoS2 through random telegraphic signals analysis observed in its FET characteristics,” 2D Materials, vol. 4, no. 1, p. 015035, 2016.
[78] L. Li, I. Lee, D.-H. Youn, and G.-H. Kim, “Hopping conduction and random telegraph signal in an exfoliated multilayer MoS2 field-effect transistor,” Nanotechnology, vol. 28, no. 7, p. 075201, 2017.
[79] J. Hong et al., “Exploring atomic defects in molybdenum disulphide monolayers,” Nature communications, vol. 6, no. 1, pp. 1-8, 2015.
[60] W. Zhou et al., “Intrinsic structural defects in monolayer molybdenum disulfide,” Nano letters, vol. 13, no. 6, pp. 2615-2622, 2013.
[81] H. Ravichandran, Y. Zheng, T. F. Schranghamer, N. Trainor, J. M. Redwing, and S. Das, “A Monolithic Stochastic Computing Architecture for Energy Efficient Arithmetic,” Advanced Materials, https://doi.org/10.1002/adma.202206168 vol. 35, no. 2, p. 2206168, 2023 Jan. 1 2023, doi: https://doi.org/10.1002/adma.202206168.
[11] T. Grasser et al., “Gate-sided hydrogen release as the origin of “permanent” NBTI degradation: From single defects to lifetimes,” in 2015 IEEE International Electron Devices Meeting (IEDM), 7-9 Dec. 2015 2015, pp. 20.1.1-20.1.4, doi: 10.1109/IEDM.2015.7409739.
[83] A. L. Mcwhorter, “1/ƒ noise and related surface effects in germanium,” 1955.
[84] M. J. Kirton and M. J. Uren, “Noise in solid-state microstructures: A new perspective on individual defects, interface states and low-frequency (1/ƒ) noise,” Advances in Physics, vol. 38, no. 4, pp. 367-468, 1989 Jan. 1 1989, doi: 10.1080/00018738900101122.
[85] A. Alkauskas, Q. Yan, and C. G. Van de Walle, “First-principles theory of nonradiative carrier capture via multiphonon emission,” Physical Review B, vol. 90, no. 7, p. 075202, Aug. 18, 2014, doi: 10.1103/PhysRevB.90.075202.
[86] W. Goes et al., “Identification of oxide defects in semiconductor devices: A systematic approach linking DFT to rate equations and experimental evidence,” Microelectronics Reliability, vol. 87, pp. 286-320, 2018 Aug. 1/2018, doi: https://doi.org/10.1016/j.microrel.2017.12.021.
[87] T. Nagumo, K. Takeuchi, S. Yokogawa, K. Imai, and Y. Hayashi, “New analysis methods for comprehensive understanding of Random Telegraph Noise,” in 2009 IEEE International Electron Devices Meeting (IEDM), 7-9 Dec. 2009 2009, pp. 1-4, doi: 10.1109/IEDM.2009.5424230.
[88] J. Martin-Martinez, J. Diaz, R. Rodriguez, M. Nafria, and X. Aymerich, “New Weighted Time Lag Method for the Analysis of Random Telegraph Signals,” IEEE Electron Device Letters, vol. 35, no. 4, pp. 479-481, 2014, doi: 10.1109/LED.2014.2304673.
[89] J. Canny, “A Computational Approach to Edge Detection,” IEEE Transactions on Pattern Analysis and Machine Intelligence, vol. PAMI-8, no. 6, pp. 679-698, 1986, doi: 10.1109/TPAMI. 1986.4767851.
[90] J. Michl et al., “Evidence of Tunneling Driven Random Telegraph Noise in Cryo-CMOS,” in 2021 IEEE International Electron Devices Meeting (IEDM), 11-16 Dec. 2021 2021, pp. 31.3.1-31.3.4, doi: 10.1109/IEDM19574.2021.9720501.
[91] O. A. Dicks, J. Cottom, A. L. Shluger, and V. V. Afanas'ev, “The origin of negative charging in amorphous Al₂O₃ films: the role of native defects,” Nanotechnology, vol. 30, no. 20, p. 205201, 2019 Mar. 12 2019, doi: 10.1088/1361-6528/ab0450.
[92] J. Strand, P. La Torraca, A. Padovani, L. Larcher, and A. L. Shluger, “Dielectric breakdown in HfO2 dielectrics: Using multiscale modeling to identify the critical physical processes involved in oxide degradation,” Journal of Applied Physics, vol. 131, no. 23, p. 234501, 2022, doi: 10.1063/5.0083189.
[93] J. P. Campbell et al., “Large random telegraph noise in sub-threshold operation of nano-scale nMOSFETs,” in 2009 IEEE International Conference on IC Design and Technology, 18-20 May 2009 2009, pp. 17-20, doi: 10.1109/ICICDT.2009.5166255.
[94] A. Asenov, R. Balasubramaniam, A. R. Brown, J. H. Davies, and S. Saini, “Random telegraph signal amplitudes in sub 100 nm (decanano) MOSFETs: a 3D ‘Atomistic’ simulation study,” in International Electron Devices Meeting 2000. Technical Digest. IEDM (Cat. No. 00CH37138), 10-13 Dec. 2000 2000, pp. 279-282, doi: 10.1109/IEDM.2000.904311.
[95] P. Fantini, A. Ghetti, A. Marinoni, G. Ghidini, A. Visconti, and A. Marmiroli, “Giant Random Telegraph Signals in Nanoscale Floating-Gate Devices,” IEEE Electron Device Letters, vol. 28, no. 12, pp. 1114-1116, 2007, doi: 10.1109/LED.2007.909835.
[96] F. Liu et al., “Giant random telegraph signals in the carbon nanotubes as a single defect probe,” Applied Physics Letters, vol. 86, no. 16, p. 163102, 2005 Apr. 18 2005, doi: 10.1063/1.1901822.
[97] A. Asenov, R. Balasubramaniam, A. R. Brown, and J. H. Davies, “RTS amplitudes in decananometer MOSFETs: 3-D simulation study,” IEEE Transactions on Electron Devices, vol. 50, no. 3, pp. 839-845, 2003, doi: 10.1109/TED.2003.811418.
[98] R. Wang, S. Guo, Z. Zhang, J. Zou, D. Mao, and R. Huang, “Complex Random Telegraph Noise (RTN): What Do We Understand?,” in 2018 IEEE International Symposium on the Physical and Failure Analysis of Integrated Circuits (IPFA), 16-19 Jul. 2018 2018, pp. 1-7, doi: 10.1109/IPFA.2018.8452514.
[99] M. J. Uren, M. J. Kirton, and S. Collins, “Anomalous telegraph noise in small-area silicon metal-oxide-semiconductor field-effect transistors,” Physical Review B, vol. 37, no. 14, pp. 8346-8350, May 15, 1988, doi: 10.1103/PhysRevB.37.8346.
[100] C. Wilhelmer et al., “Ab initio investigations in amorphous silicon dioxide: Proposing a multi-state defect model for electron and hole capture,” Microelectronics Reliability, vol. 139, p. 114801, 2022 Dec. 1/2022, doi: https://doi.org/10.1016/j.microrel.2022.114801.
[101] F. M. Puglisi, P. Pavan, A. Padovani, L. Larcher, and G. Bersuker, “RTS noise characterization of HfOx RRAM in high resistive state,” Solid-State Electronics, vol. 84, pp. 160-166, 2013 Jun. 1/2013, doi: https://doi.org/10.1016/j.sse.2013.02.023.
[102] F. Zhang, C. Erb, L. Runkle, X. Zhang, and N. Alem, “Etchant-free transfer of 2D nanostructures,” Nanotechnology, vol. 29, no. 2, 2018.
[103] A. Sebastian et al., “Electrochemical Polishing of Two-Dimensional Materials,” ACS Nano, vol. 13, no. 1, pp. 78-86, 2018, doi: 10.1021/acsnano.8b08216.

1. (canceled)

2. An s-bit generator, comprising:
a plurality of 2D memtransistors;
an inverting amplifier; and
a programmable threshold inverter;
wherein one or more s-bits are generated from inherent stochasticity in the plurality of 2D memtransistors.

3. The s-bit generator of claim 2, wherein:
the plurality of 2D memtransistors form a voltage divider.

4. The s-bit generator of claim 2, wherein:
the inherent stochasticity in the plural 2D memtransistors includes one or more of: cycle-to-cycle fluctuations in carrier trapping and detrapping phenomena in a gate insulator of a 2D memtransistor of the plural 2D memtransistor, thermal conductance fluctuations in a defect-engineered and scaled 2D memtransistor of the plural 2D memtransistors, and/or random telegraph signals (RTS) in a defect-engineered and scaled 2D memtransistor of the plural 2D memtransistors.

5. A s-bit generator, comprising:
a plurality of memtransistors, comprising:
a memtransistor, MT1, having a MT1-drain, a MT1-source, and a MT1-gate;
a memtransistor, MT2, having a MT2-drain, a MT2-source, and a MT2-gate;
a memtransistor, MT3, having a MT3-drain, a MT3-source, and a MT3-gate;
a memtransistor, MT4, having a MT4-drain, a MT4-source, and a MT4-gate;
a memtransistor, MT5, having a MT5-drain, a MT5-source, and a MT5-gate; and
a memtransistor, MT6, having a MT6-drain, a MT6-source, and a MT6-gate;
wherein:
each memtransistor is stacked on a non-volatile and programmable local back-gate stack;
each memtransistor has a 2D channel formed between its source and its drain;
the MT1-drain is connected to: the MT3-drain, the MT5-drain, and a node N1;
the MT1-gate is connected to a node N2;
the MT1-source is connected to: the MT2-drain and the MT4-gate via a node N5;
the MT2-drain is connected to the MT4-gate via the node N5;
the MT2-gate is connected to a node N3;
the MT2-source is connected to: the MT4-source, the MT6-source, and a node N4;
the MT3-drain is connected to: the MT1-drain, the MT5-drain, and the node N1;
the MT3-gate is connected to the MT6-gate via a node N6;
the MT3-source is connected to: the MT6-gate via node the N6 and the MT4-drain via the node N6;
the MT4-drain is connected to: the MT3-source via the node N6, the MT3-gate via the node N6, and the MT6-gate via the node N6;
the MT4-gate is connected to: the MT1-source via the node N5 and the MT2-drain via the node N5;
the MT4-source is connected to: the MT2-source, the MT6-source, and the node N4;
the MT5-drain is connected to: the MT1-drain, the MT3-drain, and the node N1;
the MT5-gate is connected to the MT6-drain via a node N7;
the MT6-drain is connected to: the MT5-source via the node N7 and the MT5-gate via the node N7;
the MT6-gate is connected to: the MT3-source via the node N6, the MT3-gate via the node N6, and the MT4-drain via the node N6; and
the MT6-source is connected to: the MT4-source, the MT2-source, and the node N4.

6. The s-bit generator of claim 5, wherein:
the 2D channel is a monolayer.

7. The s-bit generator of claim 6, wherein:
wherein the monolayer includes MoS2.

8. A stochastic computing processor, comprising:
a processing module including a processor and a memory and the s-bit generator of claim 5.

9. The stochastic computing processor of claim 8, wherein:
the stochastic computing processor has a non-von Neuman architecture.

10. A stochastic multiplier, comprising:
a first s-bit generator, comprising:
a plurality of memtransistors, comprising:
a memtransistor, MT1, having a MT1-drain, a MT1-source, and a MT1-gate;
a memtransistor, MT2, having a MT2-drain, a MT2-source, and a MT2-gate;
a memtransistor, MT3, having a MT3-drain, a MT3-source, and a MT3-gate;
a memtransistor, MT4, having a MT4-drain, a MT4-source, and a MT4-gate;
a memtransistor, MT5, having a MT5-drain, a MT5-source, and a MT5-gate; and
a memtransistor, MT6, having a MT6-drain, a MT6-source, and a MT6-gate;
wherein:
each memtransistor is stacked on a non-volatile and programmable local back-gate stack;
each memtransistor has a 2D channel formed between its source and its drain;
the MT1-drain is connected to: the MT3-drain, the MT5-drain, and a node N1;
the MT1-gate is connected to a node N2;
the MT1-source is connected to: the MT2-drain and the MT4-gate via a node N5;
the MT2-drain is connected to the MT4-gate via the node N5;
the MT2-gate is connected to a node N3;
the MT2-source is connected to: the MT4-source, the MT6-source, and a node N4;
the MT3-drain is connected to: the MT1-drain, the MT5-drain, and the node N1;
the MT3-gate is connected to the MT6-gate via a node N6;
the MT3-source is connected to: the MT6-gate via the node N6 and the MT4-drain via the node N6;
the MT4-drain is connected to: the MT3-source via the node N6, the MT3-gate via the node N6, and the MT6-gate via the node N6;
the MT4-gate is connected to: the MT1-source via the node N5 and the MT2-drain via the node N5;
the MT4-source is connected to: the MT2-source, the MT6-source, and the node N4;
the MT5-drain is connected to: the MT1-drain, the MT3-drain, and the node N1;
the MT5-gate is connected to the MT6-drain via a node N7;
the MT6-drain is connected to: the MT5-source via the node N7 and the MT5-gate via the node N7;
the MT6-gate is connected to: the MT3-source via the node N6, the MT3-gate via the node N6, and the MT4-drain via the node N6;
the MT6-source is connected to: the MT4-source, the MT2-source, and the node N4; and
the first s-bit generator is configured to generate an output A at the node N7;
a second s-bit generator, comprising:
a plurality of memtransistors, comprising:
a memtransistor, MT14, having a MT14-drain, a MT14-source, and a MT14-gate;
a memtransistor, MT15, having a MT15-drain, a MT15-source, and a MT15-gate;
a memtransistor, MT12, having a MT12-drain, a MT12-source, and a MT12-gate;
a memtransistor, MT13, having a MT13-drain, a MT13-source, and a MT13-gate;
a memtransistor, MT10, having a MT10-drain, a MT10-source, and a MT10-gate; and
a memtransistor, MT1, having a MT11-drain, a MT11-source, and a MT1-gate;
wherein:
each memtransistor is stacked on a non-volatile and programmable local back-gate stack;
each memtransistor has a 2D channel formed between its source and its drain;
the MT14-drain is connected to: the MT12-drain, the MT10-drain, and a V_{DD};
the MT14-gate is connected to a node N12;
the MT14-source is connected to: the MT15-drain and the MT13-gate via a node N11;
the MT15-drain is connected to the MT13-gate via the node N11;
the MT15-gate is connected to a node N13;
the MT15-source is connected to: the MT13-source, the MT11-source, and a GND;
the MT12-drain is connected to: the MT14-drain, the MT10-drain, and a V_{DD};
the MT12-gate is connected to the MT1-gate via a node N10;
the MT12-source is connected to: the MT1-gate via the node N10 and the MT13-drain via the node N10;
the MT13-drain is connected to: the MT12-source via the node N10, the MT12-gate via the node N10, and the MT1-gate via the node N10;
the MT13-gate is connected to: the MT14-source via the node N11 and the MT15-drain via the node N11;
the MT13-source is connected to: the MT14-source, the MT11-source, and the GND;
the MT10-drain is connected to: the MT14-drain, the MT12-drain, and the V_{DD};
the MT10-gate is connected to the MT11-drain via a node N9;
the MT11-drain is connected to: the MT10-source via the node N9 and the MT10-gate via the node N9;
the MT1-gate is connected to: the MT12-source via the node N10, the MT12-gate via the node N10, and the MT13-drain via the node N10;
the MT11-source is connected to: the MT13-source, the MT15-source, and the GND; and
the second s-bit generator is configured to generate an output B at the node N9; and
an AND gate configured to receive the output A, receive the output B, and generate an output C.

11. The stochastic multiplier of claim 10, wherein:
the AND gate includes a plurality of memtransistors, comprising:
a memtransistor, MT7, having a MT7-drain, a MT7-source, and a MT7-gate;
a memtransistor, MT8, having a MT8-drain, a MT8-source, and a MT8-gate; and
a memtransistor, MT9, having a MT9-drain, a MT9-source, and a MT9-gate.

12. The stochastic multiplier of claim 11, wherein:
for the first s-bit generator:
the output A is transmitted to the AND gate via the node N7;
the node N7 is connected to the MT7-gate;
the MT1-drain, the MT3-drain, and the MT5-drain are connected to the MT7-drain; and
the MT2-source, the MT4-source, and the MT6-source are connected to: the MT9-gate and to the MT9-source;
for the second s-bit generator:
the output B is transmitted to the AND gate via the node N9;
the node N7 is connected to the MT8-gate;
the MT10-drain, the MT12-drain, and the MT14-drain are connected to the MT7-drain; and
the MT14-source, the MT13-source, and the MT11-source are connected to: the MT9-gate and to the MT9-source;
for the AND gate:
the MT7-source is connected to the MT8-drain;
the MT8-source connected to the MT9-drain and to a node N8; and
the AND gate outputs the output C at the node N8.

13. A stochastic adder, comprising:
a first s-bit generator, comprising:
a plurality of memtransistors, comprising:
a memtransistor, MT1, having a MT1-drain, a MT1-source, and a MT1-gate;
a memtransistor, MT2, having a MT2-drain, a MT2-source, and a MT2-gate;
a memtransistor, MT3, having a MT3-drain, a MT3-source, and a MT3-gate;
a memtransistor, MT4, having a MT4-drain, a MT4-source, and a MT4-gate;
a memtransistor, MT5, having a MT5-drain, a MT5-source, and a MT5-gate; and
a memtransistor, MT6, having a MT6-drain, a MT6-source, and a MT6-gate;
wherein:
each memtransistor is stacked on a non-volatile and programmable local back-gate stack;
each memtransistor has a 2D channel formed between its source and its drain;
the MT1-drain is connected to: the MT3-drain, the MT5-drain, and a node N1;
the MT1-gate is connected to a node N2;
the MT1-source is connected to: MT2-drain and MT4-gate via a node N5;
the MT2-drain is connected to MT4-gate via node the N5;
the MT2-gate is connected to a node N3;
the MT2-source is connected to: the MT4-source, the MT6-source, and a node N4;
the MT3-drain is connected to: the MT1-drain, the MT5-drain, and the node N1;
the MT3-gate is connected to the MT6-gate via a node N6;
the MT3-source is connected to: the MT6-gate via the node N6 and the MT4-drain via the node N6;
the MT4-drain is connected to: the MT3-source via the node N6, the MT3-gate via the node N6, and the MT6-gate via the node N6;
the MT4-gate is connected to: the MT1-source via the node N5 and the MT2-drain via the node N5;
the MT4-source is connected to: the MT2-source, the MT6-source, and the node N4;
the MT5-drain is connected to: the MT1-drain, the MT3-drain, and the node N1;
the MT5-gate is connected to the MT6-drain via a node N7;
the MT6-drain is connected to: the MT5-source via the node N7 and the MT5-gate via the node N7;
the MT6-gate is connected to: the MT3-source via the node N6, the MT3-gate via the node N6, and the MT4-drain via the node N6;
the MT6-source is connected to: the MT4-source, the MT2-source, and the node N4; and
the first s-bit generator is configured to generate an output S;
a second s-bit generator, comprising:
a plurality of memtransistors, comprising:
a memtransistor, MT7, having a MT7-drain, a MT7-source, and a MT7-gate;
a memtransistor, MT8, having a MT8-drain, a MT8-source, and a MT8-gate;
a memtransistor, MT9, having a MT9-drain, a MT9-source, and a MT9-gate;
a memtransistor, MT10, having a MT10-drain, a MT10-source, and a MT10-gate;
a memtransistor, MT1, having a MT11-drain, a MT11-source, and a MT1-gate; and
a memtransistor, MT12, having a MT12-drain, a MT12-source, and a MT12-gate;
wherein:
each memtransistor is stacked on a non-volatile and programmable local back-gate stack;
each memtransistor has a 2D channel formed between its source and its drain;
the MT7-drain is connected to: the MT9-drain, the MT11-drain, and a node V_{DD};
the MT7-gate is connected to a node N8;
the MT7-source is connected to: the MT8-drain and the MT10-gate via a node N10;
the MT8-drain is connected to the MT10-gate via the node N10;
the MT2-gate is connected to the node N3;
the MT8-source is connected to: the MT10-source, the MT12-source, and a GND;
the MT9-drain is connected to: the MT7-drain, the MT11-drain, and the V_{DD};
the MT9-gate is connected to the MT12-gate via a node N11;
the MT9-source is connected to: the MT12-gate via the node N11 and the MT10-drain via the node N11;
the MT10-drain is connected to: the MT9-source via the node N11, the MT9-gate via the node N11, and the MT12-gate via the node N11;
the MT10-gate is connected to: the MT7-source via the node N10 and the MT8-drain via the node N10;
the MT10-source is connected to: the MT8-source, the MT12-source, and the GND:
the MT11-drain is connected to: the MT7-drain, the MT9-drain, and the V_{DD};
the MT1-gate is connected to the MT12-drain via a node N12;
the MT12-drain is connected to: the MT11-source via the node N12 and MT1-gate via the node N12;
MT12-gate is connected to: the MT9-source via the node N11, the MT9-gate via the node N11, and the MT10-drain via the node N11;
the MT12-source is connected to: the MT10-source, the MT8-source, and the GND; and
the second s-bit generator is configured to generate an output A;
a third s-bit generator, comprising:
a plurality of memtransistors, comprising:
a memtransistor, MT13, having a MT13-drain, a MT13-source, and a MT13-gate;
a memtransistor, MT14, having a MT14-drain, a MT14-source, and a MT14-gate;
a memtransistor, MT15, having a MT15-drain, a MT15-source, and a MT15-gate;
a memtransistor, MT16, having a MT16-drain, a MT16-source, and a MT16-gate;
a memtransistor, MT17, having a MT17-drain, a MT17-source, and a MT17-gate; and
a memtransistor, MT18, having a MT18-drain, a MT18-source, and a MT18-gate;
wherein:
each memtransistor is stacked on a non-volatile and programmable local back-gate stack;
each memtransistor has a 2D channel formed between its source and its drain;
the MT17-drain is connected to: the MT15-drain, the MT13-drain, and the V_{DD};
the MT17-gate is connected to a node N16;
the MT17-source is connected to: the MT18-drain and the MT16-gate via a node N15;
the MT18-drain is connected to the MT16-gate via the node N15;
the MT18-gate is connected to a node N17;
the MT18-source is connected to: the MT16-source, the MT14-source, and the GND;
the MT15-drain is connected to: the MT17-drain, the MT13-drain, and the V_{DD};
the MT15-gate is connected to the MT14-gate via a node N14;
the MT15-source is connected to: the MT14-gate via the node N14 and the MT16-drain via the node N14;
the MT16-drain is connected to: the MT15-source via the node N14, the MT15-gate via the node N14, and the MT14-gate via the node N14;
the MT16-gate is connected to: the MT17-source via the node N15 and the MT18-drain via the node N15;
the MT16-source is connected to: the MT14-source, the MT18-source, and the GND:
the MT13-drain is connected to: the MT17-drain, the MT15-drain, and the V_{DD};
the MT13-gate is connected to the MT14-drain via a node N13;
the MT14-drain is connected to: the MT13-source via the node N13 and the MT13-gate via the node N13;
the MT14-gate is connected to: the MT15-source via the node N14, the MT15-gate via the node N14, and the MT16-drain via the node N14;
the MT15-source is connected to: the MT16-source, the MT18-source, and the GND; and
the third s-bit generator is configured to generate an output B; and
a MUX gate configured to receive output S, receive the output A, receive the output B, and generate an output C.

14. The stochastic adder of claim 13, wherein:
the MUX gate includes a plurality of memtransistors, comprising:
a memtransistor, MT19, having a MT19-drain, a MT19-source, and a MT19-gate;
a memtransistor, MT20, having a MT20-drain, a MT20-source, and a MT20-gate;
a memtransistor, MT21, having a MT21-drain, a MT21-source, and a MT21-gate; and
a memtransistor, MT22, having a MT22-drain, a MT22-source, and a MT22-gate.

15. The stochastic adder of claim 14, wherein:
for the first s-bit generator:
the node N1 is connected to the V_{DD};
the node N7 is connected to the MT20-gate; and
the node N4 is connected to the GND;
for the second s-bit generator:
the MT7-drain, the MT9-drain, and the MT11-drain are connected to the MT19-drain; and
the node N12 is connected to the MT21-drain;
for the third s-bit generator:
the node N13 is connected to the MT22-source;
for the MUX gate:
the MT19-drain is connected to the node N1 and the V_{DD};
the MT19-gate is connected to: the MT21-gate via the node N18 and the MT20-drain via the node N18;
the MT19-source is connected to: the MT21-gate via the node N18 and the MT20-drain via the node N18;
the MT20-drain is connected to: the MT19-gate via the node N18, the MT19-source via the node N18, and the MT21-gate via the node N18;
the MT20-gate is connected to: the node N7 and the MT22-gate;
the MT20-source is connected to the node N4 and the GND;
the MT21-drain is connected to the node N12;
the MT21-gate is connected to: the MT19-source via the node N18, the MT19-gate via the node N18, and the MT20-drain via the node N18;
the MT21-source is connected to the MT22-drain via the node N19;
the MT22-drain is connected to the MT21-source via the node N19;
the MT22-gate is connected to the MT20-gate;
the MT22-source is connected to the node N13; and
the MUX gate outputs the output C at the node N19.

16. A stochastic subtractor, comprising:
a first s-bit generator configured to generate output A, and a second s-bit generator configured to generate output B, wherein the output A and the output B are correlated bit streams;
an XOR gate, comprising a plurality of memtransistors including:
a memtransistor, MT1, having a MT1-drain, a MT1-source, and a MT1-gate;
a memtransistor, MT2, having a MT2-drain, a MT2-source, and a MT2-gate;
a memtransistor, MT3, having a MT3-drain, a MT3-source, and a MT3-gate;
a memtransistor, MT4, having a MT4-drain, a MT4-source, and a MT4-gate;
a memtransistor, MT5, having a MT5-drain, a MT5-source, and a MT5-gate;
a memtransistor, MT6, having a MT6-drain, a MT6-source, and a MT6-gate;
a memtransistor, MT7, having a MT7-drain, a MT7-source, and a MT7-gate; and
a memtransistor, MT8, having a MT8-drain, a MT8-source, and a MT8-gate;
a memtransistor, MT9, having a MT9-drain, a MT9-source, and a MT9-gate;
wherein:
each memtransistor is stacked on a non-volatile and programmable local back-gate stack;
each memtransistor has a 2D channel formed between its source and its drain;
the MT1-drain is connected to: a node N1, the MT3-drain, the MT5-drain, the MT7-drain, and a V_{DD};
the MT1-gate is connected to: the MT7-gate and the MT2-drain via a node N2;
the MT1-source is connected to the MT2-drain via the node N2;
the MT2-drain is connected to: the MT1-source via the node N2 and the MT1-gate via the node N2;
the MT2-gate is connected to the MT4-gate via the node N4;
the MT2-source is connected to: the MT9-gate via a node N3 and a GND;
the MT3-drain is connected to: the node N1, the MT1-drain, the MT5-drain, the MT7-drain, and the V_{DD};
the MT3-gate is connected to: the MT5-gate and the MT6-drain via a node N6;
the MT3-source is connected to the MT4-drain;
the MT4-drain is connected to the MT3-source;
the MT4-gate is connected to the MT2-gate via a node N4;
the MT4-source is connected to: the MT9-drain via a node N5 and the MT8-source via the node N5;
the MT5-drain is connected to: the node N1, the MT1-drain, the MT3-drain, the MT7-drain, and the V_{DD};
the MT5-gate is connected to: the MT3-gate and the MT6-drain via the node N6;
the MT5-source is connected to: the MT3-gate via the node N6 and the MT6-drain via the node N6;
the MT6-drain is connected to: the MT5-source via the node N6, the MT5-gate via the node N6, and the MT3-gate via the node N6;
the MT6-gate is connected to: the MT8-gate via the node N7;
the MT6-source is connected to: a node N8 and the GND;
the MT7-drain is connected to: the node N1, the MT1-drain, the MT3-drain, the MT5-drain, and the V_{DD};
the MT7-gate is connected to: the MT1-gate, the MT1-source, and the MT2-drain via the node N2;
the MT7-source is connected to the MT8-drain;
the MT8-drain is connected to the MT7-source;
the MT8-gate is connected to the MT6-gate via the node N7;
the MT8-source is connected to the MT9-drain via the node N5;
the MT9-drain is connected to the MT4-source via the node N5 and the MT8-source via the node N5;
the MT9-gate is connected to: the node N3 and the GND;
the MT9-source is connected to: the node N3 and the GND;
the output A is received at the node N4 and the output B is received at the node N7;
the MT1 and the MT2, together, act as a NOT gate to invert the output A to generate output Ac;
the MT5 and the MT6, together, act as a NOT gate to invert the output B to generate Bc; and
the XOR gate is configured to receive the output A, receive the output B, and generate an output C via the node N5.

17. A stochastic correlator, comprising:
a first s-bit generator configured to generate output A, and a second s-bit generator configured to generate output B, wherein the output A and the output B are uncorrelated bit streams;
an OR gate, comprising a plurality of memtransistors including:
a memtransistor, MT1, having a MT1-drain, a MT1-source, and a MT1-gate;
a memtransistor, MT2, having a MT2-drain, a MT2-source, and a MT2-gate;
a memtransistor, MT3, having a MT3-drain, a MT3-source, and a MT3-gate;
wherein:
each memtransistor is stacked on a non-volatile and programmable local back-gate stack;
each memtransistor has a 2D channel formed between its source and its drain;
the MT1-drain is connected to: a node N1 and a V_{DD};
the MT1-gate is connected to a node N2;
the MT1-source is connected to: the MT2-source, a node N4, and the MT3-drain;
the MT2-drain is connected to: the node N1 and the V_{DD};
the MT2-gate is connected to a node N3;
the MT2-drain is connected to: the MT1-source, the node N4, and the MT3-drain;
the MT3-drain is connected to the MT1-source, the MT2-source, and the node N4;
the MT3-gate is connected to the node N5 and the GND;
the MT3-source is connected to the GND; and
the OR gate is configured to receive the output A at the node N2, receive the output B at the node N3, and generate an output C via the node N4.

18. A stochastic sorter, comprising:
a first s-bit generator configured to generate output A, and a second s-bit generator configured to generate output B;
an OR gate configured to receive the output A, receive the output B, and generate an output C that is a maximum value of the output A and the output B; and
an AND gate configured to receive the output A, receive the output B, and generate an output D that is a minimum value of the output A and the output B.

19. The stochastic sorter of claim 18, wherein:
the OR gate and the AND gate include a plurality of memtransistors including:
a memtransistor, MT1, having a MT1-drain, a MT1-source, and a MT1-gate;
a memtransistor, MT2, having a MT2-drain, a MT2-source, and a MT2-gate;
a memtransistor, MT3, having a MT3-drain, a MT3-source, and a MT3-gate;
a memtransistor, MT4, having a MT4-drain, a MT4-source, and a MT4-gate;
a memtransistor, MT5, having a MT5-drain, a MT5-source, and a MT5-gate; and
a memtransistor, MT6, having a MT6-drain, a MT6-source, and a MT6-gate;
wherein:
each memtransistor is stacked on a non-volatile and programmable local back-gate stack;
each memtransistor has a 2D channel formed between its source and its drain;
the MT1-drain is connected to a node N1 and a V_{DD};
the MT1-gate is connected to the MT5-gate via a node N2 and a node N3;
the MT1-source is connected to the MT2-drain;
the MT2-drain is connected to the MT1-source;
the MT2-gate is connected to the MT4-gate via the node N3;
the MT2-source is connected to the MT3-drain via a node N4;
the MT3-drain is connected to the MT2-source via the node N4;
the MT3-gate is connected to: a GND and the MT3-source via a node N5;
the MT3-source is connected to: the GND via the node N5 and the MT3-gate via the node N5;
the MT4-drain is connected to: the node N1, the V_{DD} via the node N1, and the MT5-drain via the node N1;
the MT4-gate is connected to the MT2-gate via the node N3;
the MT4-source is connected to: the MT5-source, a node N6, and the MT6-drain;
the MT5-drain is connected to: the node N1, the V_{DD}, and the MT4-drain via the Node N1;
the MT5-gate is connected to the MT1-gate via the node N2;
the MT5-source is connected to: the MT4-source, the node N6, and the MT6-drain;
the MT6-drain is connected to the node N6, the MT5-source, and the MT4-source;
the MT6-gate is connected to the node N5 and the GND via the node N5;
the MT6-source is connected to the GND and the node N5;
the output A from the first s-bit generator is received at the node N3, the output B from the second s-bit generator is received at the node N2, the output C is generated at the node N6, and the output D is generated at the node N4.
